(19) United States
(12) Patent Application Publication
(10) Pub. No.: US 2014/0220492 A1
(43) Pub. Date: Aug. 7, 2014

(54) RESIST COMPOSITION, POLYMERIC COMPOUND, COMPOUND AND METHOD OF FORMING RESIST PATTERN

(71) Applicant: Tokyo Ohka Kogyo Co., Ltd., Kawasaki-shi (JP)

(72) Inventors: Takaaki Kaiho, Kawasaki-shi (JP); Yoshitaka Komuro, Kawasaki-shi (JP)

(73) Assignee: Tokyo Ohka Kogyo Co., Ltd., Kawasaki-shi (JP)

(21) Appl. No.: 14/171,293

(22) Filed: Feb. 3, 2014

(30) Foreign Application Priority Data
Feb. 5, 2013 (JP) 2013-020926

(51) Int. Cl. G03F 7/038

(52) U.S. Cl. CPC G03F 7/0388
USPC 430/285.1; 430/325; 526/257; 560/151; 549/318; 549/31; 549/300

(57) ABSTRACT

A resist composition which generates acid upon exposure and exhibits changed solubility in a developing solution under action of acid, including a base component containing a polymeric compound having a structural unit derived from a compound represented by general formula (a0-1). R¹ and R² each independently represents a group represented by general formula (a0-2) or a functional group; V¹ and V² each represents a single bond or an alkylene group of C₁ to C₁₀ which may have a substituent; Y¹ represents a single bond or a divalent linking group; Y₂ represents a fluorinated alkylene group of C₁ to C₄ which may have a substituent; L¹ represents O or a group represented by —NR′¹—(R′¹ represents H or an alkyl group of C₁ to C₅); M^{m+} represents an organic cation having a valency of m; and m represents an integer of 1 or more.

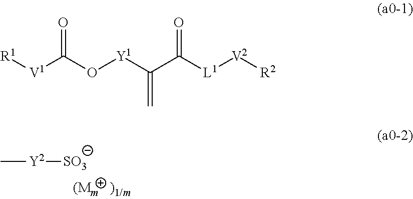

### CROSS-REFERENCE TO RELATED APPLICATION

This application claims priority to Japanese Patent Application No. 2013-020926, filed Feb. 5, 2013, the content of which is incorporated herein by reference.

### TECHNICAL FIELD

The present invention relates to a resist composition, a polymeric compound, a compound, and a method of forming resist pattern

### BACKGROUND ART

In lithography techniques, for example, a resist film composed of a resist material is formed on a substrate, and the resist film is subjected to selective exposure of radial rays such as light or electron beam through a mask having a predetermined pattern, followed by development, thereby forming a resist pattern having a predetermined shape on the resist film.

A resist material in which the exposed portions become soluble in a developing solution is called a positive-type, and a resist material in which the exposed portions become insoluble in a developing solution is called a negative-type.

In recent years, in the production of semiconductor elements and liquid crystal display elements, advances in lithography techniques have led to rapid progress in the field of pattern miniaturization.

Typically, these miniaturization techniques involve shortening the wavelength (increasing the energy) of the exposure light source. Conventionally, ultraviolet radiation typified by g-line and i-line radiation has been used, but nowadays KrF excimer lasers and ArF excimer lasers are starting to be introduced in mass production of the semiconductor elements. Furthermore, research is also being conducted into lithography techniques that use an exposure light source having a wavelength shorter (energy higher) than these excimer lasers, such as electron beam, extreme ultraviolet radiation (EUV), and X ray.

Resist materials for use with these types of exposure light sources require lithography properties such as a high resolution capable of reproducing patterns of minute dimensions, and a high level of sensitivity to these types of exposure light sources.

As a resist material that satisfies these conditions, a chemically amplified resist composition is used, which includes a base material component that exhibits a changed solubility in a developing solution under the action of acid and an acid generator component that generates acid upon exposure. For example, in the case where the developing solution is an alkali developing solution (alkali developing process), a chemically amplified positive resist which contains, as a base component (base resin), a resin which exhibits increased solubility in an alkali developing solution under action of acid, and an acid generator is typically used. If the resist film formed using the resist composition is selectively exposed during formation of a resist pattern, then within the exposed portions, acid is generated from the acid generator component, and the action of this acid causes an increase in the polarity of the base resin, making the exposed portions soluble in the alkali developing solution. Thus, by conducting alkali developing, the unexposed portions remain to form a positive resist pattern. On the other hand, in the case where such a resist composition is applied to a solvent developing process using a developing solution containing an organic solvent (organic developing solution), the polarity of the base resin at exposed portions is increased, whereas the solubility at exposed portions in an organic developing solution is relatively decreased. As a result, the unexposed portions of the resist film are dissolved and removed by the organic developing solution, and a negative resist pattern in which the exposed portions are remaining is formed. Such a solvent developing process for forming a negative-tone resist pattern is sometimes referred to as “negative-tone developing process” (for example, see Patent Document 1).

In general, the base resin for a chemically amplified resist composition contains a plurality of structural units for improving lithography properties and the like. For example, in the case of a resin composition which exhibits increased solubility in an alkali developing solution by the action of acid, a structural unit containing an acid decomposable group which is decomposed by the action of acid generated from an acid generator component or the like and exhibits increased polarity. Further, a structural unit containing a lactone-containing cyclic group or a structural unit containing a polar group such as a hydroxy group is used (for example, see Patent Document 2).

A base resin which contains a structural unit containing a cyclic group having —SO₂— structure has been proposed. It is presumed that such as base resin contributes to improvement in lithography properties such as mask reproducibility, and improvement in shape of the resist pattern such as reduction of roughness. The roughness means the surface roughness of a resist pattern, which becomes the cause of defects in the shape of the resist pattern. For example, roughness on the line width (line width roughness (LWR)) can cause various defects such as non-uniformity of the line width of line and space patterns. Such defects of the resist pattern adversely affect the formation of very fine semiconductor elements, and improvement in these defects becomes more important as the pattern becomes smaller.

In recently, as the miniaturization of patterns proceeds, a polymeric compound useful as a base resin for a resist composition is demanded.

Patent Document 3 discloses a resin having an acid generator group which is decomposed upon exposure and then generates acid. In the invention of Patent Document 3, a polymeric compound is used as a base resin, obtainable by polymerization of a monomer corresponding to a structural unit which generates acid upon exposure, a monomer corresponding to a structural unit having a cyclic group containing an —SO₂— structure, and a monomer corresponding to a structural unit having an acid decomposable group which is decomposed by the action of acid and exhibits increased polarity.

Such a resin composition has both the function as an acid generator and the function as a base component, and hence, it can compose a chemically amplified resist composition by itself

### DOCUMENTS OF RELATED ART

### [Patent Document]

[Patent Document 1] Japanese Unexamined Patent Application, First Publication No. 2009-025723

[Patent Document 2] Japanese Unexamined Patent Application, First Publication No. 2003-241385

[Patent Document 3] Japanese Unexamined Patent Application, First Publication No. 2011-158879

### SUMMARY OF THE INVENTION

As further progress is made in lithography techniques and the application field for lithography techniques expands, further improvement in various lithography properties is demanded in the formation of a resist pattern.

For example, as miniaturization of resist patterns progress, further improvement will be demanded for conventional resist materials (e.g., a resist material in which a base resin of the Patent Document 3 is used) with respect to various lithography properties such as roughness (LWR (line width roughness: non-uniformity of the line width) and the like in the case of a line pattern, and in-plane uniformity, and circularity in the case of a hole pattern), writing error enhancement factor by electron beam, and exposure latitude, as well as sensitivity and resolution.

The present invention takes the above circumstances into consideration, with an object of providing a resist composition capable of improving lithography properties, a method of forming a resist pattern using the resist composition, a polymeric compound useful for the resist composition and a compound useful for the resist composition.

A first aspect of the present invention is a resist composition which generates acid upon exposure and exhibits changed solubility in a developing solution under action of acid, including a base component (A′) which exhibits changed solubility in a developing solution under action of acid, the base component (A′) including a polymeric compound (A1′) having a structural unit (a0) derived from a compound represented by general formula (a0-1) shown below.

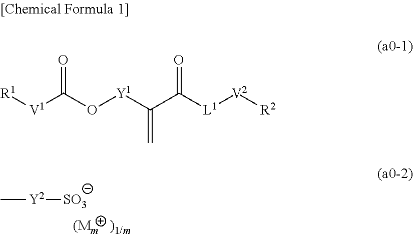

In the formula, R¹ and R² each independently represents a group represented by general formula (a0-2) or a function group, provided that at least one of R¹ and R² represents a group represented by general formula (a0-2);

V¹ represents a single bond, an oxygen atom, or an alkylene group of 1 to 10 carbon atoms which may have a substituent; V² represents a single bond or an alkylene group of 1 to 10 carbon atoms which may have a substituent;

Y¹ represents a single bond or a divalent linking group; Y² represents a fluorinated alkylene group of 1 to 4 carbon atoms which may have a substituent; L¹ represents an oxygen atom or a group represented by —NR′¹—, R′¹ represents a hydrogen atom or an alkylene group of 1 to 5 carbon atoms; M^{m+} represents an organic cation having a valency of m; and m represents an integer of 1 or more.

A second aspect of the present invention is a polymeric compound having a structural unit (a0) derived from a compound represented by general formula (a0-1) shown below.

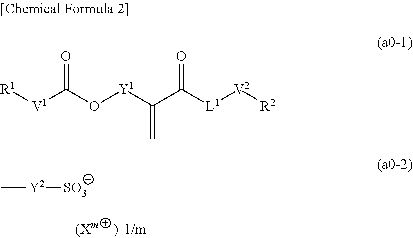

In the formula, R¹ and R² each independently represents a group represented by general formula (a0-2) or a function group, provided that at least one of R¹ and R² represents a group represented by general formula (a0-2);

V¹ represents a single bond, an oxygen atom, or an alkylene group of 1 to 10 carbon atoms which may have a substituent; V² represents a single bond or an alkylene group of 1 to 10 carbon atoms which may have a substituent;

Y¹ represents a single bond or a divalent linking group; Y² represents a fluorinated alkylene group of 1 to 4 carbon atoms which may have a substituent; L¹ represents an oxygen atom or a group represented by —NR′¹—, R′¹ represents a hydrogen atom or an alkylene group of 1 to 5 carbon atoms; X^{m+} represents a metal cation or an organic cation having a valency of m; and m represents an integer of 1 or more.

A third aspect of the present invention is a compound represented by general formula (a0-1) shown below.

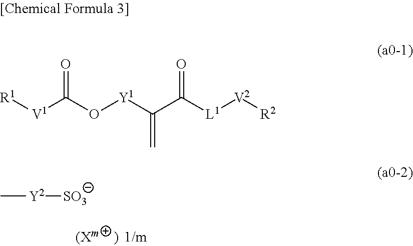

In the formula, R¹ and R² each independently represents a group represented by general formula (a0-2) or a function group, provided that at least one of R¹ and R² represents a group represented by general formula (a0-2);

V¹ represents a single bond, an oxygen atom, or an alkylene group of 1 to 10 carbon atoms which may have a substituent; V² represents a single bond or an alkylene group of 1 to 10 carbon atoms which may have a substituent;

Y¹ represents a single bond or a divalent linking group; Y² represents a fluorinated alkylene group of 1 to 4 carbon atoms which may have a substituent; L¹ represents an oxygen atom or a group represented by —NR′¹—, R′¹ represents a hydrogen atom or an alkylene group of 1 to 5 carbon atoms; X^{m+} represents a metal cation or an organic cation having a valency of m; and m represents an integer of 1 or more.

A fourth aspect of the present invention is a resist composition including a base component (A) which exhibits changed solubility in a developing solution under action of acid and an acid generator component (B′) which generates acid upon exposure,

the acid generator component (B′) including an acid generator (B1′) containing a compound represented by general formula (a0-1) shown below.

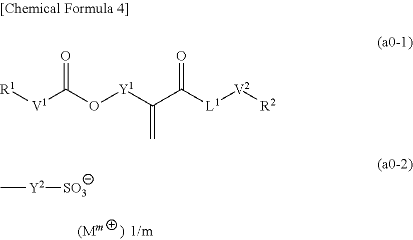

In the formula, R¹ and R² each independently represents a group represented by general formula (a0-2) or a function group, provided that at least one of R¹ and R² represents a group represented by general formula (a0-2);

V¹ represents a single bond, an oxygen atom, or an alkylene group of 1 to 10 carbon atoms which may have a substituent; V² represents a single bond or an alkylene group of 1 to 10 carbon atoms which may have a substituent;

Y¹ represents a single bond or a divalent linking group; Y² represents a fluorinated alkylene group of 1 to 4 carbon atoms which may have a substituent; L¹ represents an oxygen atom or a group represented by —NR′¹—, R′¹ represents a hydrogen atom or an alkylene group of 1 to 5 carbon atoms; M^{m+} represents an organic cation having a valency of m; and m represents an integer of 1 or more.

A fifth aspect of the present invention is a method of forming a resist pattern, including: using a resist composition of the first aspect or fourth aspect to form a resist film on a substrate; conducting exposure of the resist film; and developing the resist film to form a resist pattern.

According to the present invention, there are provided a resist composition capable of improving lithography properties, a polymeric compound useful for the resist composition, a compound useful for the resist composition, and a method of forming a resist pattern using the resist composition.

### MODE FOR CARRYING OUT THE INVENTION

In the present description and claims, the term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified.

The term “alkylene group” includes linear, branched or cyclic, divalent saturated hydrocarbon, unless otherwise specified. The same applies for the alkyl group within an alkoxy group.

A “halogenated alkyl group” is a group in which part or all of the hydrogen atoms of an alkyl group is substituted with a halogen atom. Examples of the halogen atom include a fluorine atom, a chlorine atom, a bromine atom and an iodine atom.

A “fluorinated alkyl group” or a “fluorinated alkylene group” is a group in which part or all of the hydrogen atoms of an alkyl group or an alkylene group have been substituted with fluorine atom(s).

The term “structural unit” refers to a monomer unit that contributes to the formation of a polymeric compound (resin, polymer, copolymer).

A “structural unit derived from an acrylate ester” refers to a structural unit that is formed by the cleavage of the ethylenic double bond of an acrylate ester.

An “acrylate ester” refers to a compound in which the terminal hydrogen atom of the carboxy group of acrylic acid (CH₂═CH—COOH) has been substituted with an organic group.

The acrylate ester may have the hydrogen atom bonded to the carbon atom on the α-position substituted with a substituent. The substituent (R^{α}) that substitutes the hydrogen atom bonded to the carbon atom on the α-position is an atom other than hydrogen or a group, and examples thereof include an alkyl group of 1 to 5 carbon atoms, a halogenated alkyl group of 1 to 5 carbon atoms and a hydroxyalkyl group. A carbon atom on the α-position of an acrylate ester refers to the carbon atom bonded to the carbonyl group, unless specified otherwise.

Hereafter, an acrylate ester having the hydrogen atom bonded to the carbon atom on the α-position substituted with a substituent is sometimes referred to as “α-substituted acrylate ester”. Further, acrylate esters and α-substituted acrylate esters are collectively referred to as “(α-substituted) acrylate ester”.

A “structural unit derived from hydroxystyrene or a hydroxystyrene derivative” refers to a structural unit that is formed by the cleavage of the ethylenic double bond of hydroxystyrene or a hydroxystyrene derivative.

The term “hydroxystyrene derivative” includes compounds in which the hydrogen atom at the α-position of hydroxystyrene has been substituted with another substituent such as an alkyl group or a halogenated alkyl group; and derivatives thereof. Examples of the derivatives thereof include hydroxystyrene in which the hydrogen atom of the hydroxy group has been substituted with an organic group and may have the hydrogen atom on the α-position substituted with a substituent; and hydroxystyrene which has a substituent other than a hydroxy group bonded to the benzene ring and may have the hydrogen atom on the α-position substituted with a substituent. Here, the α-position (carbon atom on the α-position) refers to the carbon atom having the benzene ring bonded thereto, unless specified otherwise.

As the substituent which substitutes the hydrogen atom on the α-position of hydroxystyrene, the same substituents as those described above for the substituent on the α-position of the aforementioned α-substituted acrylate ester can be mentioned.

A “structural unit derived from vinylbenzoic acid or a vinylbenzoic acid derivative” refers to a structural unit that is formed by the cleavage of the ethylenic double bond of vinylbenzoic acid or a vinylbenzoic acid derivative.

The term “vinylbenzoic acid derivative” includes compounds in which the hydrogen atom at the α-position of vinylbenzoic acid has been substituted with another substituent such as an alkyl group or a halogenated alkyl group; and derivatives thereof. Examples of the derivatives thereof include benzoic acid in which the hydrogen atom of the carboxy group has been substituted with an organic group and may have the hydrogen atom on the α-position substituted with a substituent; and benzoic acid which has a substituent other than a hydroxy group and a carboxy group bonded to the benzene ring and may have the hydrogen atom on the α-position substituted with a substituent. Here, the α-position (carbon atom on the α-position) refers to the carbon atom having the benzene ring bonded thereto, unless specified otherwise.

The term “styrene” includes styrene itself and compounds in which the hydrogen atom at the α-position of styrene has been substituted with another substituent such as an alkyl group or a halogenated alkyl group.

A “structural unit derived from styrene or a styrene derivative” refers to a structural unit that is formed by the cleavage of the ethylenic double bond of styrene or a styrene derivative.

As the alkyl group as a substituent on the α-position, a linear or branched alkyl group is preferable, and specific examples include alkyl groups of 1 to 5 carbon atoms, such as a methyl group, an ethyl group, a propyl group, an isopropyl group, an n-butyl group, an isobutyl group, a tert-butyl group, a pentyl group, an isopentyl group and a neopentyl group.

Specific examples of the halogenated alkyl group as the substituent on the α-position include groups in which part or all of the hydrogen atoms of the aforementioned “alkyl group as the substituent on the α-position” are substituted with halogen atoms. Examples of the halogen atom include a fluorine atom, a chlorine atom, a bromine atom and an iodine atom, and a fluorine atom is particularly desirable.

Specific examples of the hydroxyalkyl group as the substituent on the α-position include groups in which part or all of the hydrogen atoms of the aforementioned “alkyl group as the substituent on the α-position” are substituted with a hydroxy group. The number of hydroxy groups within the hydroxyalkyl group is preferably 1 to 5, and most preferably 1.

The expression “may have a substituent” means that a case where a hydrogen atom (—H) is substituted with a monovalent group, or a case where a methylene (—CH₂—) group is substituted with a divalent group.

The term “exposure” is used as a general concept that includes irradiation with any form of radiation.

An “organic group” refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

<<Resist Composition 1>>

The resist composition according to a first aspect of the present invention (hereafter, sometimes referred to as “resist composition 1”) is a resist composition which generates acid upon exposure and exhibits changed solubility in a developing solution under action of acid, and which includes a base component (A′) which exhibits changed solubility in a developing solution under action of acid, and the base component (A′) includes a polymeric compound (A1′) having a structural unit (a0) derived from a compound represented by general formula (a0-1).

The resist composition according to a first aspect of the present invention is a resist composition including a base component (A′) which generates acid upon exposure and exhibits changed solubility in a developing solution under action of acid (hereafter, frequently referred to as “component (A)′).

Since the resist composition of the present embodiment includes a component (A′), the resist composition exhibits changed solubility in a developing solution upon exposure. When a resist film formed using the resist composition is subjected to a selective exposure, acid is generated from the component (A′) at exposed portions, and the generated acid acts on the component (A′) to change the solubility of the component (A) in a developing solution. As a result, the solubility of the exposed portions in a developing solution is changed, whereas the solubility of the unexposed portions in a developing solution remains unchanged. Therefore, by subjecting the resist film to development, the exposed portions are dissolved and removed to form a positive-tone resist pattern in the case of a positive resist, whereas the unexposed portions are dissolved and removed to form a negative-tone resist pattern in the case of a negative resist.

In the present specification, a resist composition which forms a positive resist pattern by dissolving and removing the exposed portions is called a positive resist composition, and a resist composition which forms a negative resist pattern by dissolving and removing the unexposed portions is called a negative resist composition.

The resist composition of the present embodiment may be either a positive resist composition or a negative resist composition. Further, in the formation of a resist pattern, the resist composition of the present embodiment can be applied to an alkali developing process using an alkali developing solution in the developing treatment, or a solvent developing process using a developing solution containing an organic solvent (organic developing solution) in the developing treatment. The resist composition of the present invention is preferably used in the formation of a positive-tone resist pattern by an alkali developing process. In such a case, as the component (A′), a base component that exhibits increased solubility in an alkali developing solution under the action of acid is used.

<Component (A′)>

The component (A′) used in the resist composition of the present embodiment is a base component which generates acid upon exposure, exhibits changed solubility in a developing solution under action of acid, and contains a polymeric compound (A1′) (hereafter, frequently referred to as “component (A1′)”) having a structural unit (a0) described later.

Here, the term “base component” refers to an organic compound capable of forming a film, and is preferably an organic compound having a molecular weight of 500 or more. When the organic compound has a molecular weight of 500 or more, the film-forming ability is improved, and a resist pattern of nano level can be easily formed. The “organic compound having a molecular weight of 500 or more” which can be used as a base component is broadly classified into non-polymers and polymers.

In general, as a non-polymer, any of those which have a molecular weight in the range of 500 to less than 4,000 is used. Hereafter, a non-polymer having a molecular weight in the range of 500 to less than 4,000 is referred to as a low molecular weight compound.

As a polymer, any of those which have a molecular weight of 1,000 or more is generally used. Hereafter, a polymer having a molecular weight of 1,000 or more is referred to as a polymeric compound. With respect to a polymeric compound, the “molecular weight” is the weight average molecular weight in terms of the polystyrene equivalent value determined by gel permeation chromatography (GPC). Hereafter, a polymeric compound is frequently referred to simply as a “resin”.

As the component (A′), a low molecular weight compound and the component (A1′) may be used in combination.

The component (A′) containing the component (A1′) may be a component that exhibits increased solubility in a developing solution under action of acid or a component that exhibits decreased solubility in a developing solution under action of acid.

[Component (A1′)]

The component (A1′) is a polymeric compound including the structural unit (a0) derived from a compound represented by general formula (a0-1).

When the resist film formed using the resist composition of the present embodiment is subjected to exposure, in the structural unit (a0), at least a part of the bond within the structure thereof is cleaved by the action of acid to exhibit increased polarity. Therefore, the resist composition of the present embodiment becomes a positive type in the case of an alkali developing process, and a negative type in the case of a solvent developing process. Since the polarity of the component (A1′) is changed prior to and after exposure, by using the component (A1′), an excellent development contrast can be achieved not only in an alkali developing process, but also in a solvent developing process.

More specifically, in the case of applying an alkali developing process, the component (A1′) is substantially insoluble in an alkali developing solution prior to exposure, but when acid is generated from the structural unit (a0) upon exposure, the action of this acid causes an increase in the polarity of the base component, thereby increasing the solubility of the component (A1′) in an alkali developing solution. Therefore, in the formation of a resist pattern, by conducting selective exposure of a resist film formed by applying the resist composition to a substrate, the exposed portions change from an insoluble state to a soluble state in an alkali developing solution, whereas the unexposed portions remain insoluble in an alkali developing solution, and hence, a positive resist pattern can be formed by alkali developing.

On the other hand, in the case of a solvent developing process, the component (A1′) exhibits high solubility in an organic developing solution prior to exposure, and when acid is generated from the structural unit (a0) upon exposure, the polarity of the component (A1′) is increased by the action of the generated acid, thereby decreasing the solubility of the component (A1′) in an organic developing solution. Therefore, in the formation of a resist pattern, by conducting selective exposure of a resist film formed by applying the resist composition to a substrate, the exposed portions changes from an soluble state to an insoluble state in an organic developing solution, whereas the unexposed portions remain soluble in an organic developing solution. As a result, by conducting development using an organic developing solution, a contrast can be made between the exposed portions and unexposed portions, thereby enabling the formation of a negative resist pattern.

(Structural Unit (a0))

The structural unit (a0) is derived from a compound represented by general formula (a0-1) shown below.

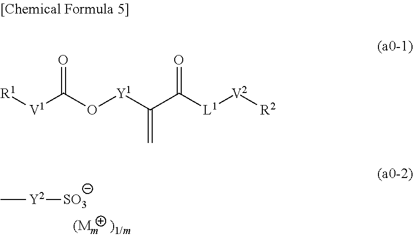

In the formula, R¹ and R² each independently represents a group represented by general formula (a0-2) or a function group, provided that at least one of R¹ and R² represents a group represented by general formula (a0-2);

V¹ represents a single bond, an oxygen atom, or an alkylene group of 1 to 10 carbon atoms which may have a substituent; V² represents a single bond or an alkylene group of 1 to 10 carbon atoms which may have a substituent;

Y¹ represents a single bond or a divalent linking group; Y² represents a fluorinated alkylene group of 1 to 4 carbon atoms which may have a substituent; L¹ represents an oxygen atom or a group represented by —NR′¹—, R′¹ represents a hydrogen atom or an alkylene group of 1 to 5 carbon atoms; M^{m+} represents an organic cation having a valency of m; and m represents an integer of 1 or more.

In the formula (a0-1), R¹ and R² each independently represents a group represented by general formula (a0-2) or a function group, provided that at least one of R¹ and R² represents a group represented by general formula (a0-2).

In the formula (a0-2), Y² represents a fluorinated alkylene group of 1 to 4 carbon atoms which may have a substituent. As the fluorinated alkylene group of 1 to 4 carbon atoms for Y², a linear or branched alkylene group of 1 to 4 carbon atom in which part or all of the hydrogen atoms has been substituted with fluorine atoms can be used.

In the present invention, Y² may have a substituent. Examples of the substituent include an alkyl group of 1 to 5 carbon atoms, a fluorine atom, a fluorinated alkyl group of 1 to 5 carbon atoms, an oxygen atom (═O), a hydroxyl group, and C(═O)—OH.

In the present invention, examples of Y² include —CF₂—, —CH₂—CH(CF₃)—, —CF₂—CH(CF₃)—, —CH₂—C(CF₃)₂—, —CF₂—CH₂—, —CF₂—CF₂—, —CF₂—CF₂—CH₂—, and —CF₂—CH₂—CH₂—. Among these, —CF₂— and —CF₂—CH₂— are preferable. In the case of Y² has two or more carbon atoms, —SO₃ may be bonded any terminal of Y².

In the formula (a0-2), M^{m+} represents an organic cation having a valency of m, wherein m represents an integer of 1 or more. Further, as examples of the organic cation in the formula (a0-1), organic cations in the onium salt acid generators represented by general formulae (b-1) to (b-3) described later can also be given.

In the formula (a0-1), As a function group for R¹ and R², a group which exhibits increased polarity by the action of acid, a substrate adhesion group, a polar group-containing aliphatic hydrocarbon group, and a non-acid dissociable cyclic group can be mentioned, and at least one function group selected from these groups can be mentioned.

Examples of the group which exhibits increased polarity by the action of an acid include an acetal-type acid dissociable group, a tertiary ester-type acid dissociable group, and a tertiary alkyloxycarbonyl group described later in relation to a structural unit (a1).

As the acetal-type acid dissociable group, a group represented by general formula (a1-r-1) described later can be mentioned. Among the groups represented by general formula (a1-r-1) described later, a group represented by general formula (a1-r-1) in which Ra′³ is a cyclic hydrocarbon group is preferable.

As the tertiary ester-type acid dissociable group, a group represented by general formula (a1-r-2) described later can be mentioned, and a group represented by general formula (a1-r2-1) or (a1-r2-2) described later is preferable, and a group represented by general formula (a1-r2-1) is more preferable. As the group represented by general formula (a1-r2-1), groups represented by formulae (r-pr-m1) to (r-pr-m17) and (r-pr-s1) to (r-pr-s18) are preferable. As the group represented by general formula (a1-r2-2), groups represented by general formulae (r-pr-c1) to (r-pr-c3) can be mentioned.

As the tertiary alkyloxycarbonyl group, a group represented by general formula (a1-r-3) described later can be mentioned.

As the substrate adhesion group, a lactone-containing cyclic group, a carbonate-containing cyclic group, and an —SO₂— containing cyclic group described later in relation to a structural unit (a2) can be mentioned.

The term “lactone-containing cyclic group” refers to a cyclic group including a ring containing a —O—C(═O)— structure (lactone ring). Specific examples thereof include groups represented by general formulae (a2-r-1) to (a2-r-7) described later. In the present invention, groups represented by general formulae (a2-r-1) and (a2-r-2) described later are preferable.

As the groups represented by general formulae (a2-r-1) and (a2-r-2), groups represented by general formulae (r-1c-1-1) to (r-1c-1-7) and (r-1c-2-1) to (r-1c-2-13) described later can be mentioned.

An “—SO₂— containing cyclic group” refers to a cyclic group having a ring containing —SO₂— within the ring structure thereof. Specific examples thereof include groups represented by general formulae (a5-r-1) to (a5-r-4) described later. In the present invention, a group represented by general formula (a5-r-1) described later is preferable.

As the group represented by general formula (a5-r-1), groups represented by general formulae (r-s1-1-1) to (r-s1-1-33) described later can be mentioned.

The term “carbonate-containing cyclic group” refers to a cyclic group including a ring containing a —O—C(═O)—O— structure (carbonate ring) in the ring skeleton thereof. Specific examples thereof include groups represented by general formulae (ax3-r-1) to (ax3-r-3) described later.

As the polar group-containing aliphatic hydrocarbon group, groups exemplified later in relation to a structural unit (a3) can be mentioned, and it is preferable that the group has a hydroxy group, a cyano group, or a carboxy group as a polar group.

In the present invention, as the polar group-containing aliphatic hydrocarbon group, groups represented by general formulae (a3-r-1) to (a3-r-3) described later can be mentioned, and a group represented by general formula (a3-r-1) is preferable.

The non-acid dissociable cyclic group may or may not have a hetero atom in the ring structure thereof. As the non-acid dissociable cyclic group, an aliphatic cyclic group exemplified later in relation to a structural unit (a4), and a heterocyclic group shown below. The “*” in the formula represents a valence bond.

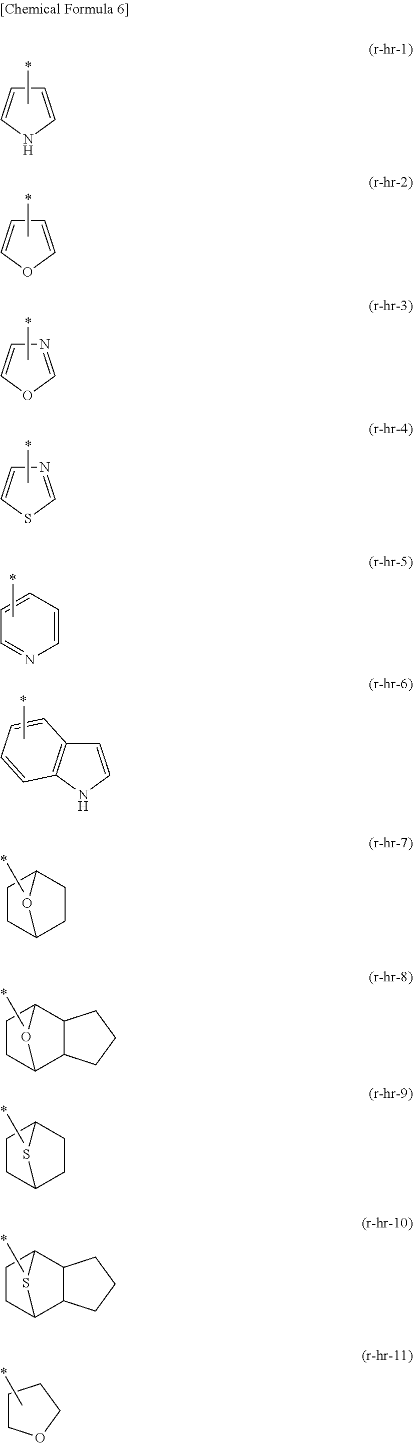

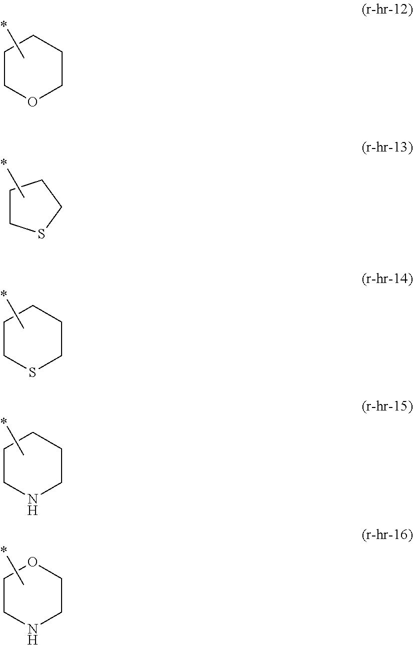

The compound of the present invention has the aforementioned function group, and hence, when the compound is used in a resist composition, it is useful for construction of a polymeric compound.

In the present invention, in the formula (a0-1), R¹ and R² each independently represents a group represented by general formula (a0-2) or a function group, provided that at least one of R¹ and R² represents a group represented by general formula (a0-2).

When R¹ is any one of the aforementioned function groups, R² is a group represented by general formula (a0-2), and when R¹ is a group represented by general formula (a0-2), R² is any one of the aforementioned function groups. Both R¹ and R² may be a group represented by general formula (a0-2).

In the formula (a0-1), V¹ represents a single bond, an oxygen atom, or an alkylene group of 1 to 10 carbon atoms which may have a substituent; V² represents a single bond or an alkylene group of 1 to 10 carbon atoms which may have a substituent;

In the formula (a0-1), examples of the alkylene group of 1 to 10 carbon atoms for V¹ and V² include a linear alkylene group of 1 to 10 carbon atoms and a branched alkylene group of 1 to 10 carbon atoms.

Specific examples of the linear alkylene group include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

Specific examples of the branched alkylene group include alkylalkylene groups, e.g., alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—.

In the present invention, V¹ and V² may have a substituent. Examples of the substituent include an alkyl group of 1 to 5 carbon atoms, a fluorine atom, a fluorinated alkyl group of 1 to 5 carbon atoms, an oxygen atom (═O), a hydroxyl group, and C(═O)—OH. When V¹ and V² represent an alkylene group having 2 or more carbon atoms, one carbon atom (i.e., methylene group) within the alkylene group may be substituted with an oxygen atom. That is, V¹ and V² may be an alkylene group of 1 to 10 carbon atoms which contains an ether bond or an ester bond.

In the present invention, it is preferable that V¹ and V² each independently represents a single bond or an alkylene group of 1 to 5 carbon atoms which may have a substituent, and it is more preferable that V¹ and V² each independently represents a single bond, an alkylene group of 1 to 5 carbon atoms, an alkylene group of 1 to 5 carbon atoms which has been substituted with an oxygen atom (═O), or an alkylene group of 1 to 5 carbon atoms which contains an ether bond or an ester bond.

When R¹ is not a group represented by general formula (a0-2), it is preferable that V¹ represents an oxygen atom, an alkylene group of 1 to 5 carbon atoms which may have a substituent (preferably an alkylene group of 1 to 5 carbon atoms which contains an ether bond or an ester bond).

In the formula (a0-1), Y¹ represents a single bond or a divalent linking group.

The divalent linking group for Y¹ is not particularly limited, and preferable examples thereof include a divalent hydrocarbon group which may have a substituent and a divalent linking group containing a hetero atom.

(Divalent Hydrocarbon Group which May have a Substituent)

The hydrocarbon group as a divalent linking group may be either an aliphatic hydrocarbon group or an aromatic hydrocarbon group.

An “aliphatic hydrocarbon group” refers to a hydrocarbon group that has no aromaticity. The aliphatic hydrocarbon group may be saturated or unsaturated. In general, the aliphatic hydrocarbon group is preferably saturated.

Examples of the aliphatic hydrocarbon group include a linear or branched aliphatic hydrocarbon group, and an aliphatic hydrocarbon group containing a ring in the structure thereof can be given. Specific examples thereof include the same group as exemplified above for Va¹ in formula (a1-1) described later.

The linear or branched aliphatic hydrocarbon group may or may not have a substituent. Examples of the substituent include a fluorine atom, a fluorinated alkyl group of 1 to 5 carbon atoms, and a carbonyl group.

As examples of the aliphatic hydrocarbon group containing a ring in the structure thereof, a cyclic aliphatic hydrocarbon group which may have a substituent containing a hetero atom in the ring structure thereof (a group in which two hydrogen atoms have been removed from an aliphatic hydrocarbon ring), a group in which the cyclic aliphatic hydrocarbon group is bonded to the terminal of a linear or branched aliphatic hydrocarbon group, and a group in which the cyclic aliphatic hydrocarbon group is interposed within a linear or branched aliphatic hydrocarbon group, can be given. As the linear or branched aliphatic hydrocarbon group, the same groups as those described above can be used.

The cyclic aliphatic hydrocarbon group preferably has 3 to 20 carbon atoms, and more preferably 3 to 12 carbon atoms.

Specific examples of the cyclic aliphatic hydrocarbon group include the same group as exemplified for Va¹ in formula (a1-1) described later.

The cyclic aliphatic hydrocarbon group may or may not have a substituent. Examples of the substituent include an alkyl group, an alkoxy group, a halogen atom, a halogenated alkyl group, a hydroxyl group and a carbonyl group.

The alkyl group as the substituent is preferably an alkyl group of 1 to 5 carbon atoms, and a methyl group, an ethyl group, a propyl group, an n-butyl group or a tert-butyl group is most desirable.

The alkoxy group as the substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom for the substituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

In the cyclic aliphatic hydrocarbon group, part of the carbon atoms constituting the ring structure thereof may be substituted with a substituent containing a hetero atom. The substituent containing a hetero atom is preferably —O—, —C(═O)—O—, —S—, —S(═O)₂—, or —S(═O)₂—O—.

Specific examples of the aromatic hydrocarbon group as a divalent hydrocarbon group include the same group as exemplified above for Va¹ in formula (a1-1) described later.

With respect to the aromatic hydrocarbon group, the hydrogen atom within the aromatic hydrocarbon group may be substituted with a substituent. For example, the hydrogen atom bonded to the aromatic ring within the aromatic hydrocarbon group may be substituted with a substituent. Examples of substituents include an alkyl group, an alkoxy group, a halogen atom, a halogenated alkyl group, and a hydroxyl group.

The alkyl group as the substituent is preferably an alkyl group of 1 to 5 carbon atoms, and a methyl group, an ethyl group, a propyl group, an n-butyl group or a tert-butyl group is most desirable.

As the alkoxy group, the halogen atom and the halogenated alkyl group for the substituent, the same groups as the aforementioned substituent groups for substituting a hydrogen atom within the cyclic aliphatic hydrocarbon group can be used.

(Divalent Linking Group Containing a Hetero Atom)

With respect to a divalent linking group containing a hetero atom, a hetero atom is an atom other than carbon and hydrogen, and examples thereof include an oxygen atom, a nitrogen atom, a sulfur atom and a halogen atom.

In the case where Y¹ represents a divalent linking group containing a hetero atom, preferable examples of the linking group include —O—, —C(═O)—O—, —C(═O)—, —O—C(═O)—O—, —C(═O)—NH—, —NH—, —NH—C(═NH)— (wherein H may be substituted with a substituent such as an alkyl group or an acyl group), —S—, —S(═O)₂—, —S(═O)₂—O—, and a group represented by general formula —Y²¹—O—Y²²—, —Y²¹—O—, —Y²¹—C(═O)—O—, —[Y²¹—(═O)—O]_{m′}—Y²²— and —Y²¹—O—C(═O)—Y²²— [in the formulas, each of Y²¹ and Y²² independently represents a divalent hydrocarbon group which may have a substituent, 0 represents an oxygen atom, and m′ represents an integer of 0 to 3].

When the divalent linking group containing a hetero atom represents —C(═O)—NH—, —NH—, or —NH—C(═NH)—, H may be substituted with a substituent such as an alkyl group, an acyl group or the like. The substituent (an alkyl group, an acyl group or the like) preferably has 1 to 10 carbon atoms, more preferably 1 to 8, and most preferably 1 to 5.

In formula —Y²¹—O—Y²²—, —Y²¹—O—, —Y²¹—C(═O)—O—, —[Y²¹—C(═O)—O]_{m′}—Y²²— or —Y²¹—O—C(═O)—Y²²—, Y²¹ and Y²² each independently represents a divalent hydrocarbon group which may have a substituent. Examples of the divalent hydrocarbon group include the same groups as those described above as the “divalent hydrocarbon group which may have a substituent” in the explanation of the aforementioned divalent linking group.

As Y²¹, a linear aliphatic hydrocarbon group is preferable, more preferably a linear alkylene group, still more preferably a linear alkylene group of 1 to 5 carbon atoms, and a methylene group or an ethylene group is particularly desirable.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group represented by the formula —[Y²¹—C(═O)—O]_{m′}—Y²²—, m′ represents an integer of 0 to 3, preferably an integer of 0 to 2, more preferably 0 or 1, and particularly preferably 1. Namely, it is particularly desirable that the group represented by the formula —[Y²¹—C(═O)—O]_{m′}—Y²²— is a group represented by the formula —Y²¹—C(═O)—O—Y²²—. Among these, a group represented by the formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

In the present invention, Y¹ preferably represents a linear or branched alkylene group which may have an ester bond [—C(═O)—O—] or an ether bond (—O—), a combination of these, or a single bond. Among these, single bond and a linear alkylene group of 1 to 5 carbon atoms are more preferable.

In the formula (a0-1), L¹ represents an oxygen atom or a group represented by —NR′¹— (wherein R′¹ represents a hydrogen atom or an alkyl group of 1 to 5 carbon atoms).

In the formula (a0-1), in the group represented by —NR′¹ for L¹, examples of alkyl group of 1 to 5 carbon atoms for R′¹ include a methyl group, an ethyl group, a propyl group, an n-butyl group and a tert-butyl group.

In the present invention, in the formula (a0-1), L¹ is preferably an oxygen atom.

Specific examples of the compound represented by the formula (a0-1) are shown below. The cation moieties may be cation moieties (ca-1) to (ca-4) described later in the explanation of the component (B).

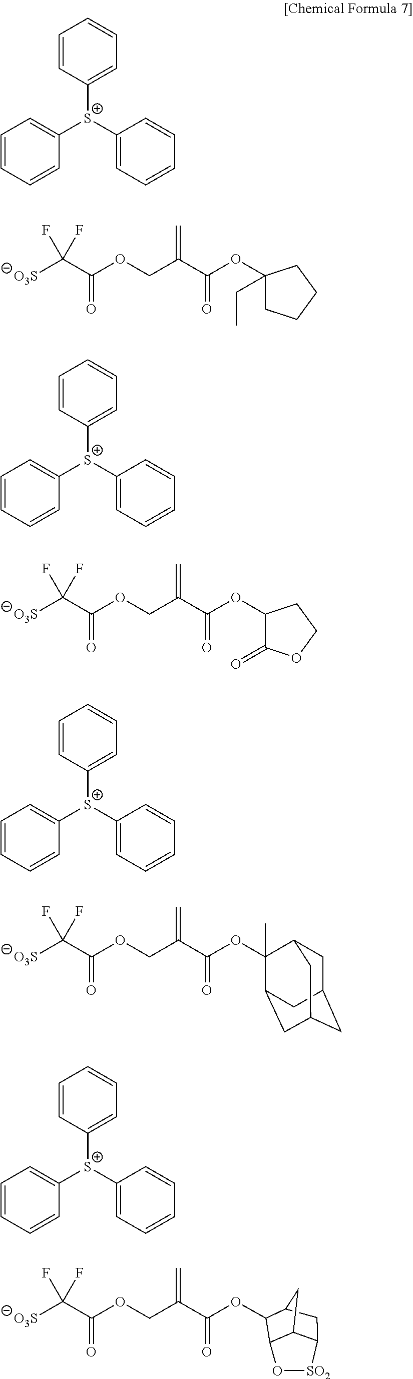

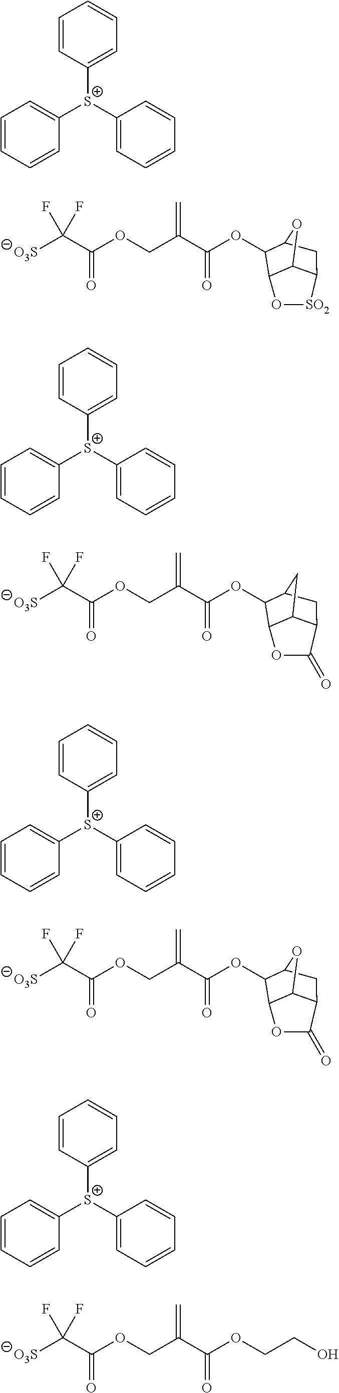

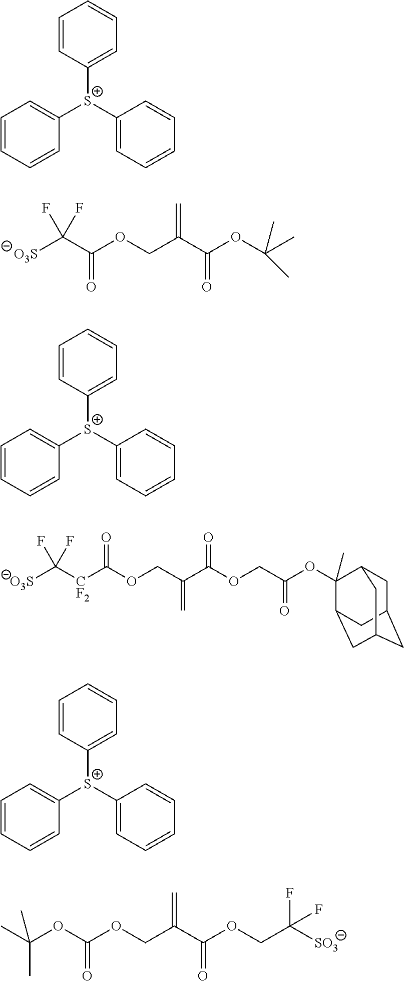

As the structural unit (a0) contained in the component (A1′), 1 type of structural unit may be used, or 2 or more types may be used.

The amount of the structural unit (a0) within the component (A1′) based on the combined total of all structural units constituting the component (A1′) is preferably 1 to 50 mol %, more preferably 5 to 45 mol %, and still more preferably 10 to 40 mol %.

When the amount of the structural unit (a0) is at least as large as the lower limit of the above-mentioned range, various lithography properties (such as WEEF, exposure latitude, and sensitivity) can be improved. On the other hand, when the amount of the structural unit (a0) is no more than the upper limit of the above-mentioned range, a good balance can be reliably achieved with the other structural units, and a resist pattern having an excellent shape can be reliably obtained.

In the resist composition 1 of the present invention, the polymeric compound (A1′) preferably has a structural unit (a1) containing an acid decomposable group that exhibits increased polarity by the action of acid.

(Structural Unit (a1))

The structural unit (a1) is a structural unit containing an acid decomposable group that exhibits increased polarity by the action of acid.

The term “acid decomposable group” refers to a group in which at least a part of the bond within the structure thereof is cleaved by the action of an acid.

Examples of acid decomposable groups which exhibit increased polarity by the action of an acid include groups which are decomposed by the action of acid to form a polar group.

Examples of the polar group include a carboxy group, a hydroxy group, an amino group and a sulfo group (—SO₃H). Among these, a polar group containing —OH in the structure thereof (hereafter, referred to as “OH-containing polar group”) is preferable, a carboxy group or a hydroxy group is more preferable, and a carboxy group is particularly desirable.

More specifically, as an example of an acid decomposable group, a group in which the aforementioned polar group has been protected with an acid dissociable group (such as a group in which the hydrogen atom of the OH-containing polar group has been protected with an acid dissociable group) can be given.

Here, the “acid dissociable group” is (i) a group in which the bond between the acid dissociable group and the adjacent atom is cleaved by the action of acid; and (ii) a group in which one of the bonds is cleaved by the action of acid, and then a decarboxylation reaction occurs, thereby cleaving the bond between the acid dissociable group and the adjacent atom.

It is necessary that the acid dissociable group that constitutes the acid decomposable group is a group which exhibits a lower polarity than the polar group generated by the dissociation of the acid dissociable group. Thus, when the acid dissociable group is dissociated by the action of acid, a polar group exhibiting a higher polarity than that of the acid dissociable group is generated, thereby increasing the polarity. As a result, the polarity of the entire component (A1′) is increased. By the increase in the polarity, the solubility in a developing solution changes and, the solubility in an organic developing solution is relatively decreased.

The acid dissociable group is not particularly limited, and any of the groups that have been conventionally proposed as acid dissociable groups for the base resins of chemically amplified resists can be used.

Examples of the acid dissociable group for protecting the carboxy group or hydroxy group as a polar group include the acid dissociable group represented by general formula (a1-r-1) shown below (hereafter, sometimes referred to as “acetal-type acid dissociable group”).

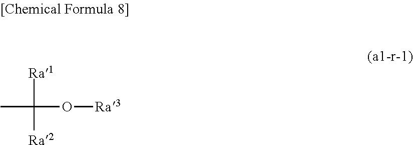

In the formula, Ra′¹ and Ra′² represents a hydrogen atom or an alkyl group; and Ra′³ represents a hydrocarbon group, provided that Ra′³ may be bonded to Ra′¹ or Ra′² to form a ring.

In the formula (a1-r-1), as the alkyl group for Ra′¹ and Ra′², the same alkyl groups as those described above the alkyl groups as the substituent which may be bonded to the carbon atom on the α-position of the aforementioned α-substituted alkylester can be used, although a methyl group or ethyl group is preferable, and a methyl group is particularly desirable.

As the hydrocarbon group for Ra′³, an alkyl group of 1 to 20 carbon atoms is preferable, an alkyl group of 1 to 10 carbon atoms is more preferable, and a linear or branched alkyl group is still more preferable. Specific examples thereof include a methyl group, an ethyl group, a propyl group, an isopropyl group, an n-butyl group, an isobutyl group, a tert-butyl group, a pentyl group, an isopentyl group, a neopentyl group, 1,1-dimethylethyl group, 1,1-diethylpropyl group, 2,2-dimethypropyl group and 2,2-dimethybutyl group.

When Ra′³ is a cyclic hydrocarbon group, the hydrocarbon group may be either an aliphatic group or an aromatic group, and may be either a polycyclic group or a monocyclic group. As the monocyclic alicyclic hydrocarbon group, a group in which one hydrogen atom has been removed from a monocycloalkane is preferable. The monocycloalkane preferably has 3 to 8 carbon atoms, and specific examples thereof include cyclopentane, cyclohexane and cyclooctane. As the polycyclic alicyclic hydrocarbon group, a group in which one hydrogen atom has been removed from a polycycloalkane is preferable, and the polycycloalkane preferably has 7 to 12 carbon atoms. Examples of the polycycloalkane include adamantane, norbornane, isobornane, tricyclodecane and tetracyclododecane.

Examples of the aromatic ring contained in the aromatic hydrocarbon group include aromatic hydrocarbon rings, such as benzene, biphenyl, fluorene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom.

Specific examples of the aromatic hydrocarbon group include a group in which one hydrogen atom has been removed from the aforementioned aromatic hydrocarbon ring (aryl group); and a group in which one hydrogen atom of the aforementioned aryl group has been substituted with an alkylene group (an arylalkyl group such as a benzyl group, a phenethyl group, a 1-naphthylmethyl group, a 2-naphthylmethyl group, a 1-naphthylethyl group or a 2-naphthylethyl group). The alkylene group (alkyl chain within the arylalkyl group) preferably has 1 to 4 carbon atoms, more preferably 1 or 2, and most preferably 1.

In the case where Ra′³ is bonded to Ra′¹ or Ra′² to form a ring, the cyclic group is preferably a 4 to 7-membered ring, and more preferably a 4 to 6-membered ring. Specific examples of the cyclic group include tetrahydropyranyl group and tetrahydrofuranyl group.

Examples of the acid dissociable group for protecting the carboxy group as a polar group include the acid dissociable group represented by general formula (a1-r-2) shown below (hereafter, with respect to the acid dissociable group represented by the following formula (a1-r-2), the acid dissociable group constituted of alkyl groups is referred to as “tertiary ester-type acid dissociable group”).

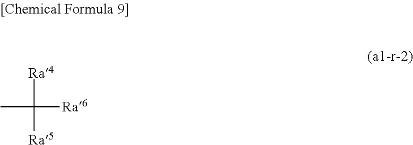

In the formula, Ra′⁴ to Ra′⁶ each independently represents a hydrocarbon group, provided that Ra′⁵ and Ra′⁶ may be mutually bonded to form a ring.

As the hydrocarbon group for Ra′⁴ to Ra′⁶, the same groups as those described above for Ra′³ can be mentioned. Ra′⁴ is preferably an alkyl group of 1 to 5 carbon atoms. In the case where Ra′⁵ and Ra′⁶ are mutually bonded to form a ring, a group represented by general formula (a1-r2-1) shown below can be mentioned.

On the other hand, in the case where Ra′⁴ to Ra′⁶ are not mutually bonded and independently represent a hydrocarbon group, the group represented by general formula (a1-r2-2) shown below can be mentioned.

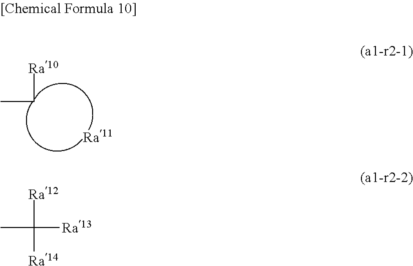

In the formula, Ra′¹⁰ represents an alkyl group of 1 to 10 carbon atoms; Ra′¹¹ is a group which forms an aliphatic cyclic group together with a carbon atom having Ra′¹⁰ bonded thereto; and Ra′¹² to Ra′¹⁴ each independently represents a hydrocarbon group.

In the formula (a1-r2-1), as the alkyl group of 1 to 10 carbon atoms for Ra′¹⁰, the same groups as described above for the linear or branched alkyl group for Ra′³ in the formula (a1-r-1) are preferable. In the formula (a1-r2-1), as the aliphatic cyclic group which is formed by Ra′¹¹, the same groups as those described above for the cyclic alkyl group for Ra′³ in the formula (a1-r-1) are preferable.

In the formula (a1-r2-2), it is preferable that Ra′¹² and Ra′¹⁴ each independently represents an alkyl group or 1 to 10 carbon atoms, and it is more preferable that the alkyl group is the same group as the described above for the linear or branched alkyl group for Ra′³ in the formula (a1-r-1), it is still more preferable that the alkyl group is a linear alkyl group of 1 to 5 carbon atoms, and it is particularly preferable that the alkyl group is a methyl group or an ethyl group.

In the formula (a1-r2-2), it is preferable that Ra′¹³ is the same group as described above for the linear, branched or cyclic alkyl group for Ra′³ in the formula (a1-r-1).

Among these, the same cyclic alkyl group as those describe above for Ra′³ is more preferable.

Specific examples of the formula (a1-r2-1) are shown below. The “*” in the formula represents a valence bond.

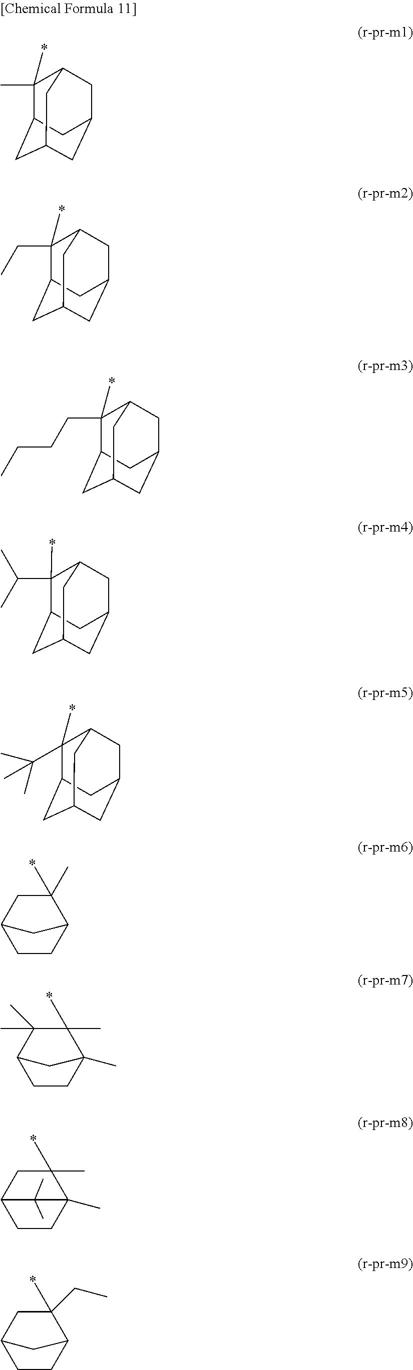

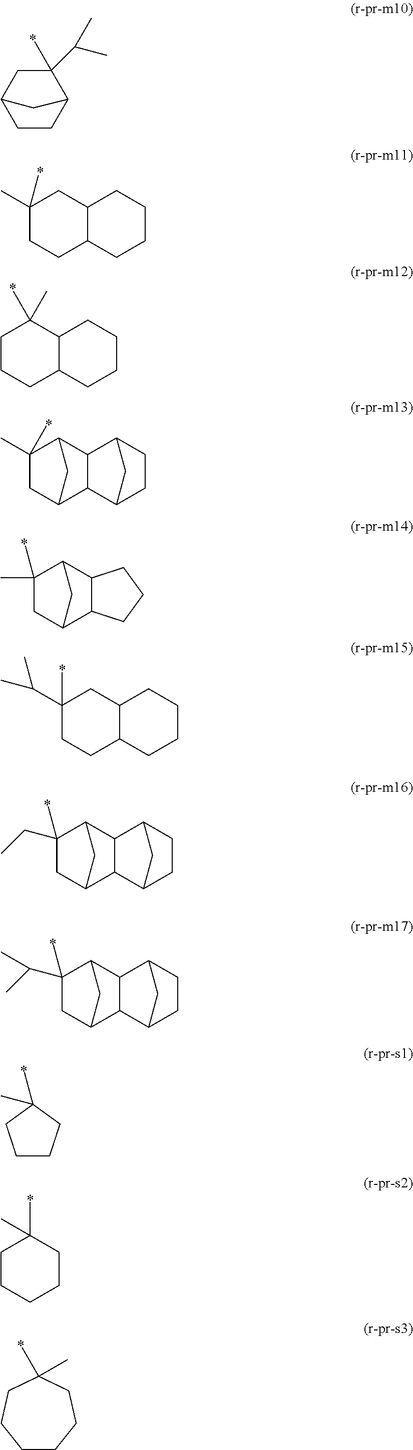

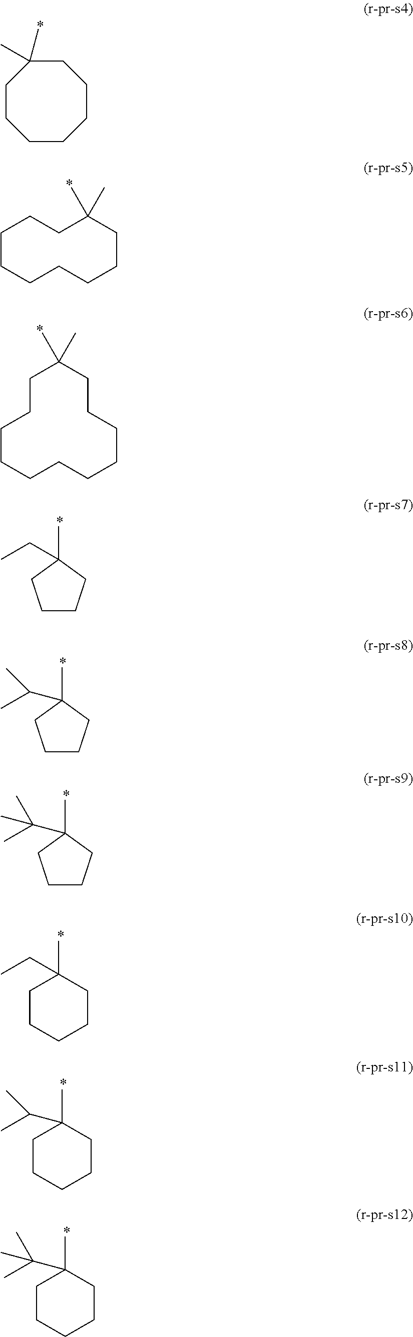

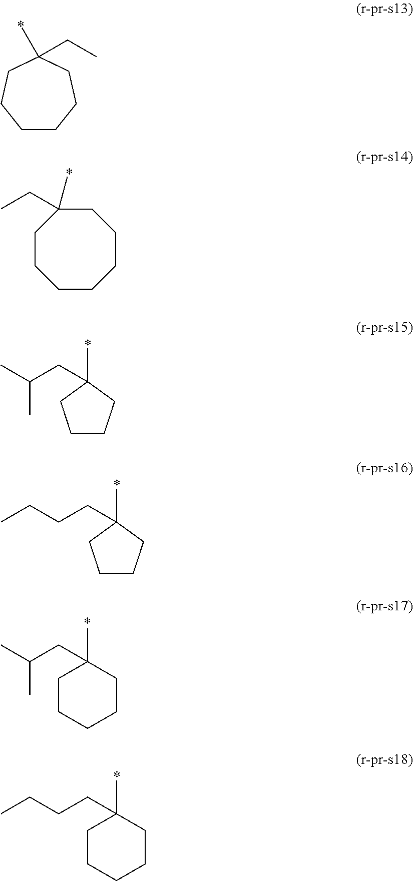

Specific examples of the formula (a1-r2-2) are shown below.

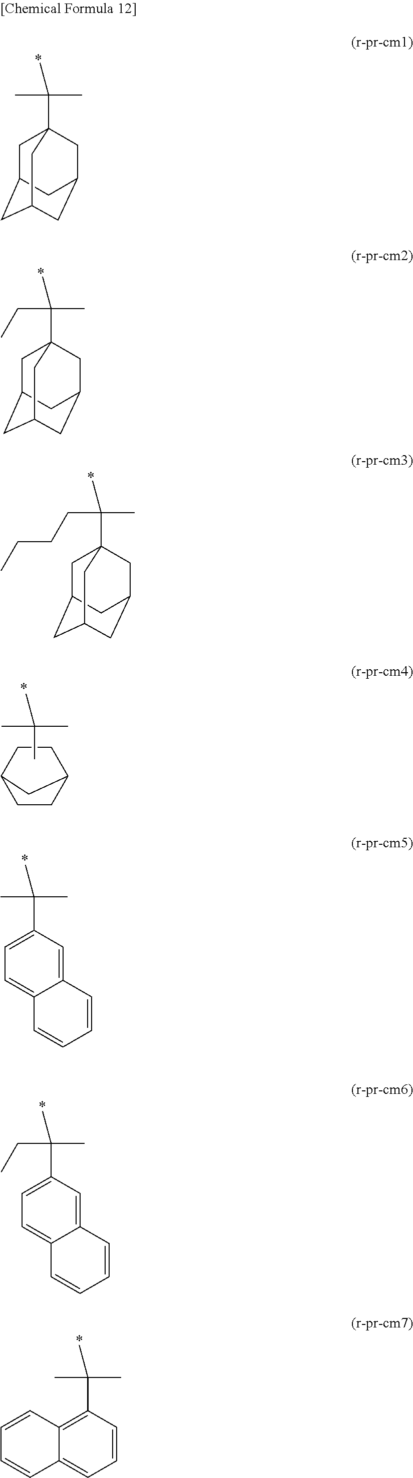

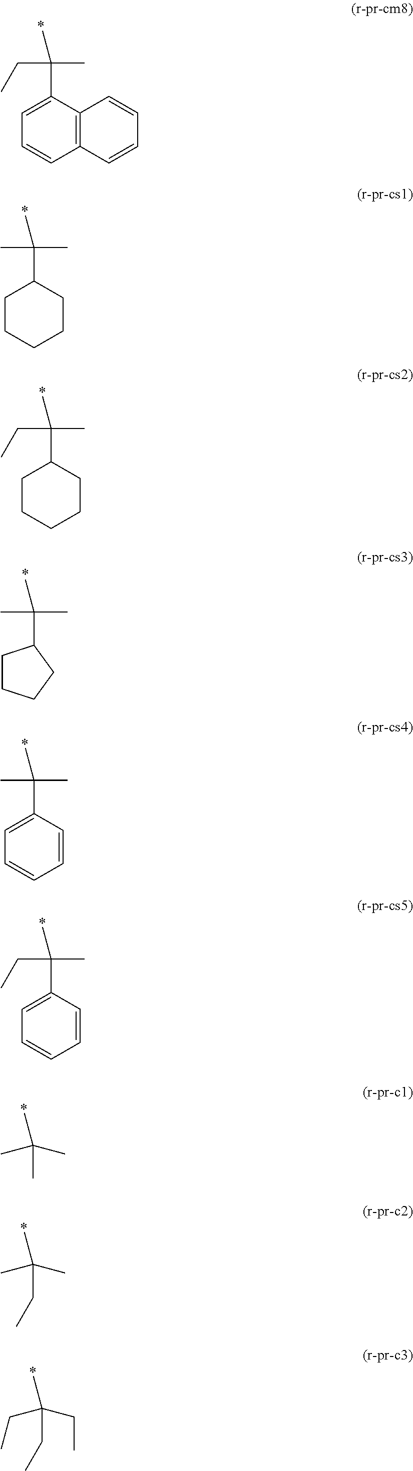

Examples of the acid dissociable group for protecting a hydroxy group as a polar group include the acid dissociable group represented by general formula (a1-r-3) shown below (hereafter, referred to as “tertiary alkyloxycarbonyl-type acid dissociable group”).

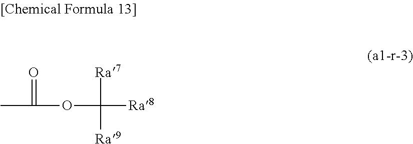

In the formula, Ra′⁷ to Ra′⁹ each represents an alkyl group.

In the formula (a1-r-3), Ra′⁷ to Ra′⁹ is preferably an alkyl group of 1 to 5 carbon atoms, and more preferably an alkyl group of 1 to 3 carbon atoms.

Further, the total number of carbon atoms within the alkyl group is preferably 3 to 7, more preferably 3 to 5, and most preferably 3 or 4.

Examples of the structural unit (a1) include a structural unit derived from an acrylate ester which may have the hydrogen atom bonded to the carbon atom on the α-position substituted with a substituent and contains an acid decomposable group which exhibits increased polarity by the action of acid; a structural unit derived from hydroxystyrene or a hydroxystyrene derivative in which at least a part of the hydrogen atom of the hydroxy group is protected with a substituent containing an acid decomposable group; and a structural unit derived from vinylbenzoic acid or a vinylbenzoic acid derivative in which at least a part of the hydrogen atom within —C(═O)—OH is protected with a substituent containing an acid decomposable group.

As the structural unit (a1), a structural unit derived from an acrylate ester which may have the hydrogen atom bonded to the carbon atom on the α-position substituted with a substituent is preferable.

As the structural unit (a1), structural units represented by general formulas (a1-1) and (a1-2) shown below are preferable.

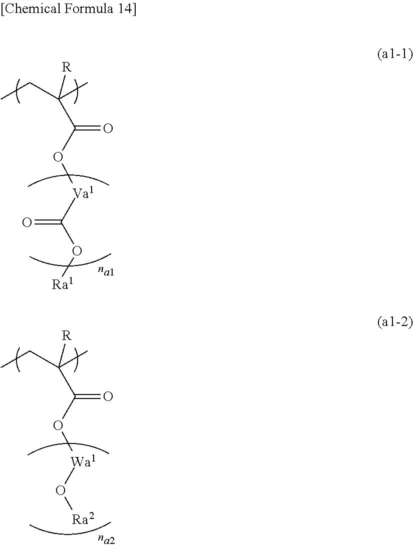

In the formulae, R represents a hydrogen atom, an alkyl group of 1 to 5 carbon atoms or a halogenated alkyl group of 1 to 5 carbon atoms; Va¹ represents a divalent linking group which may contain a linking group selected from the group consisting of an ether bond, an urethane bond and an amide bond; nₐ₁ represents an integer of 0 to 2; Ra¹ represents an acid dissociable group represented by the aforementioned formula (a1-r-1) or (a1-r-2);

Wa¹ represents a hydrocarbon group having a valency of nₐ₂+1; nₐ₂ represents 1 to 3; and

Ra² represents an acid dissociable group represented by the aforementioned formula (a1-r-1) or (a1-r-3);

In general formula (a1-1), as the alkyl group of 1 to 5 carbon atoms, a linear or branched alkyl group of 1 to 5 carbon atoms is preferable, and specific examples include a methyl group, an ethyl group, a propyl group, an isopropyl group, an n-butyl group, an isobutyl group, a tert-butyl group, a pentyl group, an isopentyl group and a neopentyl group. The halogenated alkyl group of 1 to 5 carbon atoms is a group in which part or all of the hydrogen atoms of the aforementioned alkyl group of 1 to 5 carbon atoms have been substituted with halogen atoms. Examples of the halogen atom include a fluorine atom, a chlorine atom, a bromine atom and an iodine atom, and a fluorine atom is particularly desirable.

As R, a hydrogen atom, an alkyl group of 1 to 5 carbon atoms or a fluorinated alkyl group of 1 to 5 carbon atoms is preferable, and a hydrogen atom or a methyl group is particularly desirable in terms of industrial availability.

The hydrocarbon group for Va¹ may be either an aliphatic hydrocarbon group or an aromatic hydrocarbon group. An “aliphatic hydrocarbon group” refers to a hydrocarbon group that has no aromaticity. The aliphatic hydrocarbon group as the divalent hydrocarbon group for Va¹ may be either saturated or unsaturated. In general, the aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

Further, as the group for Va¹, a group in which the aforementioned divalent hydrocarbon group has been bonded via an ether bond, urethane bond or amide bond can be mentioned.

The linear or branched aliphatic hydrocarbon group preferably has 1 to 10 carbon atoms, more preferably 1 to 6, still more preferably 1 to 4, and most preferably 1 to 3.

As the linear aliphatic hydrocarbon group, a linear alkylene group is preferable, and specific examples include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, a branched alkylene group is preferable, and specific examples include alkylalkylene groups, e.g., alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

As examples of the aliphatic hydrocarbon group containing a ring in the structure thereof, an alicyclic hydrocarbon group (a group in which two hydrogen atoms have been removed from an aliphatic hydrocarbon ring), a group in which the alicyclic hydrocarbon group is bonded to the terminal of a linear or branched aliphatic hydrocarbon group, and a group in which the alicyclic hydrocarbon group is interposed within a linear or branched aliphatic hydrocarbon group, can be given. As the linear or branched aliphatic hydrocarbon group, the same groups as those described above can be used.

The alicyclic hydrocarbon group preferably has 3 to 20 carbon atoms, and more preferably 3 to 12 carbon atoms.

The alicyclic hydrocarbon group may be either a monocyclic group or a polycyclic group. As the monocyclic alicyclic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic alicyclic hydrocarbon group, a group in which two hydrogen atoms have been removed from a polycycloalkane is preferable, and the polycycloalkane preferably has 7 to 12 carbon atoms. Examples of the polycycloalkane include adamantane, norbornane, isobornane, tricyclodecane and tetracyclododecane.

The aromatic hydrocarbon group is a hydrocarbon group having an aromatic ring.

The aromatic hydrocarbon group as the divalent hydrocarbon group for Va¹ preferably has 3 to 30 carbon atoms, more preferably 5 to 30, still more preferably 5 to 20, still more preferably 6 to 15, and most preferably 6 to 10. Here, the number of carbon atoms within a substituent(s) is not included in the number of carbon atoms of the aromatic hydrocarbon group.

Examples of the aromatic ring contained in the aromatic hydrocarbon group include aromatic hydrocarbon rings, such as benzene, biphenyl, fluorene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom.

Specific examples of the aromatic hydrocarbon group include a group in which two hydrogen atoms have been removed from the aforementioned aromatic hydrocarbon ring (arylene group); and a group in which one hydrogen atom has been removed from the aforementioned aromatic hydrocarbon ring (aryl group) and one hydrogen atom has been substituted with an alkylene group (for example, a group in which one hydrogen atom has been removed from an aryl group within an arylalkyl group such as a benzyl group, a phenethyl group, a 1-naphthylmethyl group, a 2-naphthylmethyl group, a 1-naphthylethyl group, or a 2-naphthylethyl group). The alkylene group (alkyl chain within the arylalkyl group) preferably has 1 to 4 carbon atoms, more preferably 1 or 2, and most preferably 1.

In the aforementioned formula (a1-2), the hydrocarbon group for Wa¹ having a valency of nₐ₂+1 may be either an aliphatic hydrocarbon group or an aromatic hydrocarbon group. The aliphatic hydrocarbon group refers to a hydrocarbon group that has no aromaticity, and may be either saturated or unsaturated, but is preferably saturated. Examples of the aliphatic hydrocarbon group include a linear or branched aliphatic hydrocarbon group, an aliphatic hydrocarbon group containing a ring in the structure thereof, and a combination of the linear or branched aliphatic hydrocarbon group and the aliphatic hydrocarbon group containing a ring in the structure thereof. As the specific examples thereof, the same groups as those described above for Va¹ in the aforementioned formula (a1-1) can be mentioned.

The valency of nₐ₂+1 is preferably divalent, trivalent or tetravalent, and divalent or trivalent is more preferable.

As the structural unit represented by the aforementioned formula (a1-2), a structural unit represented by general formula (a1-2-01) shown below is desirable.

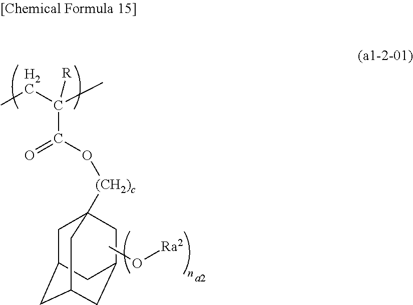

In the formula (a1-2-01), Ra² represents an acid dissociable group represented by the aforementioned formulae (a1-r-1) or (a1-r-3); nₐ₂ is an integer of 1 to 3, preferably 1 or 2, and more preferably 1; c is an integer of 0 to 3, preferably 0 or 1, and more preferably 1; and R is the same as defined above.

Specific examples of the structural units (a1-1) and (a1-2) are shown below. In the formulas shown below, R^{α} represents a hydrogen atom, a methyl group or a trifluoromethyl group.

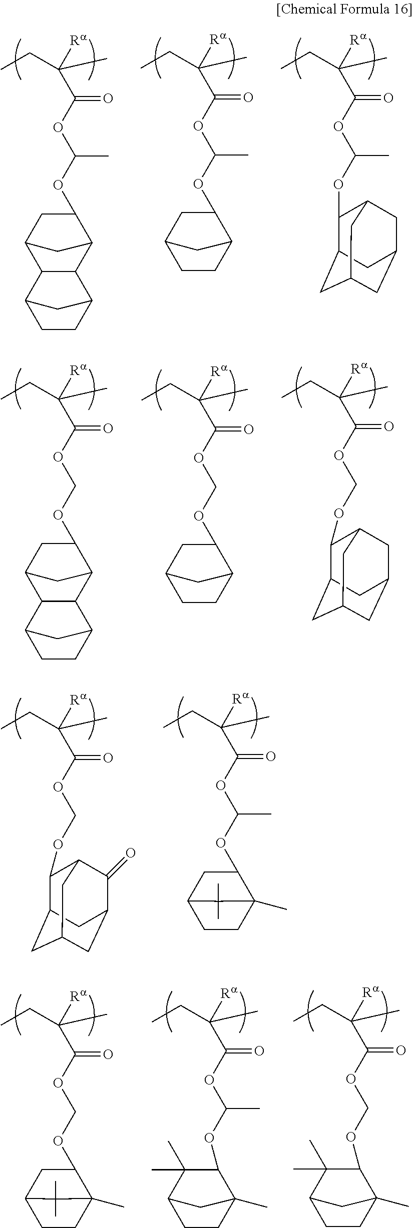

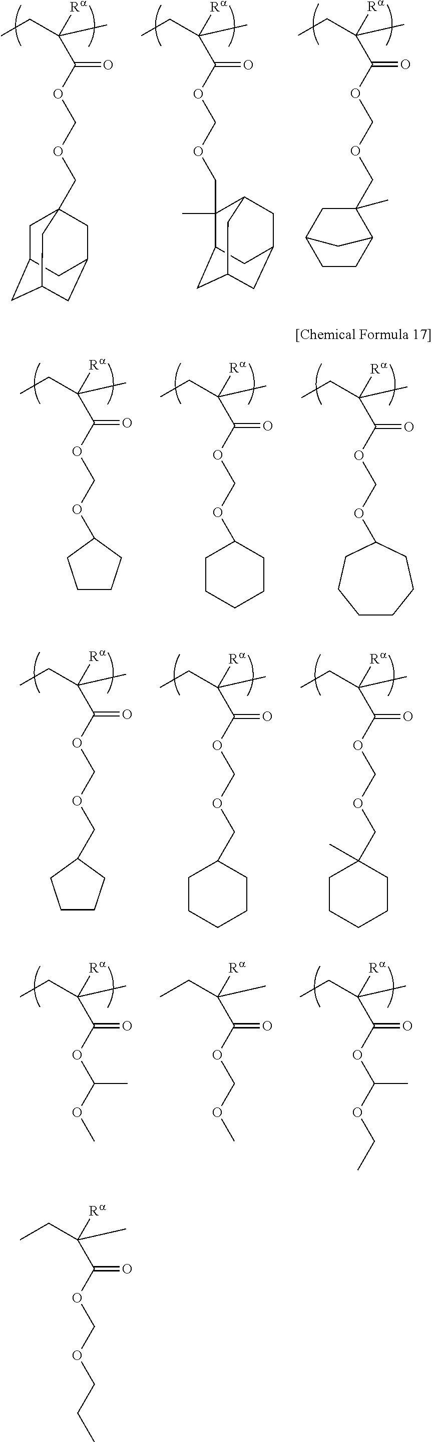

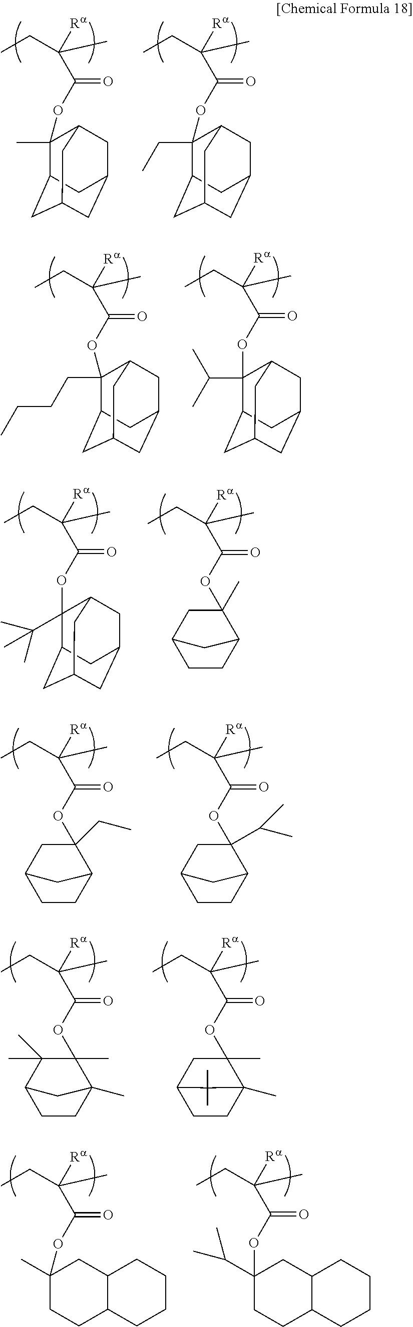

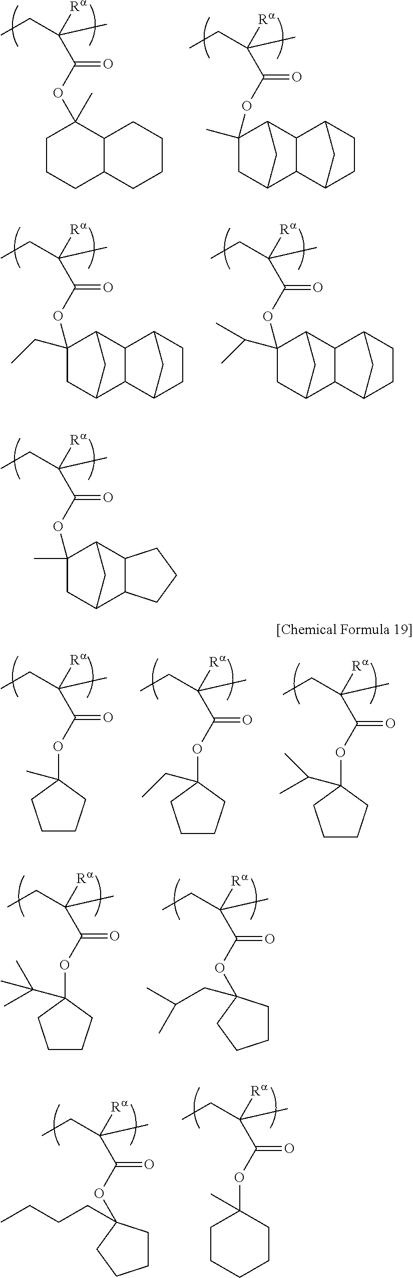

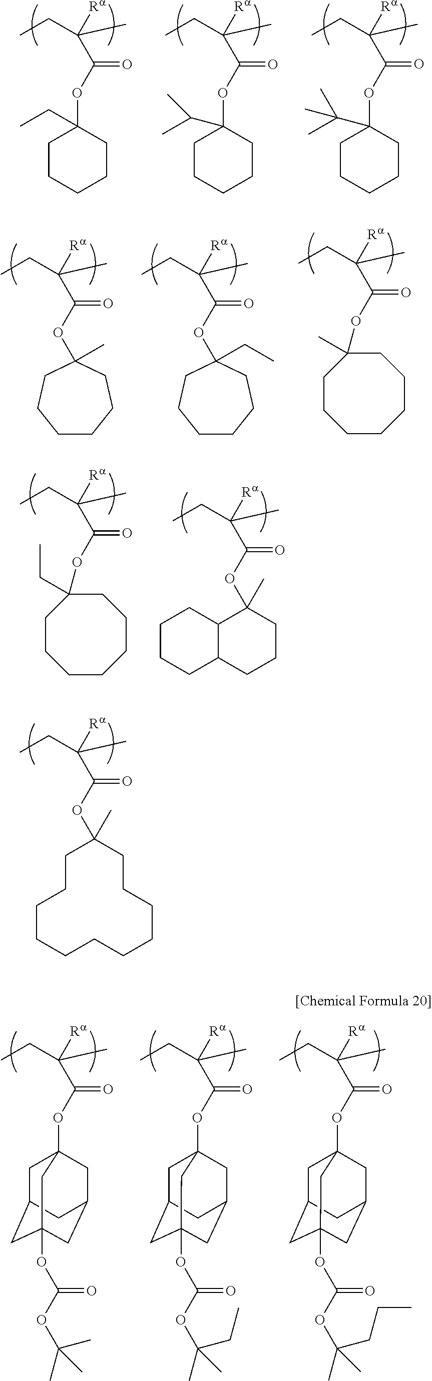

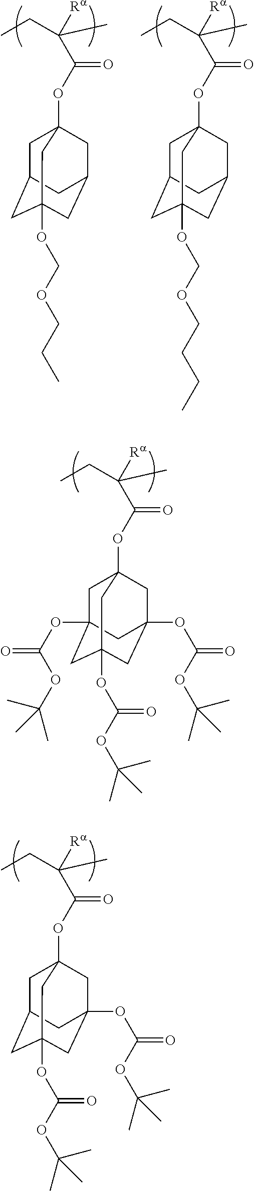

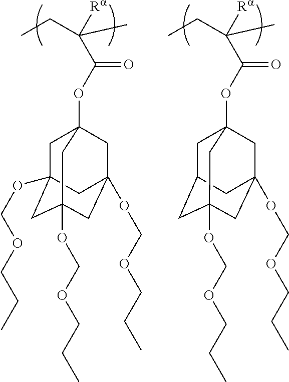

In the component (A′), the amount of the structural unit (a1) based on the combined total of all structural units constituting the component (A′) is preferably 5 to 80 mol %, more preferably 10 to 75 mol %, and still more preferably 20 to 70 mol %. When the amount of the structural unit (a1) is at least as large as the lower limit of the above-mentioned range, various lithography properties such as sensitivity, resolution, roughness and the like are improved. On the other hand, when the amount of the structural unit (a1) is no more than the upper limit of the above-mentioned range, a good balance can be achieved with the other structural units.

(Other Structural Units)

In the present invention, the component (A1′) may also include the structural units (a2) to (a4) described later.

(Structural Unit (a2))

The structural unit (a2) is a structural unit which contains a lactone-containing cyclic group, an —SO₂— containing cyclic group or a carbonate-containing cyclic group, and which does not fall under the definition of the structural unit (a0).

When the component (A1′) is used for forming a resist film, the lactone-containing cyclic group or the carbonate-containing cyclic group within the structural unit (a2) is effective in improving the adhesion between the resist film and the substrate.

The aforementioned structural unit (a1) which contains a lactone-containing cyclic group or a carbonate-containing cyclic group falls under the definition of the structural unit (a2); however, such a structural unit is regarded as a structural unit (a1), and does not fall under the definition of the structural unit (a2).

When the component (A1′) is used for forming a resist film, the —SO₂— containing cyclic group within the structural unit (a2) is effective in improving the adhesion between the resist film and the substrate.

The aforementioned structural unit (a1) which contains a —SO₂— containing cyclic group falls under the definition of the structural unit (a2); however, such a structural unit is regarded as a structural unit (a1), and does not fall under the definition of the structural unit (a2).

As the structural unit (a2), a structural unit derived from an acrylate ester which may have the hydrogen atom bonded to the carbon atom on the α-position substituted with a substituent is preferable. The structural unit (a2) is preferably a structural unit represented by general formula (a2-1) shown below.

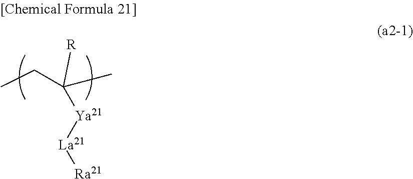

In the formula, R represents a hydrogen atom, an alkyl group of 1 to 5 carbon atoms or a halogenated alkyl group of 1 to 5 carbon atoms; Ya²¹ represents a single bond or a divalent linking group; La²¹ represents —O—, —COO—, —CON(R′)—, —OCO—, —CONHCO— or —CONHCS; and R′ represents a hydrogen atom or a methyl group, provided that when La²¹ represents —O—, Ya²¹ does not represents —CO—; and Ra²¹ represents a lactone-containing cyclic group, a carbonate-containing cyclic group or an —SO₂— containing cyclic group.

The divalent linking group for Ya²¹ is not particularly limited, and preferable examples thereof include a divalent hydrocarbon group which may have a substituent and a divalent linking group containing a hetero atom.

(Divalent Hydrocarbon Group which May have a Substituent)

The hydrocarbon group as a divalent linking group may be either an aliphatic hydrocarbon group or an aromatic hydrocarbon group.

An “aliphatic hydrocarbon group” refers to a hydrocarbon group that has no aromaticity. The aliphatic hydrocarbon group may be saturated or unsaturated. In general, the aliphatic hydrocarbon group is preferably saturated.

Examples of the aliphatic hydrocarbon group include a linear or branched aliphatic hydrocarbon group, and an aliphatic hydrocarbon group containing a ring in the structure thereof can be given. Specific examples thereof include the same group as exemplified above for Va¹ in the aforementioned formula (a1-1).

The linear or branched aliphatic hydrocarbon group may or may not have a substituent. Examples of the substituent include a fluorine atom, a fluorinated alkyl group of 1 to 5 carbon atoms, and a carbonyl group.

As examples of the aliphatic hydrocarbon group containing a ring in the structure thereof, a cyclic aliphatic hydrocarbon group which may have a substituent containing a hetero atom in the ring structure thereof (a group in which two hydrogen atoms have been removed from an aliphatic hydrocarbon ring), a group in which the cyclic aliphatic hydrocarbon group is bonded to the terminal of a linear or branched aliphatic hydrocarbon group, and a group in which the cyclic aliphatic hydrocarbon group is interposed within a linear or branched aliphatic hydrocarbon group, can be given. As the linear or branched aliphatic hydrocarbon group, the same groups as those described above can be used.

The cyclic aliphatic hydrocarbon group preferably has 3 to 20 carbon atoms, and more preferably 3 to 12 carbon atoms.

Specific examples of the cyclic aliphatic hydrocarbon group include the same group as exemplified above for Va¹ in the aforementioned formula (a1-1).

The cyclic aliphatic hydrocarbon group may or may not have a substituent. Examples of the substituent include an alkyl group, an alkoxy group, a halogen atom, a halogenated alkyl group, a hydroxyl group and a carbonyl group.

The alkyl group as the substituent is preferably an alkyl group of 1 to 5 carbon atoms, and a methyl group, an ethyl group, a propyl group, an n-butyl group or a tert-butyl group is most desirable.

The alkoxy group as the substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom for the substituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

In the cyclic aliphatic hydrocarbon group, part of the carbon atoms constituting the ring structure thereof may be substituted with a substituent containing a hetero atom. The substituent containing a hetero atom is preferably —O—, —C(═O)—O—, —S—, —S(═O)₂—, or —S(═O)₂—O—.

Specific examples of the aromatic hydrocarbon group as a divalent hydrocarbon group include the same group as those exemplified above for Va¹ in the aforementioned formula (a1-1).

With respect to the aromatic hydrocarbon group, the hydrogen atom within the aromatic hydrocarbon group may be substituted with a substituent. For example, the hydrogen atom bonded to the aromatic ring within the aromatic hydrocarbon group may be substituted with a substituent. Examples of substituents include an alkyl group, an alkoxy group, a halogen atom, a halogenated alkyl group, and a hydroxyl group.

The alkyl group as the substituent is preferably an alkyl group of 1 to 5 carbon atoms, and a methyl group, an ethyl group, a propyl group, an n-butyl group or a tert-butyl group is most desirable.

As the alkoxy group, the halogen atom and the halogenated alkyl group for the substituent, the same groups as the aforementioned substituent groups for substituting a hydrogen atom within the cyclic aliphatic hydrocarbon group can be used.

(Divalent Linking Group Containing a Hetero Atom)

With respect to a divalent linking group containing a hetero atom, a hetero atom is an atom other than carbon and hydrogen, and examples thereof include an oxygen atom, a nitrogen atom, a sulfur atom and a halogen atom.

In the case where Ya²¹ represents a divalent linking group containing a hetero atom, preferable examples of the linking group include —O—, —C(═O)—O—, —C(═O)—, —O—C(═O)—O—, —C(═O)—NH—, —NH—, —NH—C(═NH)— (wherein H may be substituted with a substituent such as an alkyl group or an acyl group), —S—, —S(═O)₂—, —S(═O)₂—O— and a group represented by general formula —Y²¹—O—Y²²—, —Y²¹—O—, —Y²¹—C(═O)—O—, —[Y²¹—(═O)—O]_{m′}—Y²²— or —Y²¹—O—C(═O)—Y²²—[in the formulas, each of Y²¹ and Y²² independently represents a divalent hydrocarbon group which may have a substituent, O represents an oxygen atom, and m′ represents an integer of 0 to 3].

When the divalent linking group containing a hetero atom represents —C(═O)—NH—, —NH—, or —NH—C(═NH)—, H may be substituted with a substituent such as an alkyl group, an acyl group or the like. The substituent (an alkyl group, an acyl group or the like) preferably has 1 to 10 carbon atoms, more preferably 1 to 8, and most preferably 1 to 5.

In formula —Y²¹—O—Y²²—, —Y²¹—O—, —Y²¹—C(═O)—O—, —[Y²¹—C(═O)—O]_{m′}—Y²²— or —Y²¹—O—C(═O)—Y²²—, Y²¹ and Y²² each independently represents a divalent hydrocarbon group which may have a substituent. Examples of the divalent hydrocarbon group include the same groups as those described above as the “divalent hydrocarbon group which may have a substituent” in the explanation of the aforementioned divalent linking group.

As Y²¹, a linear aliphatic hydrocarbon group is preferable, more preferably a linear alkylene group, still more preferably a linear alkylene group of 1 to 5 carbon atoms, and a methylene group or an ethylene group is particularly desirable.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group represented by the formula —[Y²¹—C(═O)—O]_{m′}, —Y²², m′ represents an integer of 0 to 3, preferably an integer of 0 to 2, more preferably 0 or 1, and particularly preferably 1. Namely, it is particularly desirable that the group represented by the formula —[Y²¹—C(═O)—O]_{m′}, —Y²²— is a group represented by the formula —Y²¹—C(═O)—O—Y²²—. Among these, a group represented by the formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

In the present invention, Ya²¹ preferably represents an ester bond [—C(═O)—O—], an ether bond (—O—), a linear or branched alkylene group, a combination of these, or a single bond.

In the formula (a2-1), Ra²¹ represents a lactone-containing cyclic group, a carbonate-containing cyclic group or an —SO₂— containing cyclic group.

The term “lactone-containing cyclic group” refers to a cyclic group including a ring containing a —O—C(═O)— structure (lactone ring). The term “lactone ring” refers to a single ring containing a —O—C(═O)— structure, and this ring is counted as the first ring. A lactone-containing cyclic group in which the only ring structure is the lactone ring is referred to as a monocyclic group, and groups containing other ring structures are described as polycyclic groups regardless of the structure of the other rings. The lactone-containing cyclic group may be either a monocyclic group or a polycyclic group.

The lactone-containing cyclic group for Ra²¹ is not particularly limited, and an arbitrary structural unit may be used. Specific examples include groups represented by general formulas (a2-r-1) to (a2-r-7) shown below. Hereafter, “*” represents a valence bond.

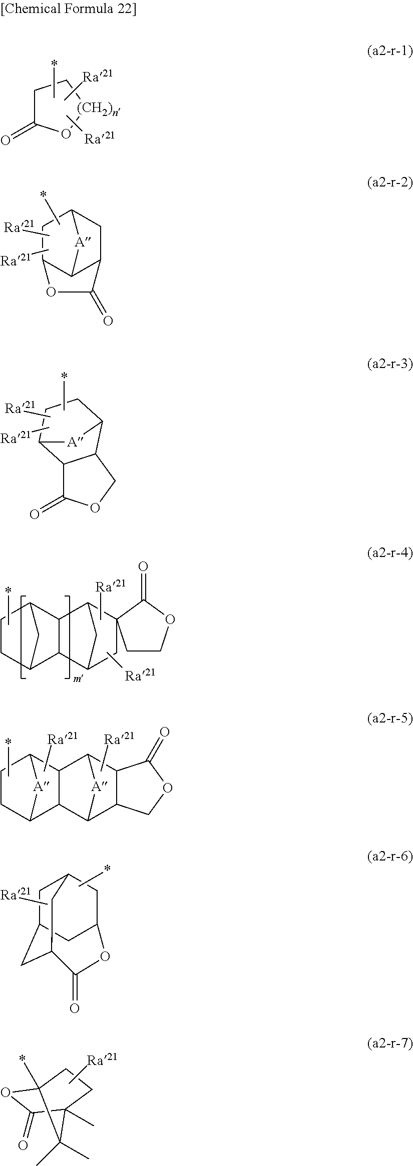

In the formulas, each Ra′²¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; n′ represents an integer of 0 to 2; and m′ represents 0 or 1.

In general formulas (a2-r-1) to (a2-r-7), A″ represents an oxygen atom, a sulfonyl group or an alkylene group of 1 to 5 carbon atoms which may contain an oxygen atom (—O—) or a sulfur atom (—S—). As the alkylene group of 1 to 5 carbon atoms for A″, a linear or branched alkylene group is preferable, and examples thereof include a methylene group, an ethylene group, an n-propylene group and an isopropylene group. Examples of alkylene groups that contain an oxygen atom or a sulfur atom include the aforementioned alkylene groups in which —O— or —S— is bonded to the terminal of the alkylene group or present between the carbon atoms of the alkylene group. Specific examples of such alkylene groups include —O—CH₂—, —CH₂—O—CH₂—, —S—CH₂— and —CH₂—S—CH₂—. As A″, an alkylene group of 1 to 5 carbon atoms or —O— is preferable, more preferably an alkylene group of 1 to 5 carbon atoms, and most preferably a methylene group. Each Ra′²¹ independently represents an alkyl group, an alkoxy group, a halogen atom, a halogenated alkyl group, —COOR″, —OC(═O)R″, a hydroxyalkyl group or a cyano group.

The alkyl group for Ra′²¹ is preferably an alkyl group of 1 to 5 carbon atoms.

The alkoxy group for Ra′²¹ is preferably an alkoxy group of 1 to 6 carbon atoms.

Further, the alkoxy group is preferably a linear or branched alkoxy group. Specific examples of the alkoxy groups include the aforementioned alkyl groups for Ra′²¹ having an oxygen atom (—O—) bonded thereto.

As examples of the halogen atom for Ra′²¹, a fluorine atom, chlorine atom, bromine atom and iodine atom can be given. Among these, a fluorine atom is preferable.

Examples of the halogenated alkyl group for Ra′²¹ include groups in which part or all of the hydrogen atoms within the aforementioned alkyl groups for Ra′²¹ has been substituted with the aforementioned halogen atoms. As the halogenated alkyl group, a fluorinated alkyl group is preferable, and a perfluoroalkyl group is particularly desirable.

With respect to —COOR″ and —OC(═O)R″ for Ra′²¹, R″ represents a hydrogen atom or an alkyl group.

Specific examples of the groups represented by the aforementioned general formulas (a2-r-1) to (a2-r-7) are shown below.

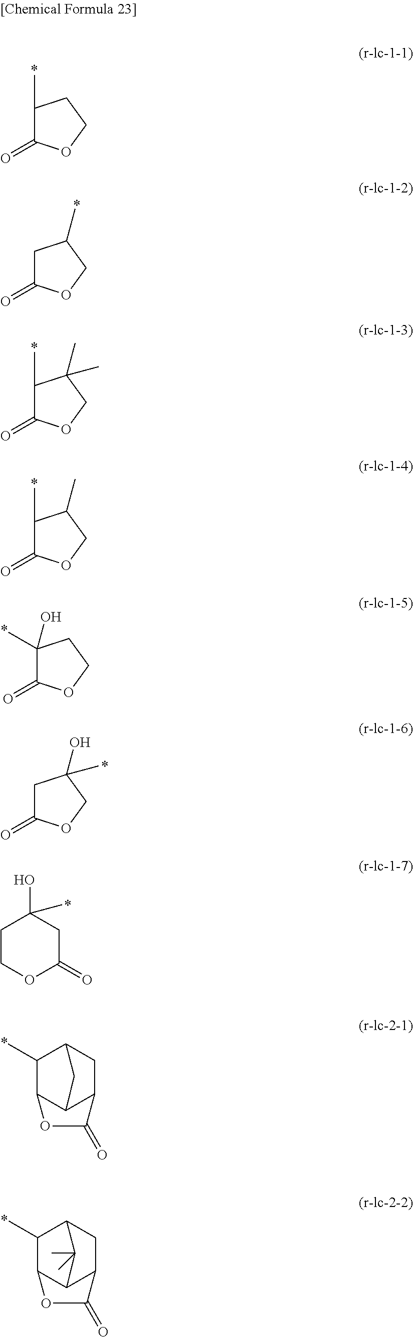

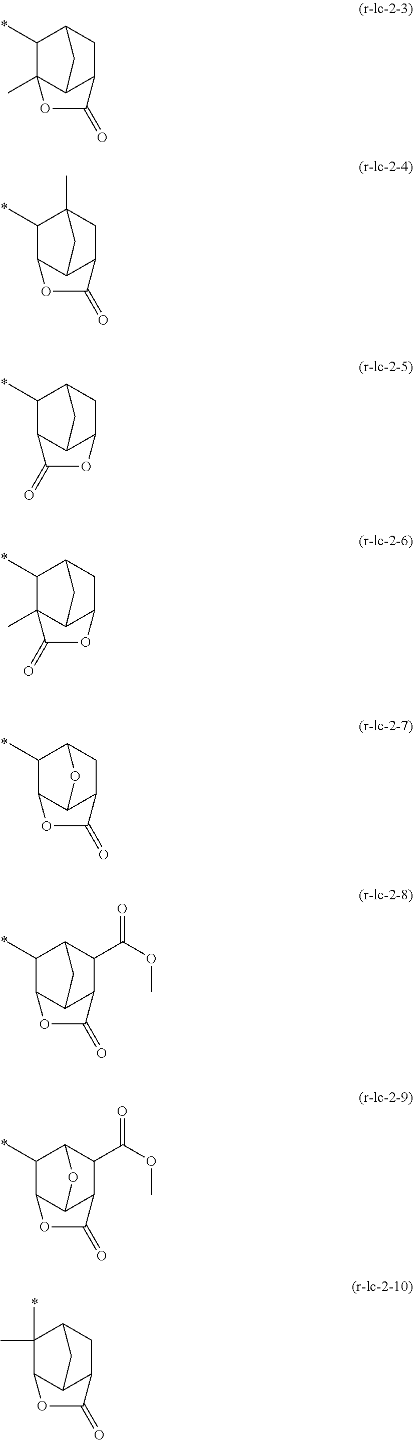

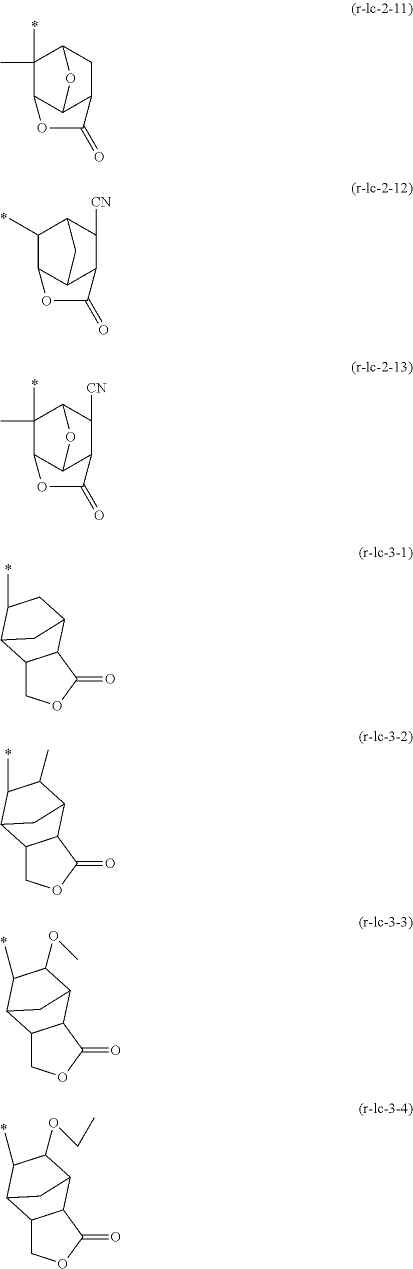

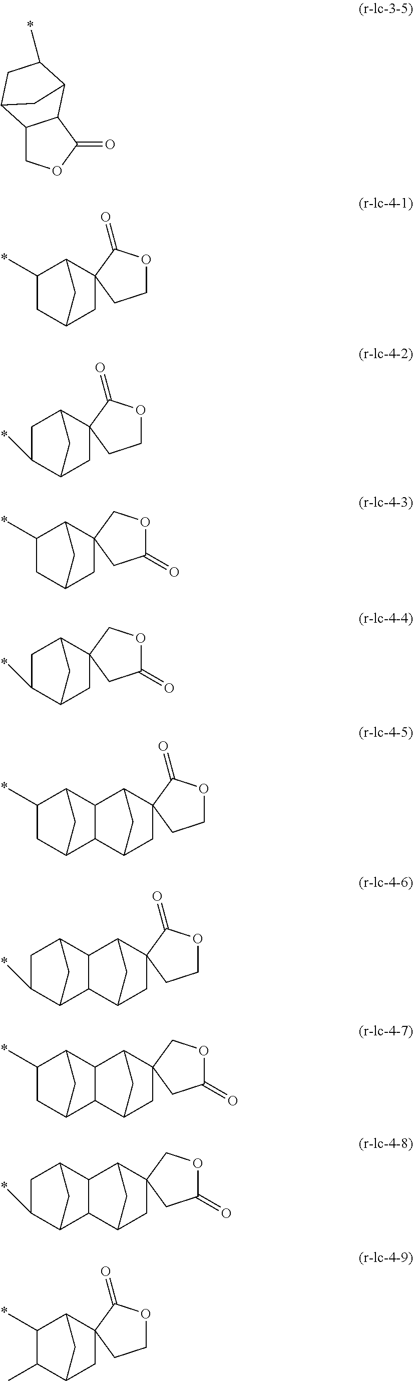

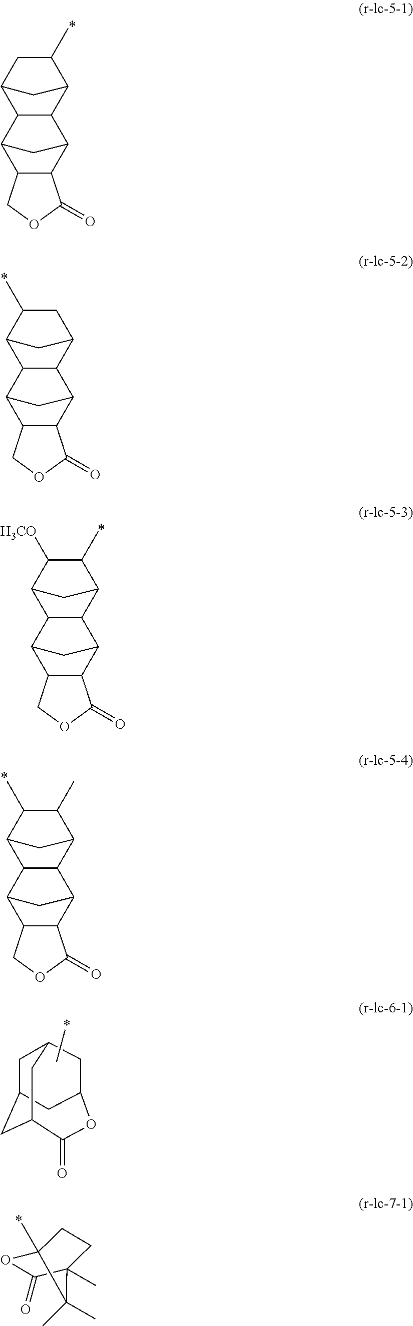

An “—SO₂— containing cyclic group” refers to a cyclic group having a ring containing —SO₂— within the ring structure thereof, i.e., a cyclic group in which the sulfur atom (S) within —SO₂— forms part of the ring skeleton of the cyclic group. The ring containing —SO₂— within the ring skeleton thereof is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings. The —SO₂— containing cyclic group may be either a monocyclic group or a polycyclic group.

As the —SO₂— containing cyclic group as a cyclic hydrocarbon group for Ra²¹, a cyclic group containing —O—SO₂— within the ring skeleton thereof, i.e., a cyclic group containing a sultone ring in which —O—S— within the —O—SO₂— group forms part of the ring skeleton thereof is particularly desirable. More specific examples of the —SO₂— containing cyclic group include groups represented by general formulas (a5-r-1) to (a5-r-4) shown below.

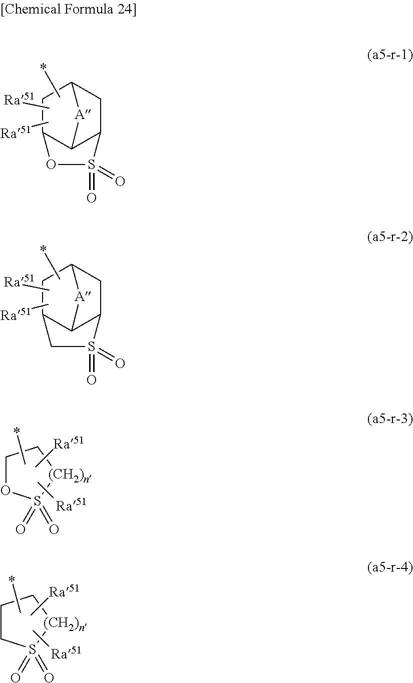

In the formulas, each Ra′⁵¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; and n′ represents an integer of 0 to 2.

In general formulas (a5-r-1) to (a5-r-4), A″ is the same as defined for A″ in general formulas (a2-r-1) to (a2-r-7). Examples of the alkyl group, alkoxy group, halogen atom, halogenated alkyl group, —COOR″, —OC(═O)R″ and hydroxyalkyl group for Ra′⁵¹ include the same groups as those described above in the explanation of Ra′²¹ in the general formulas (a2-r-1) to (a2-r-7).

Specific examples of the groups represented by the aforementioned general formulas (a5-r-1) to (a5-r-4) are shown below. In the formulas shown below, “Ac” represents an acetyl group.

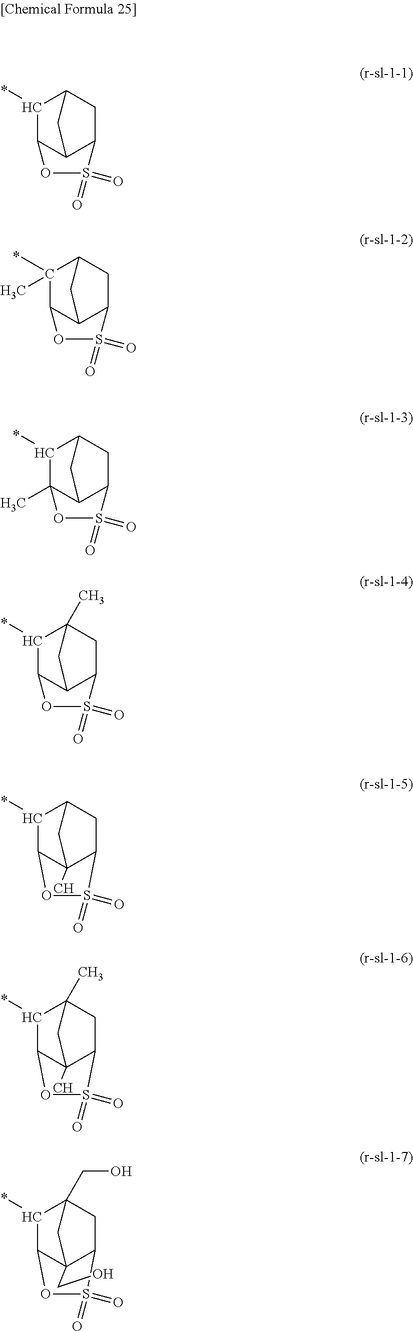

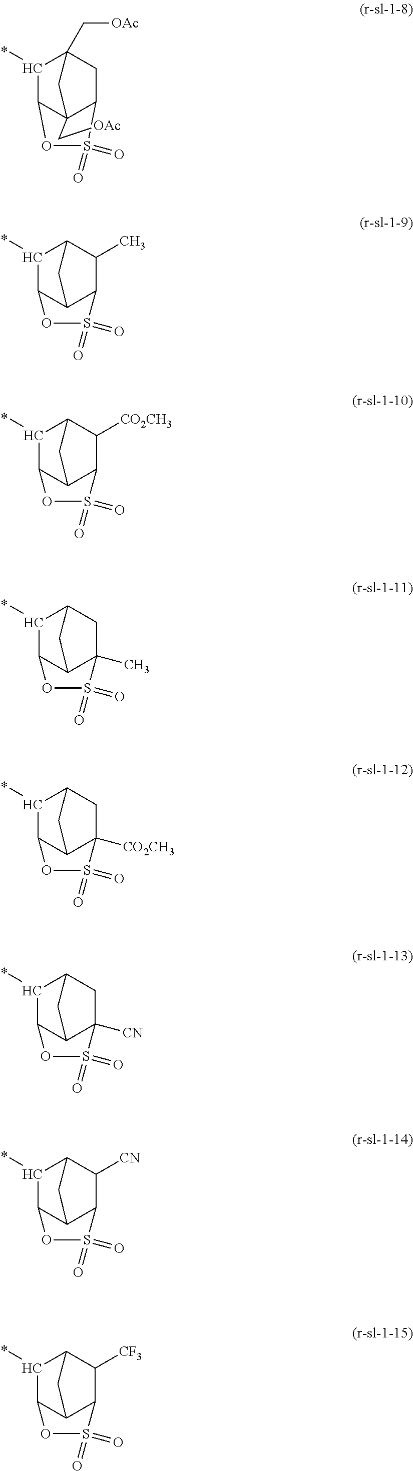

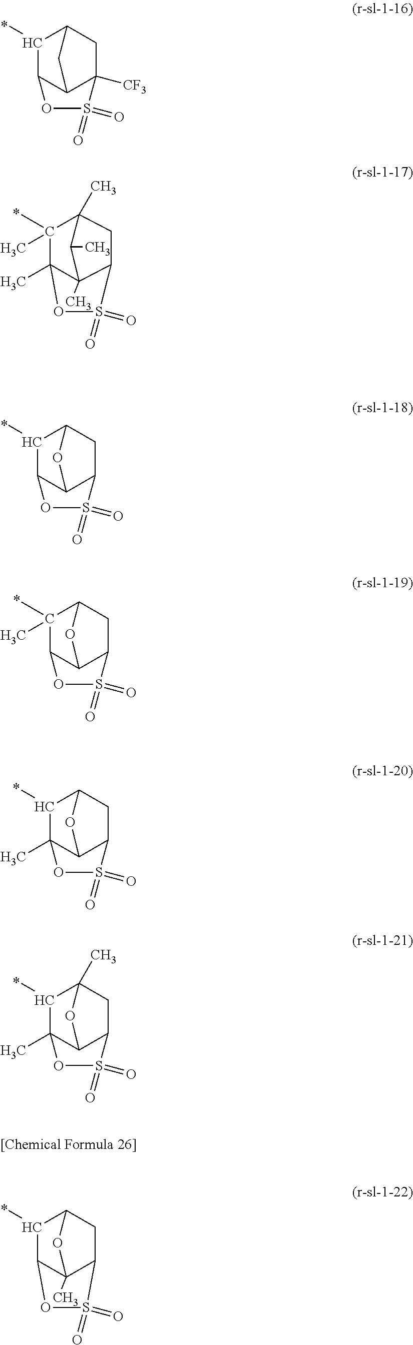

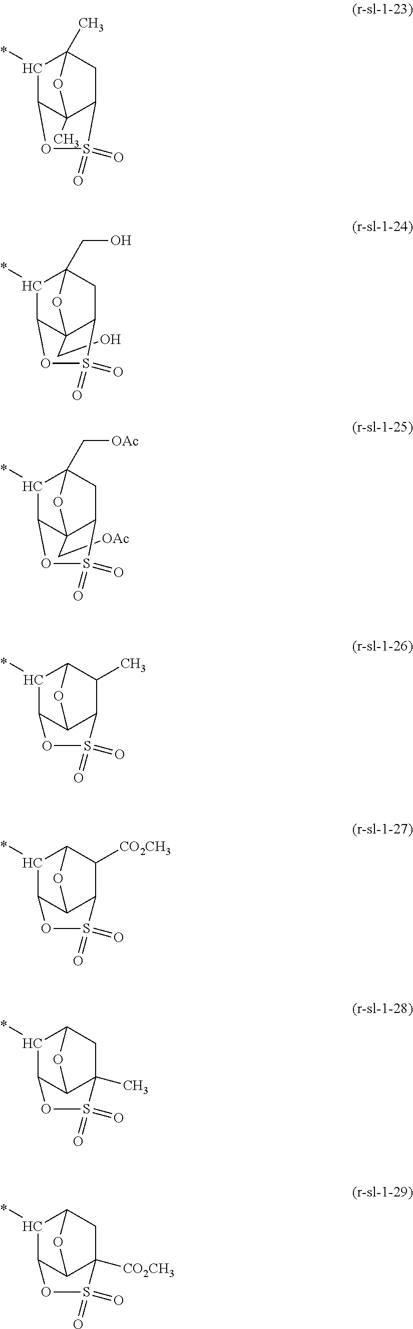

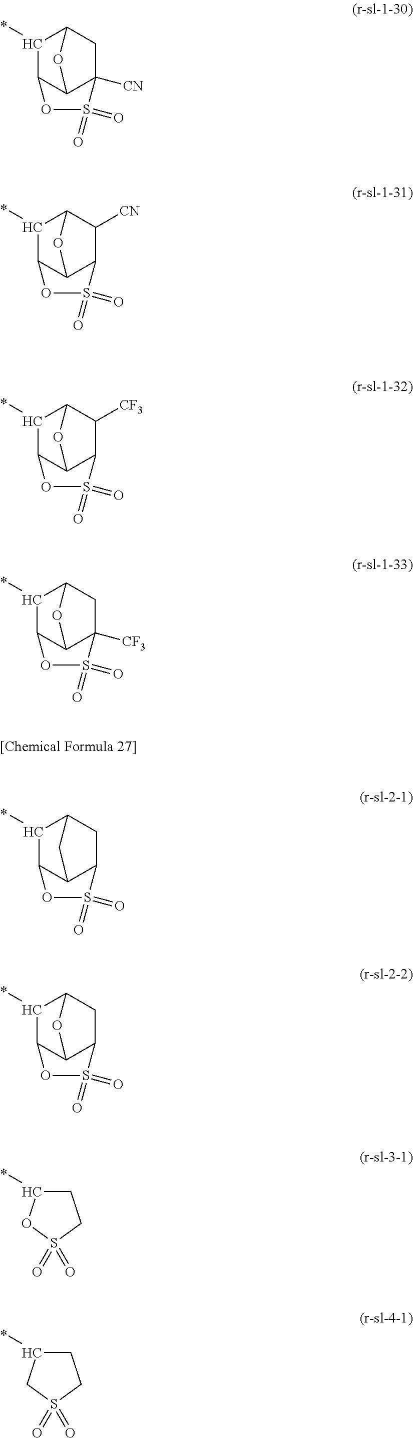

As the —SO₂— containing cyclic group, a group represented by the aforementioned general formula (a5-r-1) is preferable, at least one member selected from the group consisting of groups represented by the aforementioned chemical formulas (r-s1-1-1), (r-s1-1-18), (r-s1-3-1) and (r-s1-4-1) is more preferable, and a group represented by chemical formula (r-s1-1-1) is most preferable.

The term “carbonate-containing cyclic group” refers to a cyclic group including a ring containing a —O—C(═O)—O— structure (carbonate ring) in the ring skeleton thereof. The term “carbonate ring” refers to a single ring containing a —O—C(═O)—O— structure, and this ring is counted as the first ring. A carbonate-containing cyclic group in which the only ring structure is the carbonate ring is referred to as a monocyclic group, and groups containing other ring structures are described as polycyclic groups regardless of the structure of the other rings. The carbonate-containing cyclic group may be either a monocyclic group or a polycyclic group.

The carbonate-containing cyclic group for Ra²¹ as a cyclic hydrocarbon group is not particularly limited, and an arbitrary structural unit may be used. Specific examples include groups represented by general formulas (ax3-r-1) to (ax3-r-3) shown below.

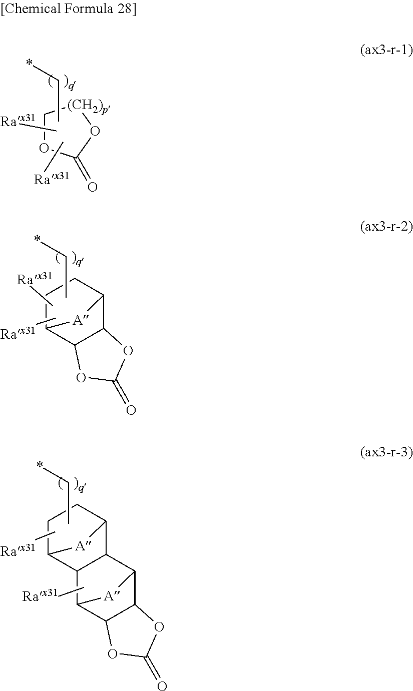

In the formulas, each Ra′^{x31} independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfur atom or an alkylene group of 1 to 5 carbon atoms which may contain an oxygen atom or a sulfur atom; p′ represents an integer of 0 to 3; and q′ represents 0 or 1.

In general formulas (ax3-r-1) to (ax3-r-3), A″ is the same as defined for A″ in general formula (a2-r-1).

Examples of the alkyl group, alkoxy group, halogen atom, halogenated alkyl group, —COOR″, —OC(═O)R″ and hydroxyalkyl group for Ra′³¹ include the same groups as those described above in the explanation of Ra′²¹ in the general formulae (a2-r-1) to (a2-r-7).

Specific examples of the groups represented by the aforementioned general formulas (ax3-r-1) to (ax3-r-3) are shown below.

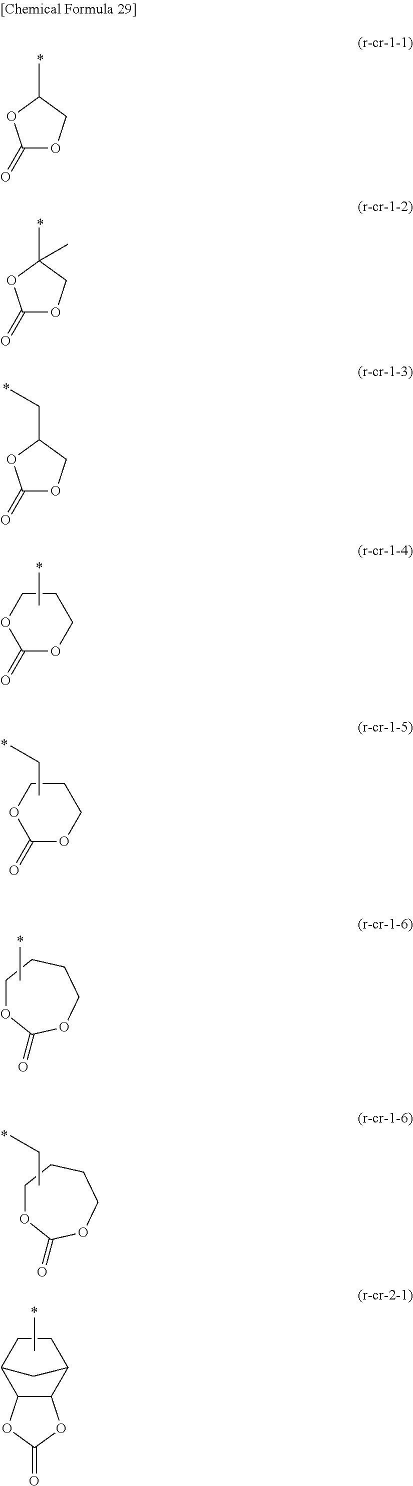

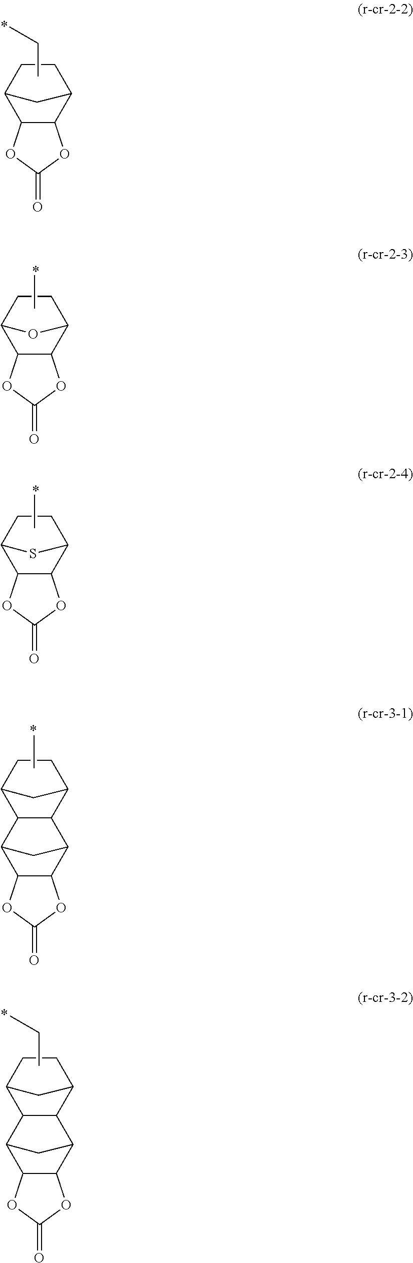

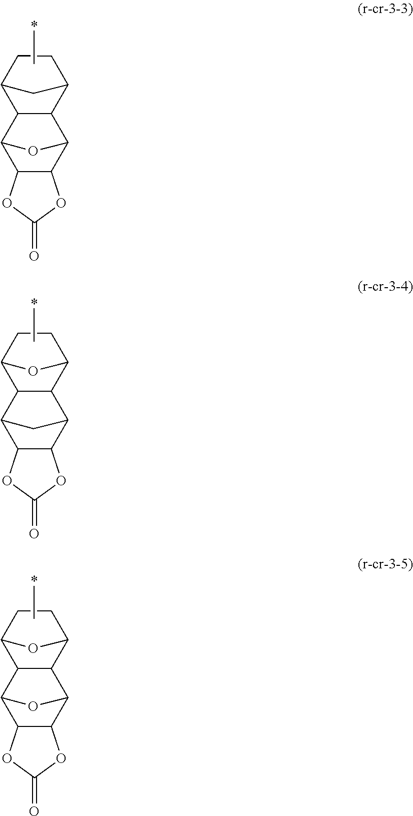

Among the examples shown above, a lactone-containing cyclic group or an —SO₂— containing cyclic group is preferable, a group represented by the general formula (a2-r-1), (a2-r-2) or (a5-r-1) is more preferable, and a group represented by any one of the chemical formulas (r-1c-1-1) to (r-1c-1-7), (r-1c-2-1) to (r-1c-2-13), (r-s1-1-1) and (r-s1-1-18) is still more preferable.

As the structural unit (a2) contained in the component (A1′), 1 type of structural unit may be used, or 2 or more types may be used.

When the component (A1′) contains the structural unit (a2), the amount of the structural unit (a2) based on the combined total of all structural units constituting the component (A1′) is preferably 1 to 80 mol %, more preferably 5 to 70 mol %, still more preferably 10 to 65 mol %, and particularly preferably 10 to 60 mol %. When the amount of the structural unit (a2) is at least as large as the lower limit of the above-mentioned range, the effect of using the structural unit (a2) can be satisfactorily achieved. On the other hand, when the amount of the structural unit (a2) is no more than the upper limit of the above-mentioned range, a good balance can be achieved with the other structural units, and various lithography properties such as DOF and CDU and pattern shape can be improved.

(Structural Unit (a3))

The structural unit (a3) is a structural unit containing a polar group-containing aliphatic hydrocarbon group (provided that the structural units that fall under the definition of structural units (a1), (a0) and (a2) are excluded).

When the component (A1′) includes the structural unit (a3), it is presumed that the hydrophilicity of the component (A1′) is enhanced, thereby contributing to improvement in resolution.

Examples of the polar group include a hydroxyl group, a cyano group, a carboxyl group, or a hydroxyalkyl group in which part of the hydrogen atoms of the alkyl group have been substituted with fluorine atoms, although a hydroxyl group is particularly desirable.

Examples of the aliphatic hydrocarbon group include linear or branched hydrocarbon groups (preferably alkylene groups) of 1 to 10 carbon atoms, and cyclic aliphatic hydrocarbon groups (cyclic groups). These cyclic groups may be either monocyclic or polycyclic, and can be selected appropriately from the multitude of groups that have been proposed for the resins of resist compositions designed for use with ArF excimer lasers. The cyclic group is preferably a polycyclic group, more preferably a polycyclic group of 7 to 30 carbon atoms.

Of the various possibilities, structural units derived from an acrylate ester that includes an aliphatic polycyclic group that contains a hydroxyl group, a cyano group, a carboxyl group or a hydroxyalkyl group in which part of the hydrogen atoms of the alkyl group have been substituted with fluorine atoms, are particularly desirable. Examples of the polycyclic group include groups in which two or more hydrogen atoms have been removed from a bicycloalkane, tricycloalkane, tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, a group in which two or more hydrogen atoms have been removed from adamantane, a group in which two or more hydrogen atoms have been removed from norbornane or a group in which two or more hydrogen atoms have been removed from tetracyclododecane are preferred industrially.

As the structural unit (a3), there is no particular limitation as long as it is a structural unit containing a polar group-containing aliphatic hydrocarbon group, and an arbitrary structural unit may be used.

The structural unit (a3) is preferably a structural unit derived from an acrylate ester which may have the hydrogen atom bonded to the carbon atom on the α-position substituted with a substituent and contains a polar group-containing aliphatic hydrocarbon group.

As the polar group-containing aliphatic hydrocarbon group in the structural unit (a3), groups represented by general formulae (a3-r-1) to (a3-r-3) shown below. The “*” in the formula represents a valence bond.

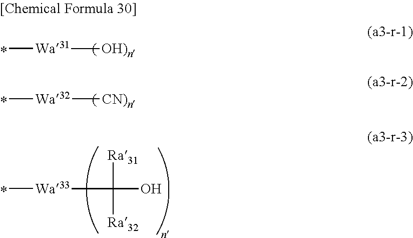

In the formulae, Wa′³¹, Wa′³², and Wa′³³ each independently represents an aliphatic hydrocarbon group having a valency of (n′+1); n′ represents an integer of 1 to 3; and Ra′³¹ and Ra′³² represents a fluorine atom or a fluorinated alkylene group.

In the general formulae (a3-r-1) to (a3-r-3), Wa′³¹, Wa′³², and Wa′³³ each independently represents an aliphatic hydrocarbon group having a valency of (n′+1). The explanation of the aliphatic hydrocarbon group is the same as the explanation of the aliphatic hydrocarbon group in relation to the divalent linking group for Y¹ in formula (a0-1).

In the formulae (a3-r-1) to (a3-r-3), n′ represents an integer of 1 to 3.

In the formulae (a3-r-1) to (a3-r-3), Ra′³¹ and Ra′³² represents a fluorine atom or a fluorinated alkyl group. As the fluorinated alkyl group, a fluorinate alkyl group of 1 to 5 carbon atoms can be mentioned.

Specific examples of groups represented by general formulae (a3-r-1) to (a3-r-3) are shown below.

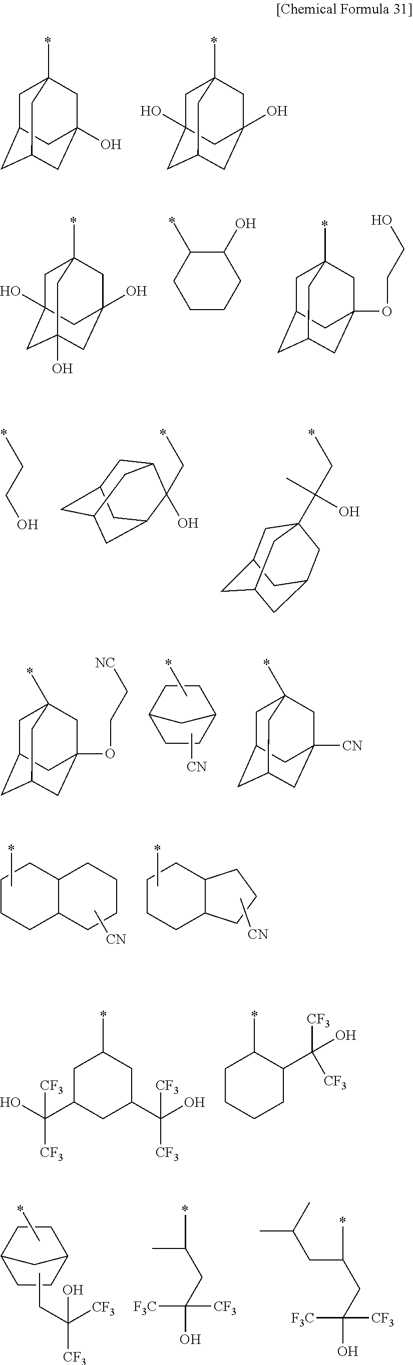

As the structural unit (a3) contained in the component (A1′), 1 type of structural unit may be used, or 2 or more types may be used.

The amount of the structural unit (a3) within the component (A1′) based on the combined total of all structural units constituting the component (A1′) is preferably 1 to 50 mol %, more preferably 5 to 40 mol %, and still more preferably 5 to 25 mol %.

When the amount of the structural unit (a3) is at least as large as the lower limit of the above-mentioned range, the effect of using the structural unit (a3) can be satisfactorily achieved. On the other hand, when the amount of the structural unit (a3) is no more than the upper limit of the above-mentioned range, a good balance can be achieved with the other structural units.

(Structural Unit (a4))

The structural unit (a4) is a structural unit containing an acid non-dissociable cyclic group. When the component (A1′) includes the structural unit (a4), dry etching resistance of the resist pattern to be formed is improved. Further, the hydrophobicity of the component (A1′) is further improved. Increase in the hydrophobicity contributes to improvement in terms of resolution, shape of the resist pattern and the like, particularly in an organic solvent developing process.

In the structural unit (a4), an “acid non-dissociable, aliphatic cyclic group” refers to a cyclic group which is not dissociated by the action of the acid generated from the component (A1′) or component (B) upon exposure, and remains in the structural unit.

As the structural unit (a4), a structural unit which contains a non-acid-dissociable aliphatic cyclic group, and is also derived from an acrylate ester is preferable. Examples of this cyclic group include the same groups as those described above in relation to the aforementioned structural unit (a1), and any of the multitude of conventional groups used within the resin component of resist compositions for ArF excimer lasers or KrF excimer lasers (and particularly for ArF excimer lasers) can be used.

In consideration of industrial availability and the like, at least one polycyclic group selected from amongst a tricyclodecyl group, adamantyl group, tetracyclododecyl group, isobornyl group, and norbornyl group is particularly desirable. These polycyclic groups may have a linear or branched alkyl group of 1 to 5 carbon atoms as a substituent.

Specific examples of the structural unit (a4) include units with structures represented by general formulas (a4-1) to (a4-7) shown below.

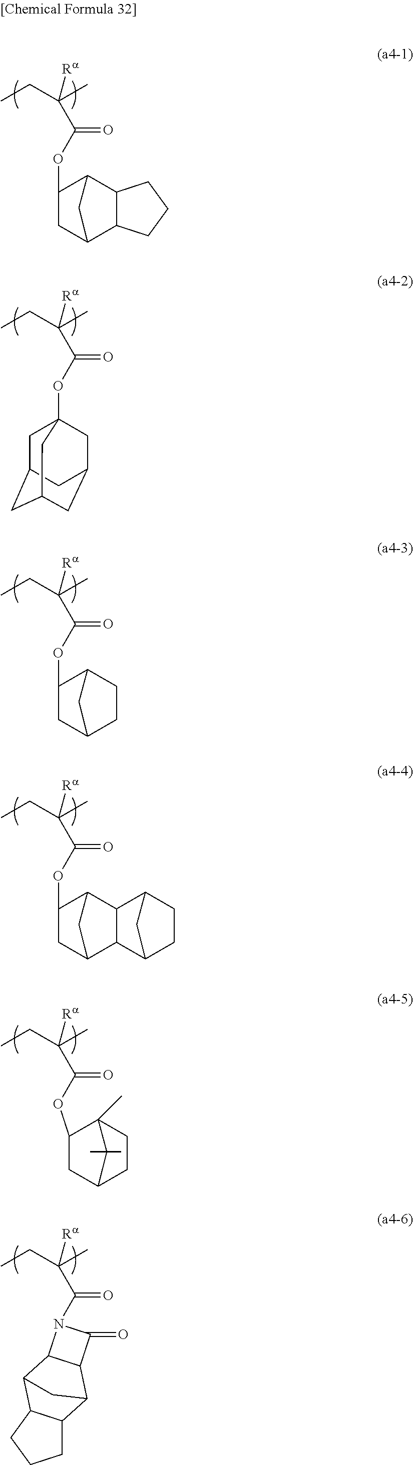

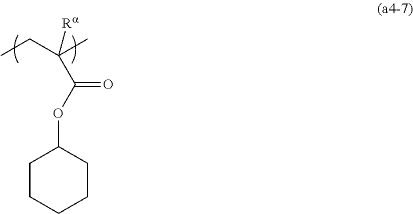

In the formulas shown above, R^{α} represents a hydrogen atom, a methyl group or a trifluoromethyl group.

As the structural unit (a4) contained in the component (A1′), 1 type of structural unit may be used, or 2 or more types may be used.

When the structural unit (a4) is included in the component (A1′), the amount of the structural unit (a4) based on the combined total of all the structural units that constitute the component (A1′) is preferably within the range from 1 to 30 mol %, and more preferably from 10 to 20 mol %.

The component (A1′) is preferably a copolymer containing the structural unit (a0). As the copolymer having the structural unit (a0), a copolymer further having any one of the structural units (a1), (a2), (a3) and (a4) is preferable; a copolymer having the structural units (a0), (a1) and (a2), and a copolymer having the structural units (a0), (a1), (a2) and (a3) are more preferable.

The weight average molecular weight (Mw) (the polystyrene equivalent value determined by gel permeation chromatography) of the component (A1′) is not particularly limited, but is preferably 1,000 to 50,000, more preferably 1,500 to 30,000, and most preferably 2,000 to 20,000. When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the component (A1′) is preferably 1.0 to 5.0, and more preferably 1.0 to 3.0.

As the component (A1′), one type may be used alone, or two or more types may be used in combination.

In the base component (A′), the amount of the component (A1′) based on the total weight of the component (A′) is preferably 25% by weight or more, more preferably 50% by weight or more, still more preferably 75% by weight or more, and may be even 100% by weight. When the amount of the component (A1′) is 25% by weight or more, various lithography properties are improved, such as improvement in MEF and circularity, and reduction of roughness.

In the resist composition 1 of the present invention, as the component (A′), one type may be used, or two or more types of compounds may be used in combination.

In the resist composition 1 of the present invention, the amount of the component (A′) can be appropriately adjusted depending on the thickness of the resist film to be formed, and the like.

[Optional Components] <Acid Generator Component; Component (B)>

The resist composition 1 of the present invention may further include an acid generator component (B) (hereafter, referred to as “component (B)”) which generates acid upon exposure. As the component (B), there is no particular limitation, and any of the known acid generators used in conventional chemically amplified resist compositions can be used.

Examples of these acid generators are numerous, and include onium salt acid generators such as iodonium salts and sulfonium salts; oxime sulfonate acid generators; diazomethane acid generators such as bisalkyl or bisaryl sulfonyl diazomethanes and poly(bis-sulfonyl)diazomethanes; nitrobenzylsulfonate acid generators; iminosulfonate acid generators; and disulfone acid generators. Among these, onium salt acid generators are preferably used.

As the component (B), an acid generator (B1′) described later may be added.

Examples of the onium salt acid generators include a compound represented by general formula (b-1) shown below (hereafter, sometimes referred to as “component (b-1)”), a compound represented by general formula (b-2) shown below (hereafter, sometimes referred to as “component (b-2)”) and a compound represented by general formula (b-3) shown below (hereafter, sometimes referred to as “component (b-3)”).

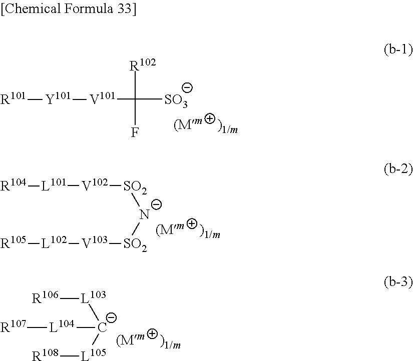

In the formulas, R¹⁰¹ and R¹⁰⁴ to R¹⁰⁸ each independently represents a cyclic group which may have a substituent, a chain-like alkyl group which may have a substituent or a chain-like alkenyl group which may have a substituent, provided that R¹⁰⁴ and R¹⁰⁵ may be mutually bonded to form a ring; provided that two of R¹⁰⁶ to R¹⁰⁷ may be mutually bonded to form a ring; R¹⁰² represents a fluorine atom or a fluorinated alkyl group of 1 to 5 carbon atoms; Y¹⁰¹ represents a single bond or a divalent linking group containing an oxygen atom; V¹⁰¹ to V¹⁰³ each independently represents a single bond, an alkylene group or a fluorinated alkylene group; L¹⁰¹ and L¹⁰² each independently represents a single bond or an oxygen atom; L¹⁰³ to L¹⁰⁵ each independently represents a single bond, —CO— or —SO₂—; and M′^{m+} represents an organic cation having a valency of m.

{Anion Moiety}—Anion Moiety of Component (b-1)

In the formula (b-1), R¹⁰¹ represents a cyclic group which may have a substituent, a chain-like alkyl group which may have a substituent or a chain-like alkenyl group which may have a substituent.

(Cyclic Group which May have a Substituent)

The cyclic group is preferably a cyclic hydrocarbon group, and the cyclic hydrocarbon group may be either an aromatic hydrocarbon group or an aliphatic hydrocarbon group.

As the aromatic hydrocarbon group for R¹⁰¹, groups in which one hydrogen atom has been removed from an aromatic hydrocarbon ring described above in relation to the divalent aromatic hydrocarbon group for Va¹ in the formula (a1-1) or an aryl group in which one hydrogen atom has been removed from an aromatic compound containing two or more aromatic ring can be mentioned, and a phenyl group or a naphthyl group is preferable.

As the cyclic aliphatic hydrocarbon group for R¹⁰¹, groups in which one hydrogen atom has been removed from a monocycloalkane or a polycycloalkane exemplified above in the explanation of the divalent aliphatic hydrocarbon group for Va¹ in the formula (a1-1) can be mentioned, and an adamantyl group or a norbornyl group is preferable.

Further, the cyclic hydrocarbon group for R¹⁰¹ may contain a hetero atom like as a heterocycle, and specific examples thereof include lactone-containing cyclic groups represented by the aforementioned general formulas (a2-r-1) to (a2-r-7), —SO₂— containing cyclic groups represented by the aforementioned formulas (a5-r-1) to (a5-r-4) and heterocycles shown below.

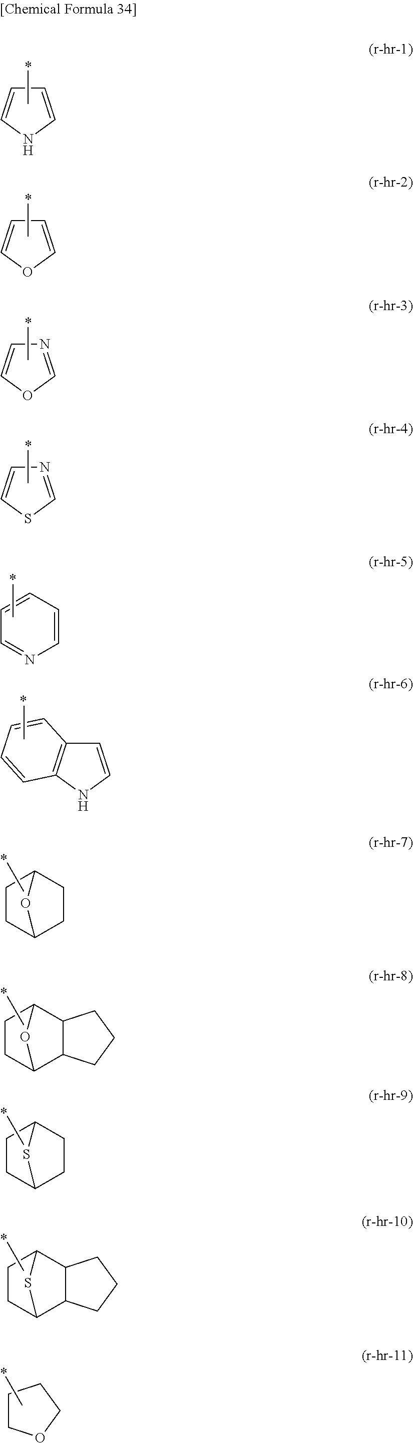

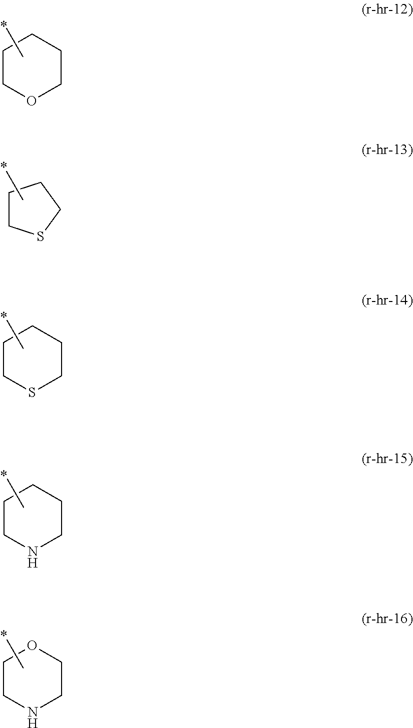

As the substituent for substituting the cyclic hydrocarbon group for R¹⁰¹, an alkyl group, an alkoxy group, a halogen atom, a halogenated alkyl group, a hydroxyl group, a carbonyl group, a nitro group or the like can be used.

The alkyl group as the substituent is preferably an alkyl group of 1 to 5 carbon atoms, and a methyl group, an ethyl group, a propyl group, an n-butyl group or a tert-butyl group is most desirable.

The alkoxy group as the substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent include a fluorine atom, a chlorine atom, a bromine atom and an iodine atom, and a fluorine atom is preferable.

Example of the halogenated alkyl group as a substituent includes a group in which a part or all of the hydrogen atoms within an alkyl group of 1 to 5 carbon atoms such as a methyl group, an ethyl group, a propyl group, an n-butyl group or a tert-butyl group have been substituted with the aforementioned halogen atoms.

(Chain-Like Alkyl Group which May have a Substituent)

The chain-like alkyl group for R¹⁰¹ may be either linear or branched.

The linear alkyl group preferably has 1 to 20 carbon atoms, more preferably 1 to 15, and most preferably 1 to 10. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched alkyl group preferably has 3 to 20 carbon atoms, more preferably 3 to 15, and most preferably 3 to 10. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

(Chain-Like Alkenyl Group which May have a Substituent)

The chain-like alkenyl group for R¹⁰¹ may be linear or branched, and preferably has 2 to 10 carbon atoms, more preferably 2 to 5 carbon atoms, still more preferably 2 to 4 carbon atoms, and particularly preferably 3 carbon atoms. Examples of linear alkenyl groups include a vinyl group, a propenyl group (an allyl group) and a butynyl group. Examples of branched alkenyl groups include a 1-methylpropenyl group and a 2-methylpropenyl group.

Among the above-mentioned examples, as the chain-like alkenyl group, a propenyl group is particularly desirable.

As the substituent for substituting the chain-like alkyl group or alkenyl group for R¹⁰¹, an alkoxy group, a halogen atom, a halogenated alkyl group, a hydroxyl group, a carbonyl group, a nitro group, an amino group, the same cyclic group as described above for R¹⁰¹ or the like can be used.

Among these, as R¹⁰¹, a cyclic group which may have a substituent is preferable, and a cyclic hydrocarbon group which may have a substituent is more preferable. Specific examples include a group in which one or more hydrogen atoms have been removed from a phenyl group, a naphthyl group or a polycycloalkane, lactone-containing cyclic groups represented by the aforementioned formulae (a2-r-1) to (a2-r-7) and —SO₂— containing cyclic groups represented by the aforementioned formulae (a5-r-1) to (a5-r-4) and the like.

In the formula (b-1), Y¹⁰¹ represents a single bond or a divalent linking group containing an oxygen atom.

In the case where Y¹⁰¹ is a divalent linking group containing an oxygen atom, Y¹⁰¹ may contain an atom other than an oxygen atom. Examples of atoms other than an oxygen atom include a carbon atom, a hydrogen atom, a sulfur atom and a nitrogen atom.

Examples of divalent linkage groups containing an oxygen atom include non-hydrocarbon, oxygen atom-containing linking groups such as an oxygen atom (an ether bond; —O—), an ester bond (—C(═O)—O—), an oxycarbonyl group (—O—C(═O)—), an amide bond (—C(═O)—NH—), a carbonyl group (—C(═O)—) and a carbonate group (—O—C(═O)—O—); and a combination of any of the aforementioned non-hydrocarbon, oxygen atom-containing linking groups with an alkylene group. Furthermore, the combinations may have a sulfonyl group (—SO₂—) bonded thereto. As the combination, the linking groups represented by formulae (y-a1-1) to (y-a1-7) shown below can be mentioned.

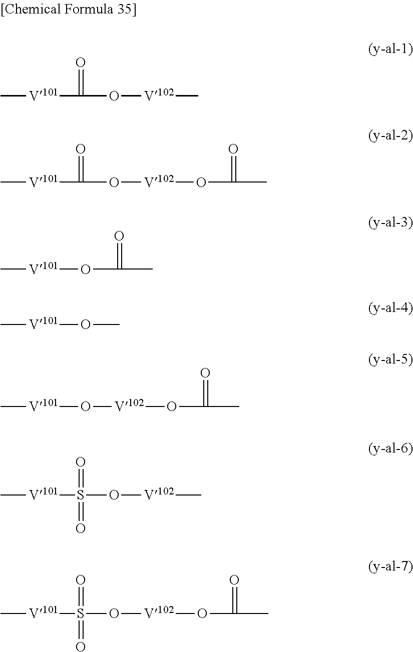

In the formulae, V′¹⁰¹ represents a single bond or an alkylene group of 1 to 5 carbon atoms; and V′¹⁰² represents a divalent saturated hydrocarbon group of 1 to 30 carbon atoms.

The divalent saturated hydrcarbon group for V′¹⁰² is preferably an alkylene group of 1 to 30 carbon atoms.

As the alkylene group for V′¹⁰¹ and V′¹⁰², a linear alkylene group or a branched alkylene group can be used, and a linear alkylene group is preferable.

Specific examples of the alkylene group for V′¹⁰¹ and V′¹⁰² include a methylene group[—CH₂—]; alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; an ethylene group[—CH₂CH₂—]; alkylethylene groups such as —CH(CH₃)CH₂—, —CH(CH₃)CH(CH₃)—, —C(CH₃)₂CH₂— and —CH(CH₂CH₃)CH₂—; a trimethylene group (n-propylene group)[—CH₂CH₂CH₂—]; alkyltrimethylene groups such as —CH(CH₃)CH₂CH₂— and —CH₂CH(CH₃)CH₂—; a tetramethylene group [—CH₂CH₂CH₂CH₂—]; alkyltetramethylene groups such as —CH(CH₃)CH₂CH₂CH₂— and —CH₂CH(CH₃)CH₂CH₂—; and a pentamethylene group[—CH₂CH₂CH₂CH₂CH₂—].

Further, part of methylene group within the alkylene group for V′¹⁰¹ and V′¹⁰² may be substituted with a divalent aliphatic cyclic group of 5 to 10 carbon atoms. The aliphatic cyclic group is preferably a divalent group in which one hydrogen atom has been removed from the cyclic aliphatic hydrocarbon group described above for Ra′³ in the aforementioned formula (a1-r-1), and a cyclohexylene group, 1,5-adamantylene group or 2,6-adamantylene group is more preferable.

Y¹⁰¹ is preferably a divalent linking group containing an ether bond or an ester bond, and linking groups represented by the aforementioned formulas (y-a1-1) to (y-a1-5) are preferable.

In the formula (b-1), V¹⁰¹ represents a single bond, an alkylene group or a fluorinated alkylene group. The alkylene group or fluorinated alkylene group for V¹⁰¹ preferably has 1 to 4 carbon atoms. As the fluorinated alkylene group for V¹⁰¹, a group in which part or all of the hydrogen atoms within the aforementioned alkylene group for V′¹⁰¹ has been substituted with fluorine atoms can be used. Among these, V′¹⁰¹ is preferably a single bond or a fluorinated alkylene group of 1 to 4 carbon atoms.

In the formula (b-1), R¹⁰² represents a fluorine atom or a fluorinated alkyl group of 1 to 5 carbon atoms. R¹⁰² is preferably a fluorine atom or a perfluoroalkyl group of 1 to 5 carbon atoms, and is more preferably a fluorine atom.

As specific examples of anion moieties of the formula (b-1),

When Y¹⁰¹ is a single bond, fluorinated alkylsulfonate anions such as a trifluoromethanesulfonate anion or a perfluorobutanesulfonate anion can be mentioned; and when Y¹⁰¹ is a divalent linking group containing an oxygen atom, anions represented by formulae (an-1) to (an-3) shown below can be mentioned.

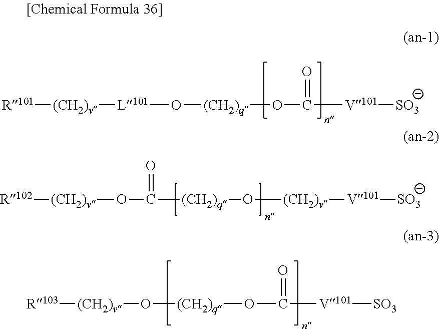

In the formulae, R″¹⁰¹ represents an aliphatic cyclic group which may have a substituent, a group represented by any one of the aforementioned formulae (r-hr-1) to (r-hr-6) or a chain-like alkyl group which may have a substituent; R″¹⁰² represents an aliphatic cyclic group which may have a substituent, a lactone-containing cyclic group represented by any one of the formulae (a2-r-1) to (a2-r-7) or an —SO₂— containing cyclic group represented by any one of the formulae (a5-r-1) to (a5-r-4); R″¹⁰³ represents an aromatic cyclic group which may have a substituent, an aliphatic cyclic group which may have a substituent or a chain-like alkenyl group which may have a substituent; V″¹⁰¹ represents a fluorinated alkylene group; L″¹⁰¹ represents —C(═O)— or —SO₂—; v″ each independently represents an integer of 0 to 3; q″ each independently represents an integer of 1 to 20; n″ represents 0 or 1.

As the aliphatic cyclic group for R″¹⁰¹, R″¹⁰² and R″¹⁰³ which may have a substituent, the same groups as the cyclic aliphatic hydrocarbon group for R¹⁰¹ described above are preferable. As the substituent, the same groups as those described above for substituting the cyclic aliphatic hydrocarbon group for R¹⁰¹ can be mentioned.

As the aromatic cyclic group for R″¹⁰³ which may have a substituent, the same groups as the aromatic hydrocarbon group exemplified as a cyclic hydrocarbon group for R¹⁰¹ described above are preferable. As the substituent, the same groups as those described above for substituting the aromatic hydrocarbon group for R¹⁰¹ can be mentioned.

As the chain-like alkyl group for R″¹⁰¹ which may have a substituent, the same groups exemplified as the chain-like alkyl group for R¹⁰¹ are preferable. As the chain-like alkenyl group for R″¹⁰³ which may have a substituent, the same groups exemplified as the chain-like alkenyl group for R¹⁰¹ are preferable. V″¹⁰¹ is preferably a fluorinated alkylene group of 1 to 3 carbon atoms, and particularly preferably —CF₂CF₂—, —CHFCF₂—, —CF(CF₃)CF₂— or —CH(CF₃)CF₂—.

Anion Moiety of Component (b-2)

In formula (b-2), R¹⁰⁴ and R¹⁰⁵ each independently represents a cyclic group which may have a substituent, a chain-like alkyl group which may have a substituent or a chain-like alkenyl group which may have a substituent, and is the same groups as those defined above for R¹⁰¹ in the aforementioned formula (b-1), provided that, R¹⁰⁴ and R¹⁰⁵ may be mutually bonded to form a ring.

As R¹⁰⁴ and R¹⁰⁵, a chain-like alkyl group which may have a substituent is preferable, and a linear or branched alkyl group or a linear or branched fluorinated alkyl group is more preferable.

The chain-like alkyl group preferably has 1 to 10 carbon atoms, preferably 1 to 7, and more preferably 1 to 3. The smaller the number of carbon atoms of the chain-like alkyl group for R¹⁰⁴ and R¹⁰⁵ within the above-mentioned range of the number of carbon atoms, the more the solubility in a resist solvent is improved. Further, in the chain-like alkyl group for R¹⁰⁴ and R¹⁰⁵, it is preferable that the number of hydrogen atoms substituted with fluorine atoms is as large as possible because the acid strength increases and the transparency to high energy radiation of 200 nm or less or electron beam is improved. The fluorination ratio of the chain-like alkyl group is preferably from 70 to 100%, more preferably from 90 to 100%, and it is particularly desirable that the chain-like alkyl group be a perfluoroalkyl group in which all hydrogen atoms are substituted with fluorine atoms.

In formula (b-2), V¹⁰² and V¹⁰³ each independently represents a single bond, an alkylene group or a fluorinated alkylene group, and is the same groups as those defined above for V¹⁰¹ in the aforementioned formula (b-1).

In the formula (b-2), L¹⁰¹ and L¹⁰² each independently represents a single bond or an oxygen atom.

Anion Moiety of Component (b-3)

In formula (b-3), R¹⁰⁶ to R¹⁰⁸ each independently represents a cyclic group which may have a substituent, a chain-like alkyl group which may have a substituent or a chain-like alkenyl group which may have a substituent, and is the same groups as those defined above for R¹⁰¹ in the aforementioned formula (b-1).

L¹⁰³ to L¹⁰⁵ each independently represents a single bond, —CO— or —SO₂—.

{Cation Moiety}

In the formulas (b-1), (b-2) and (b-3), M′^{m+} represents an organic cation having a valency of m. Among these, a sulfonium cation or an iodonium cation is preferable, and cation moieties represented by general formulae (ca-1) to (ca-4) shown below are particularly preferable.

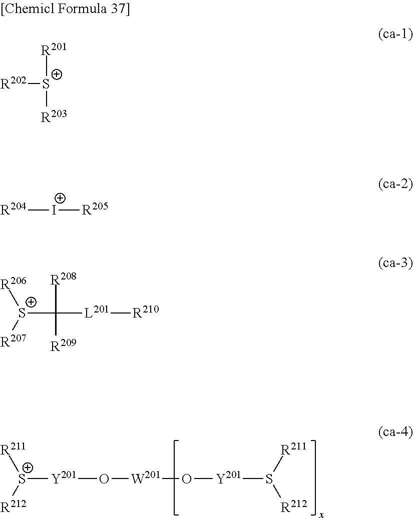

In the formulas, each of R²⁰¹ to R²⁰⁷, R²¹¹ and R²¹² independently represents an aryl group which may have a substituent, an alkyl group which may have a substituent or an alkenyl group which may have a substituent; R²⁰¹ to R²⁰³, R²⁰⁶ and R²⁰⁷, and R²¹¹ and R²¹² may be mutually bonded to form a ring with the sulfur atom; R²⁰⁸ and R²⁰⁹ each represents a hydrogen atom or an alkyl group of 1 to 5 carbon atoms; R²¹⁰ represents an aryl group which may have a substituent, an alkyl group which may have a substituent, an alkenyl group which may have a substituent or an —SO₂— containing cyclic group which may have a substituent; L²⁰¹ represents —C(═O)— or —C(═O)—O—; Y²⁰¹ each independently represents an arylene group, an alkylene group or an alkenylene group; x represents 1 or 2; and W²⁰¹ represents a linking group having a valency of (x+1).

As the aryl group for R²⁰¹ to R²⁰⁷, R²¹¹ and R²¹², an unsubstituted aryl group of 6 to 20 carbon atoms can be mentioned, and a phenyl group or a naphthyl group is preferable.

As the alkyl group for R²⁰¹ to R²⁰⁷, R²¹¹ and R²¹², a chain-like or cyclic alkyl group of 1 to 30 carbon atoms is preferable.

The alkenyl group for R²⁰¹ to R²⁰⁷, R²¹¹ and R²¹² preferably has 2 to 10 carbon atoms.

Specific examples of the substituent which R²⁰¹ to R²⁰⁷, R²¹¹ and R²¹² may have include an alkyl group, a halogen atom, a halogenated alkyl group, a carbonyl group, a cyano group, an amino group, an aryl group, an arylthio group and groups represented by formulas (ca-r-1) to (ca-r-7) shown below.

As the aryl group within the arylthio group as a substituent, the same aryl groups as those described above for R¹⁰¹ can be mentioned, and specific examples thereof include a phenylthio group or a biphenylthio group.

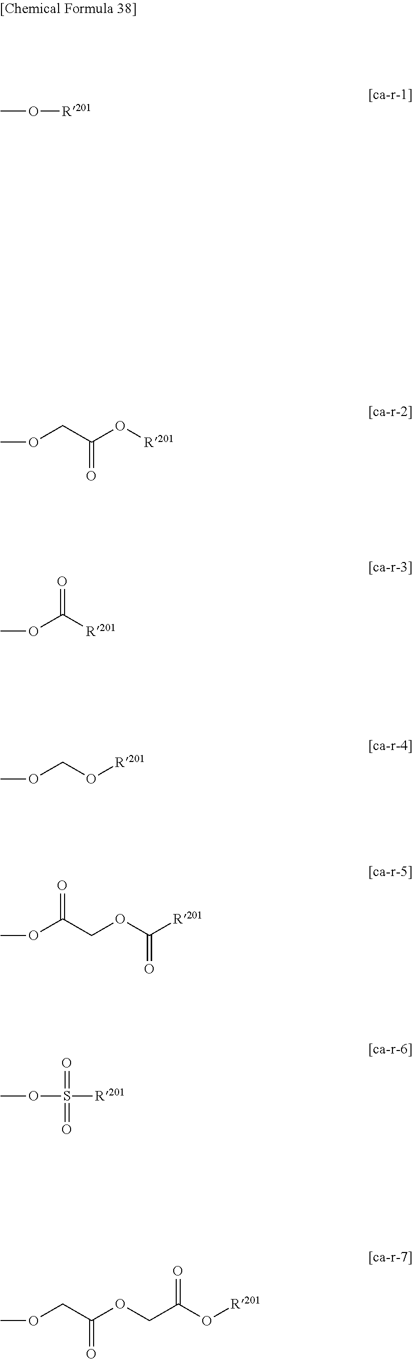

In the formulae, R′²⁰¹ each independently represents a hydrogen atom, a cyclic group which may have a substituent, a chain-like alkyl group which may have a substituent or a chain-like alkenyl group which may have a substituent.

As the cyclic group which may have a substituent, the chain-like alkyl group which may have a substituent and the chain-like alkenyl group which may have a substituent for R′²⁰¹, the same groups as those described above for R¹⁰¹ in the aforementioned formula (b-1) can be mentioned. As the cyclic group which may have a substituent and chain-like alkyl group which may have a substituent, the same groups as those described above for the acid dissociable group represented by the aforementioned formula (a1-r-2) can be also mentioned.

When R²⁰¹ to R²⁰³, R²⁰⁶ and R²⁰⁷, and R²¹¹ and R²¹² are mutually bonded to form a ring with the sulfur atom, these groups may be mutually bonded via a hetero atom such as a sulfur atom, an oxygen atom or a nitrogen atom, or a functional group such as a carbonyl group, —SO—, —SO₂—, —SO₃—, —COO—, —CONH— or —N(R_{N})— (wherein R_{N} represents an alkyl group of 1 to 5 carbon atoms). As the ring to be formed, the ring containing the sulfur atom in the skeleton thereof is preferably a 3 to 10-membered ring, and particularly preferably a 5 to 7-membered ring. Examples of the formed ring include a thiophene ring, a thiazole ring, a benzothiophene ring, a thianthrene ring, a benzothiophene ring, a dibenzothiophene ring, a 9H-thioxanthene ring, a thioxanthone ring, a phenoxathiin ring, a tetrahydrothiophenium ring and a tetrahydrothiopyranium ring.

R²⁰⁸ and R²⁰⁹ each independently represents a hydrogen atom or an alkyl group of 1 to 5 carbon atoms, is preferably a hydrogen atom or an alkyl group of 1 to 3 carbon atoms, and when R²⁰⁸ and R²⁰⁹ each represents an alkyl group, R²⁰⁸ and R²⁰⁹ may be mutually bonded to form a ring.

R²¹⁰ represents an aryl group which may have a substituent, an alkyl group which may have a substituent, an alkenyl group which may have a substituent or an —SO₂— containing cyclic group which may have a substituent.

As the aryl group for R²¹⁰, an unsubstituted aryl group of 6 to 20 carbon atoms can be mentioned, and a phenyl group or a naphthyl group is preferable.

As the alkyl group for R²¹⁰, a chain-like or cyclic alkyl group of 1 to 30 carbon atoms is preferable.

The alkenyl group for R²¹⁰ preferably has 2 to 10 carbon atoms.

As the —SO₂— containing cyclic group for R²¹⁰ which may have a substituent, the same groups as the “—SO₂— containing cyclic group” for Ra²¹ in the general formula (a2-1) can be mentioned, and the group represented by the aforementioned general formula (a5-r-1) is preferable.

Y²⁰¹ each independently represents an arylene group, an alkylene group or an alkenylene group.

As the arylene group for Y²⁰¹, a group in which one hydrogen atom has been removed from an aryl group exemplified as an aromatic hydrocarbon group for R¹⁰¹ in the aforementioned formula (b-1) can be mentioned.

As the alkylene group and the alkenylene group for Y²⁰¹, the same aliphatic hydrocarbon group as those described above for the divalent hydrocarbon group for Va¹ in the aforementioned general formula (a1-1) can be mentioned.

In the formula (ca-4), x represents 1 or 2.

W²⁰¹ represents a linking group having a valency of (x+1), that is, a divalent or trivalent linking group.

As the divalent linking group for W²⁰¹, a divalent hydrocarbon groups which may have a substituent is preferable, and as examples thereof, the same hydrocarbon group as those described above for Ya²¹ in the general formula (a2-1) can be mentioned. The divalent linking group for W²⁰¹ may be linear, branched or cyclic, and cyclic is more preferable. Among these, an arylene group having two carbonyl groups, each bonded to the terminal thereof is preferable. As the arylene group, a phenylene group and a naphthylene group can be mentioned. Of these, a phenylene group is particularly desirable.

As the trivalent linking group for W²⁰¹, a group in which one hydrogen atom has been removed from the aforementioned divalent linking group for W²⁰¹, and a group in which the divalent linking group has been bonded to an another divalent linking group can be mentioned. The trivalent linking group for W²⁰¹ is preferably an arylene group having two carbonyl groups bonded thereto.

Specific examples of preferable cations represented by formula (ca-1) include cations represented by formulas (ca-1-1) to (ca-1-63) shown below.

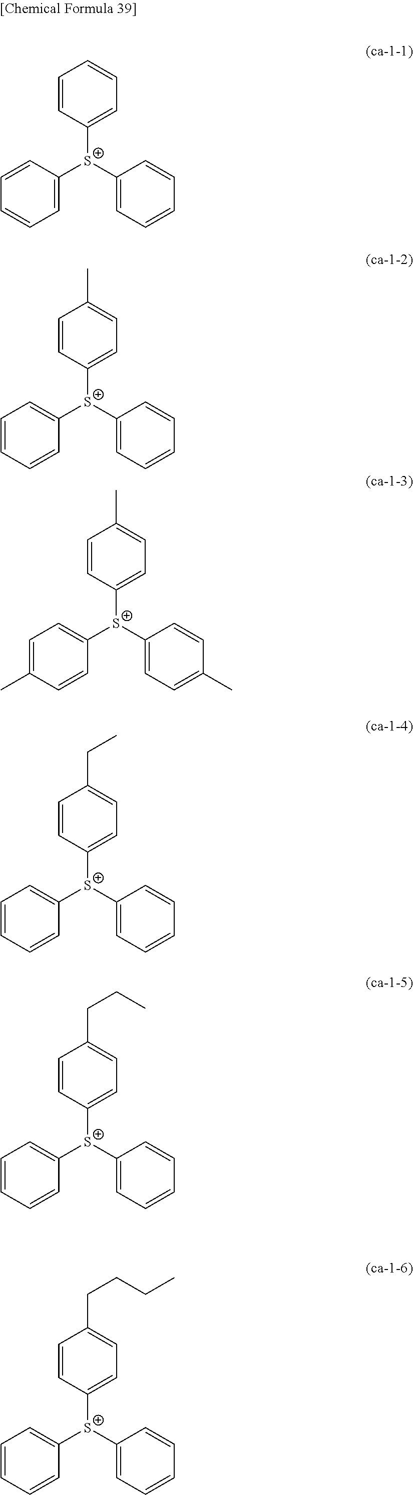

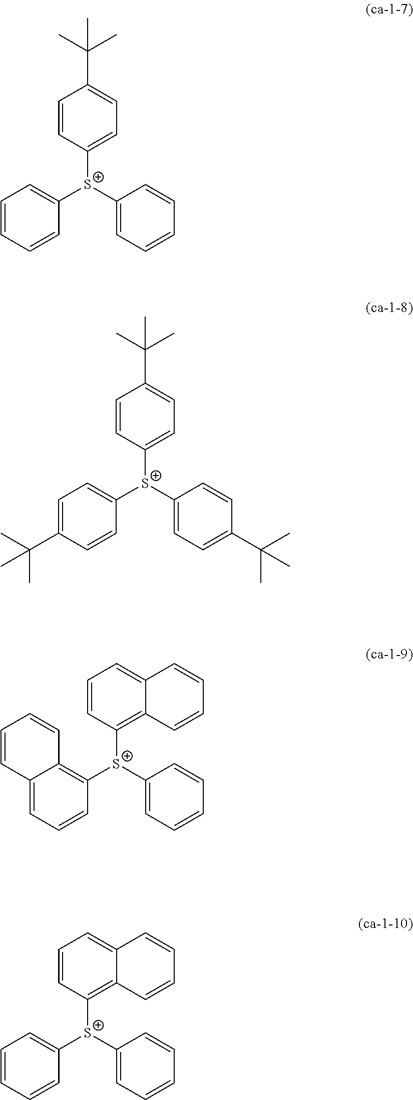

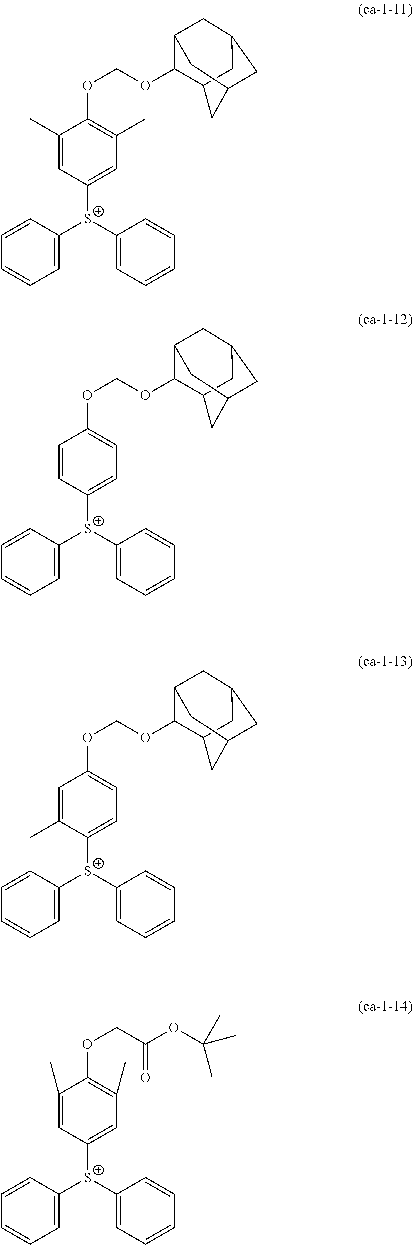

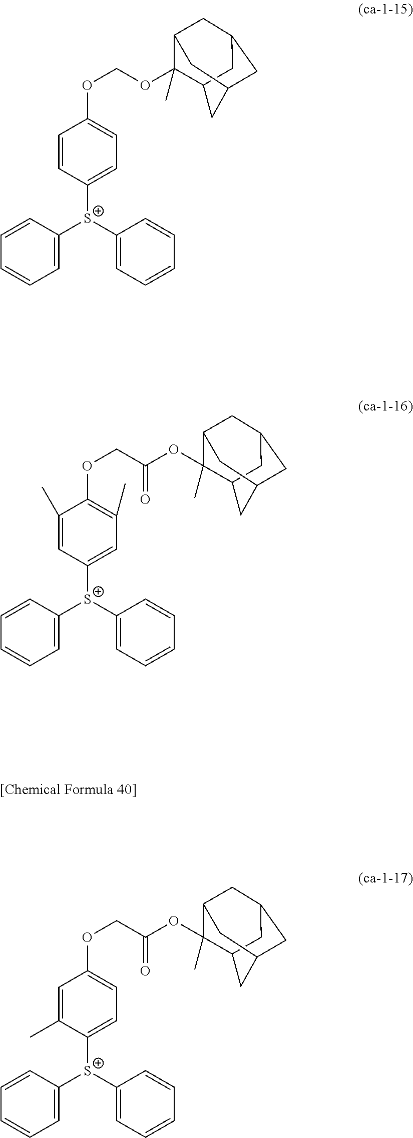

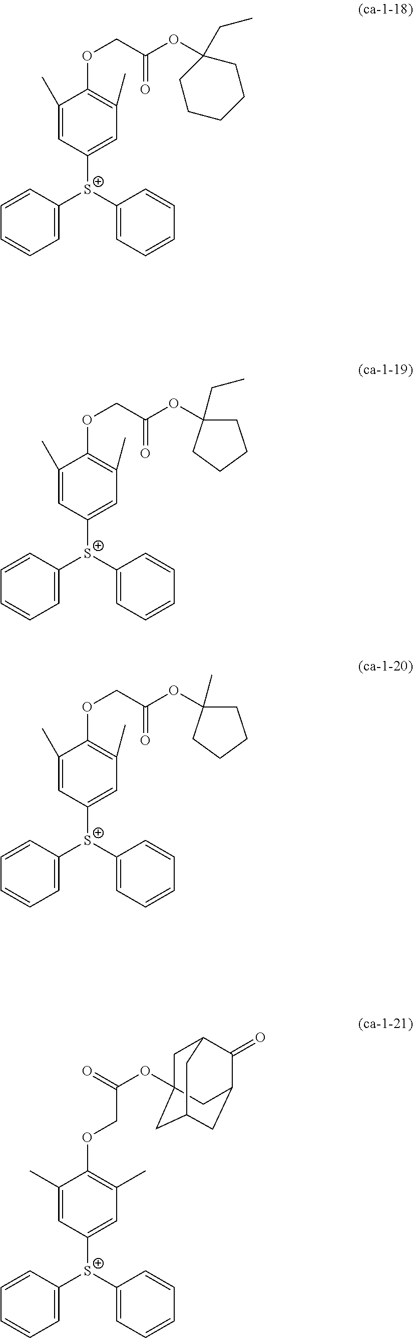

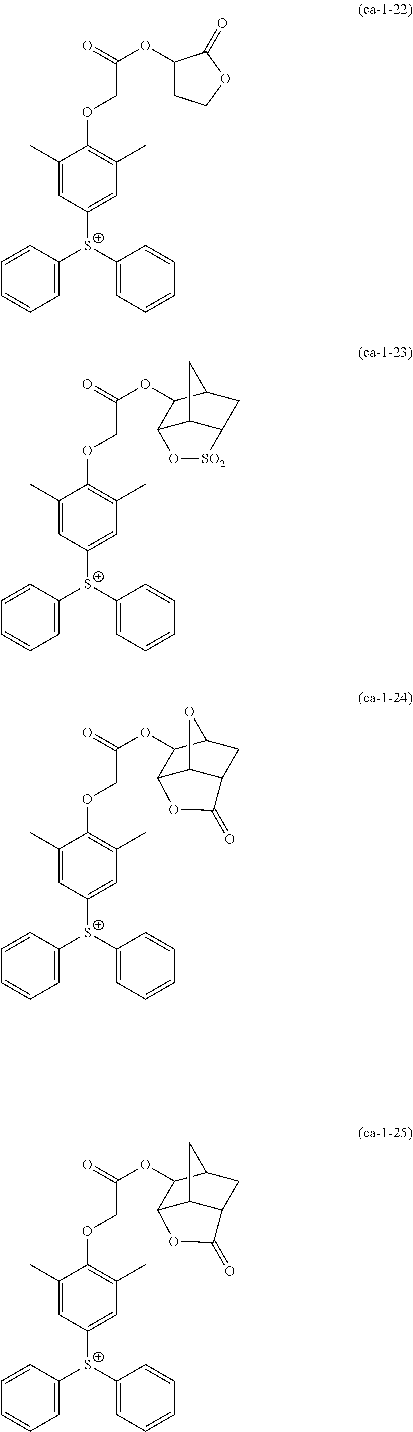

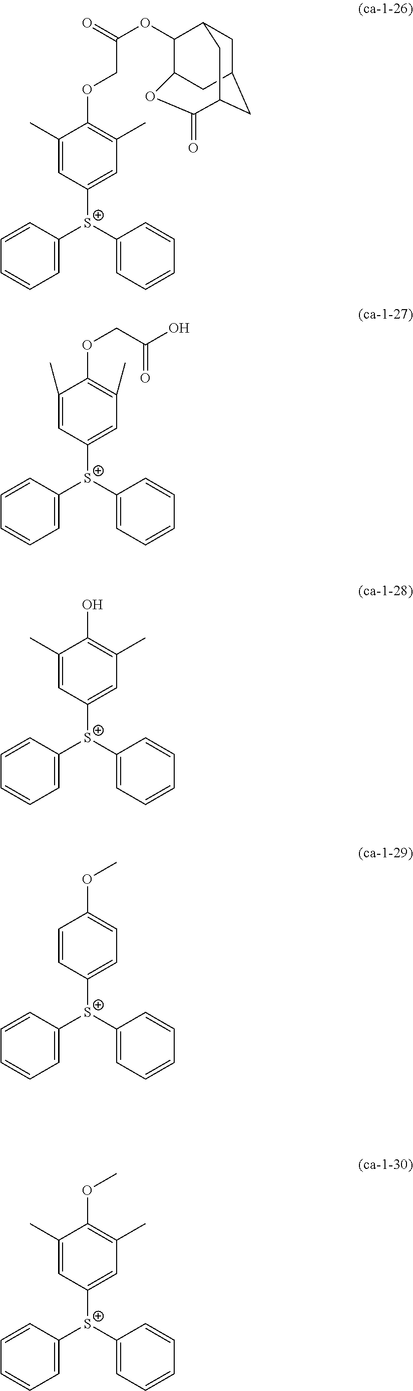

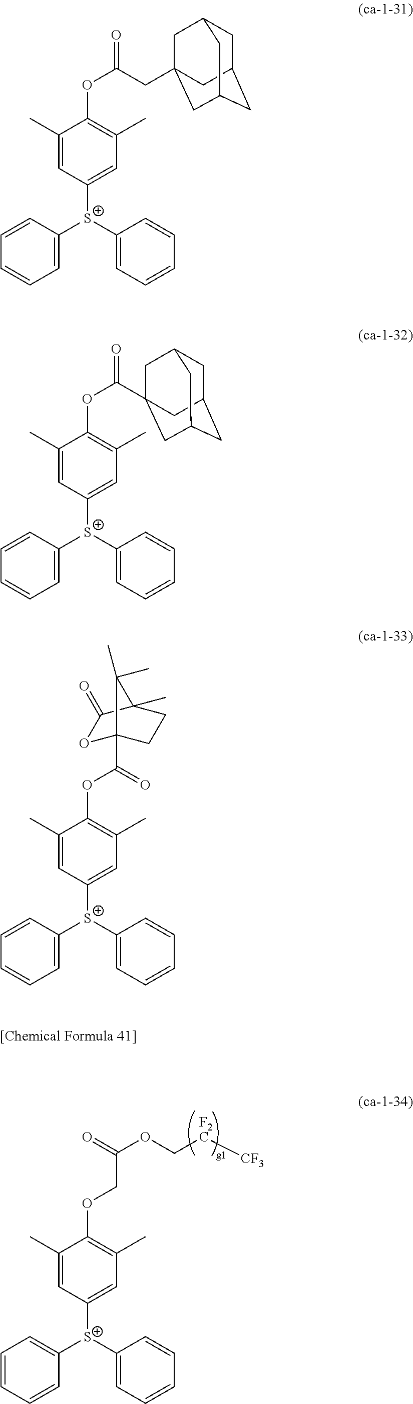

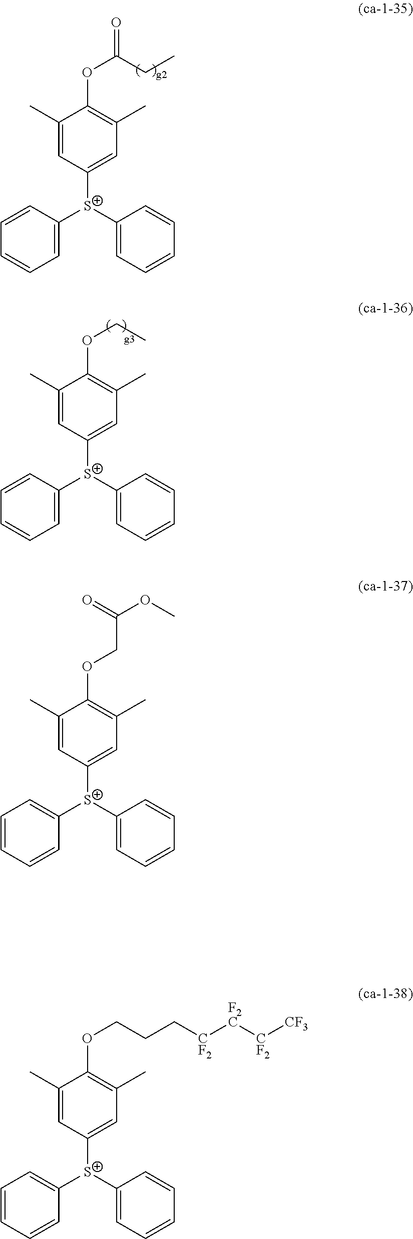

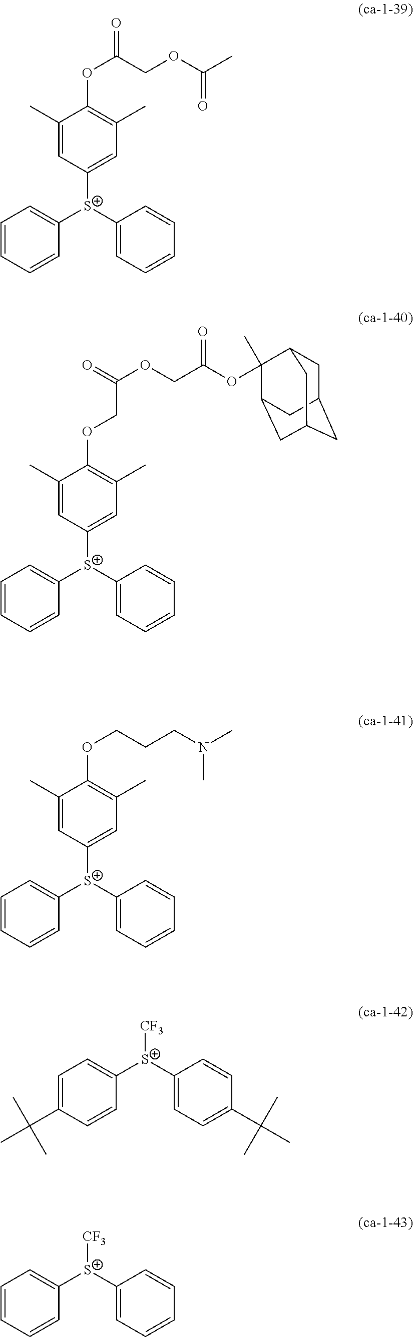

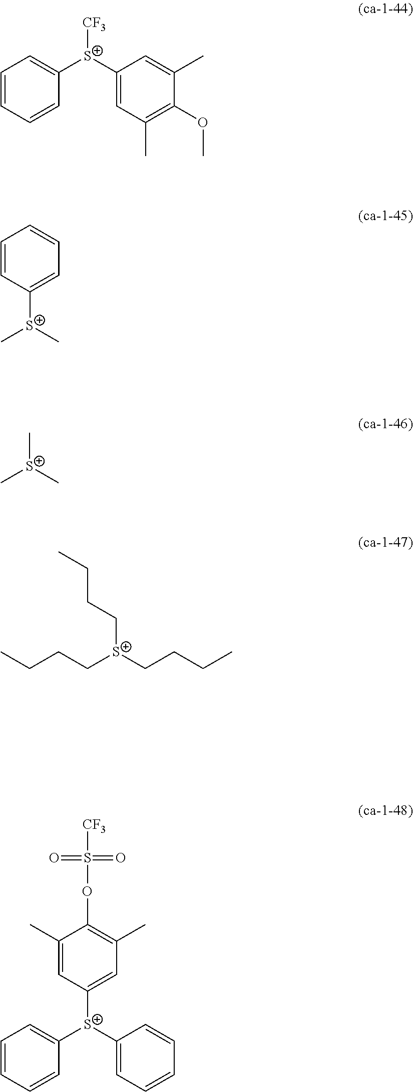

In the formulas, g1, g2 and g3 represent recurring numbers, wherein g1 is an integer of 1 to 5, g2 is an integer of 0 to 20, and g3 is an integer of 0 to 20.

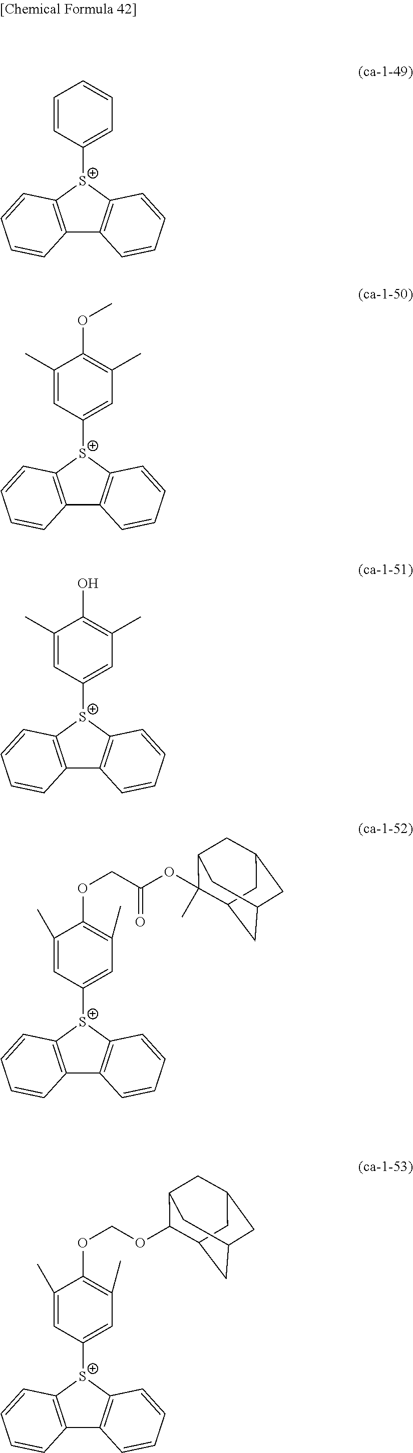

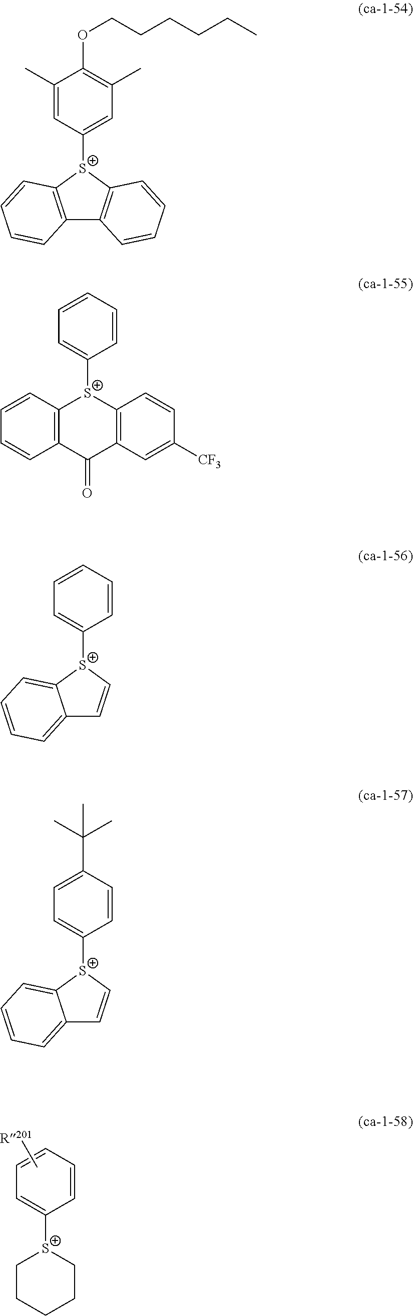

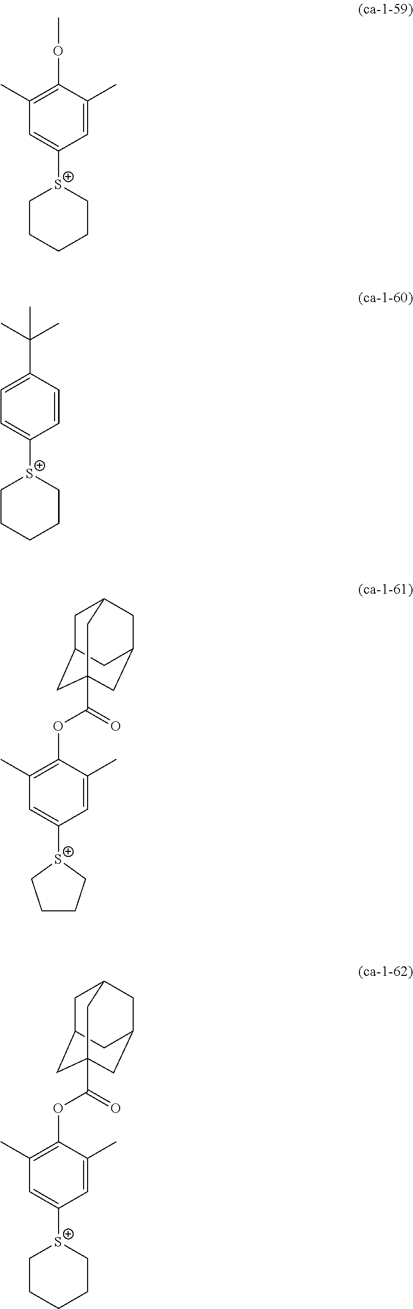

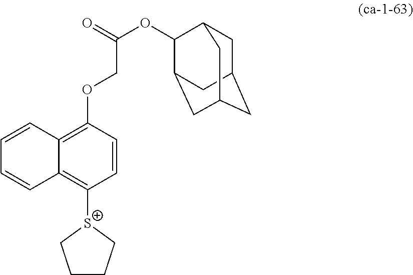

In the formulas, R″²⁰¹ represents a hydrogen atom or a substituent, and as the substituent, the same groups as those described above for substituting the R²⁰¹ to R²⁰⁷ and R²¹⁰ to R²¹² can be mentioned.

Specific examples of preferable cations represented by the formula (ca-3) include cations represented by formulae (ca-3-1) to (ca-3-6) shown below.

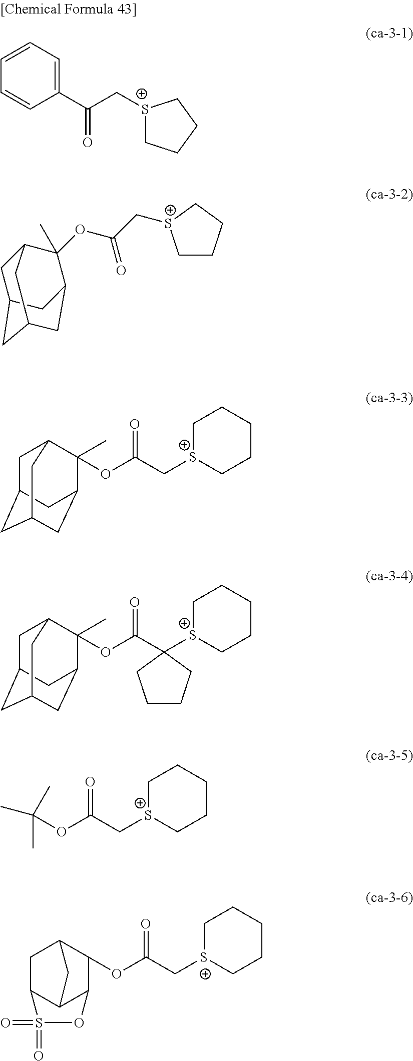 [SMILES: O=C(C[S+]1CCCC1)c1ccccc1 ; CC1(OC(=O)C[S+]2CCCC2)C2CC3CC(C2)CC1C3 ; CC1(OC(=O)C[S+]2CCCCC2)C2CC3CC(C2)CC1C3 ; CC1(OC(=O)C2([S+]3CCCCC3)CCCC2)C2CC3CC(C2)CC1C3 ; CC(C)(C)OC(=O)C[S+]1CCCCC1 ; O=C(C[S+]1CCCCC1)OC1C2CC3C1OS(=O)(=O)C3C2]

Specific examples of preferable cations represented by formula (ca-4) include cations represented by formulas (ca-4-1) to (ca-4-2) shown below.

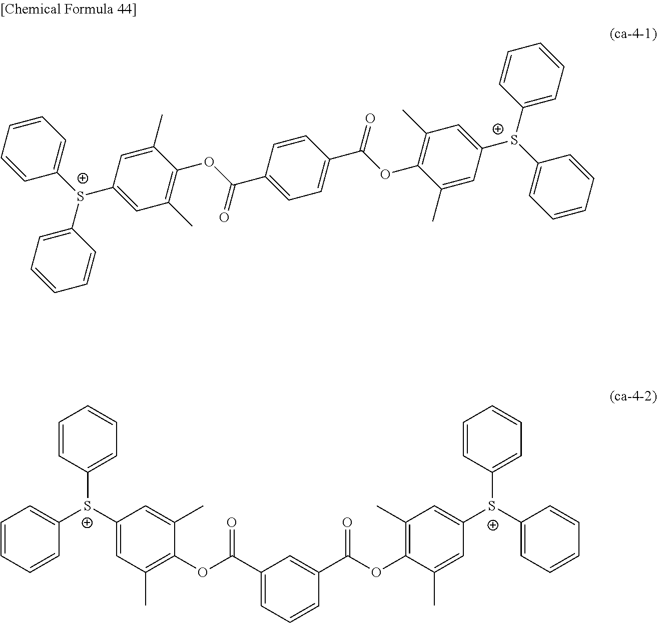 [SMILES: Cc1cc([S+](c2ccccc2)c2ccccc2)cc(C)c1OC(=O)c1ccc(C(=O)Oc2c(C)cc([S+](c3ccccc3)c3ccccc3)cc2C)cc1 ; Cc1cc([S+](c2ccccc2)c2ccccc2)cc(C)c1OC(=O)c1cccc(C(=O)Oc2c(C)cc([S+](c3ccccc3)c3ccccc3)cc2C)c1]

As the component (B), one type of these acid generators may be used alone, or two or more types may be used in combination.

When the resist composition 1 of the present invention contains the component (B), the amount of the component (B) relative to 100 parts by weight of the component (A′) is preferably within a range from 0.5 to 60 parts by weight, more preferably from 1 to 50 parts by weight, and still more preferably from 1 to 40 parts by weight. When the amount of the component (B) is within the above-mentioned range, formation of a resist pattern can be satisfactorily performed. Further, by virtue of the above-mentioned range, when each of the components are dissolved in an organic solvent, a uniform solution can be obtained and the storage stability becomes satisfactory.

<Basic Compound Component; Component (D)>

The resist composition 1 of the present invention may include an acid diffusion control agent component (hereafter, frequently referred to as “component (D)”), in addition to the component (A′), or in addition to the component (A′) and the component (B).

The component (D) functions as an acid diffusion control agent, i.e., a quencher which traps the acid generated from the component (B) and the like upon exposure.

In the present invention, the component (D) may be a photodecomposable base (D1) (hereafter, referred to as “component (D1)”) which is decomposed upon exposure and then loses the ability of controlling of acid diffusion, or a nitrogen-containing organic compound (D2) (hereafter, referred to as “component (D2)”) which does not fall under the definition of component (D2).

[Component (D1)]

When a resist pattern is formed using a resist composition containing the component (D1), the contrast between exposed portions and unexposed portions is improved.

The component (D1) is not particularly limited, as long as it is decomposed upon exposure and then loses the ability of controlling of acid diffusion. As the component (D1), at least one compound selected from the group consisting of a compound represented by general formula (d1-1) shown below (hereafter, referred to as “component (d1-1)”), a compound represented by general formula (d1-2) shown below (hereafter, referred to as “component (d1-2)”) and a compound represented by general formula (d1-3) shown below (hereafter, referred to as “component (d1-3)”) is preferably used.

At exposed portions, the components (d1-1) to (d1-3) are decomposed and then lose the ability of controlling of acid diffusion (i.e., basicity), and therefore the components (d1-1) to (d1-3) cannot function as a quencher, whereas at unexposed portions, the components (d1-1) to (d1-3) function as a quencher.

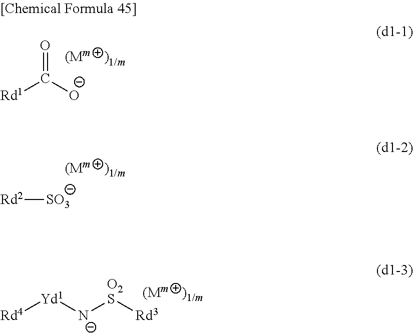

In the formulae, Rd¹ to Rd⁴ represents a cyclic group which may have a substituent, a chain-like alkyl group which may have a substituent or a chain-like alkenyl group which may have a substituent; provided that, in the formula (d1-2), the carbon atom within the Rd² adjacent to the sulfur atom has no fluorine atom bonded thereto; Yd¹ represents a single bond or a divalent linking group; and M^{m+} each independently represents an organic cation having a valency of m.

{Component (d1-1)}•Anion Moiety

In formula (d1-1), Rd¹ represents a cyclic group which may have a substituent, a chain-like alkyl group which may have a substituent or a chain-like alkenyl group which may have a substituent, and is the same groups as those defined above for R¹⁰¹.

Among these, as the group for Rd¹, an aromatic hydrocarbon group which may have a substituent, an aliphatic cyclic group which may have a substituent and a chain-like hydrocarbon group which may have a substituent are preferable. As the substituents which these groups may have, a hydroxy group, a fluorine atom or a fluorinated alkyl group is preferable.

The aromatic hydrocarbon group is preferably a phenyl group or a naphthyl group.

Examples of the aliphatic cyclic group include groups in which one or more hydrogen atoms have been removed from a polycycloalkane such as adamantane, norbornane, isobornane, tricyclodecane or tetracyclododecane.

As the chain-like hydrocarbon group, a chain-like alkyl group is preferable. The chain-like alkyl group preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group or a 4-methylpentyl group.

When the chain-like alkyl group is a fluorinated alkyl group containing a fluorine atom or a fluorinated alkyl group as a substituent, the fluorinated alkyl group preferably has 1 to 11 carbon atoms, more preferably 1 to 8, and still more preferably 1 to 4. The fluorinated alkyl group for may contain an atom other than fluorine. Examples of the atom other than fluorine include an oxygen atom, a carbon atom, a hydrogen atom, a sulfur atom and a nitrogen atom.

As for Rd¹, a fluorinated alkyl group in which part or all of the hydrogen atoms constituting a linear alkyl group have been substituted with fluorine atom(s) is preferable, and a fluorinated alkyl group in which all of the hydrogen atoms constituting a linear alkyl group have been substituted with fluorine atoms (i.e., a linear perfluoroalkyl group) is more preferable.

Specific examples of preferable anion moieties for the component (d1-1) are shown below.

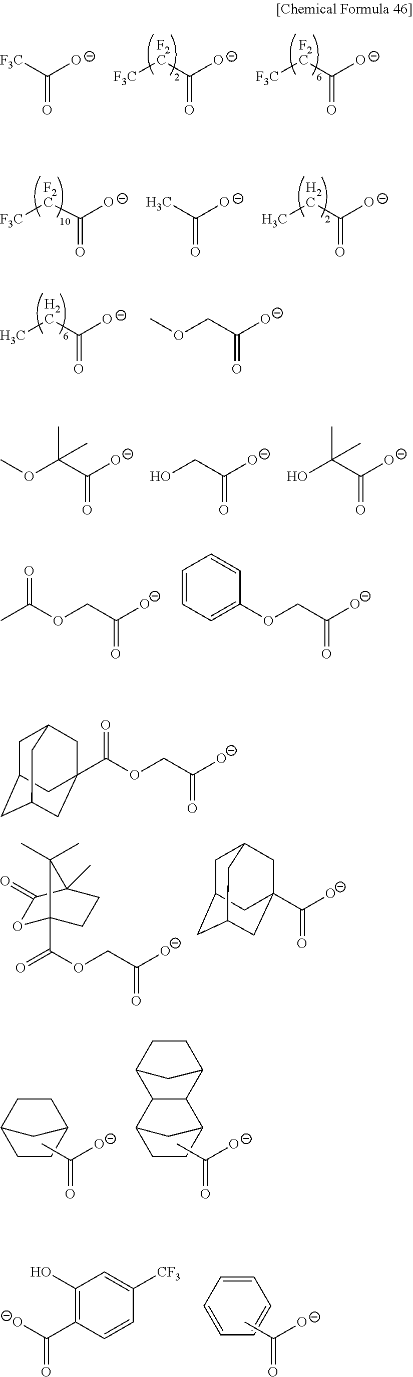

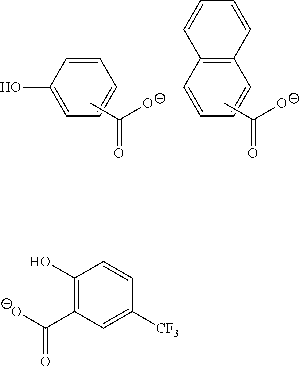

Cation Moiety

In formula (d1-1), M^{m+} represents an organic cation having a valency of m.

The organic cation for M^{m+} is not particularly limited, and examples thereof include the same cation moieties as those represented by the aforementioned formulas (ca-1) to (ca-4), and cation moieties represented by the aforementioned formulas (ca-1-1) to (ca-1-63) are preferable.

As the component (d1-1), one type of compound may be used, or two or more types of compounds may be used in combination.

{Component (d1-2)}•Anion Moiety

In formula (d1-2), Rd² represents a cyclic group which may have a substituent, a chain-like alkyl group which may have a substituent or a chain-like alkenyl group which may have a substituent, and is the same groups as those defined above for R¹⁰¹,

provided that, the carbon atom within Rd² group adjacent to the sulfur atom has no fluorine atom bonded thereto (i.e., the carbon atom within Rd² group adjacent to the sulfur atom is not substituted with a fluorine atom). As a result, the anion of the component (d1-2) becomes an appropriately weak acid anion, thereby improving the quenching ability of the component (D).

As Rd², an aliphatic cyclic group which may have a substituent is preferable, and a group in which one or more hydrogen atoms have been removed from adamantane, norbornane, isobornane, tricyclodecane or tetracyclododecane (which may have a substituent); or a group in which one or more hydrogen atoms have been removed from camphor is more preferable.

The hydrocarbon group for Rd² may have a substituent. As the substituent, the same groups as those described above for substituting the hydrocarbon group (e.g., aromatic hydrocarbon group, aliphatic hydrocarbon group) for Rd¹ in the formula (d1-1) can be mentioned.

Specific examples of preferable anion moieties for the component (d1-2) are shown below.

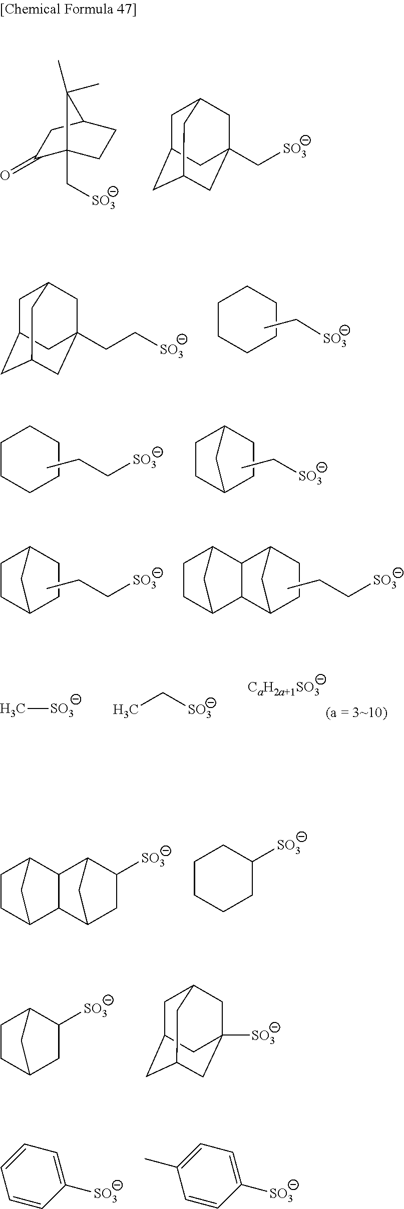

Cation Moiety

In formula (d1-2), M^{m+} is an organic cation having a valency of m, and is the same as defined for M^{m+} in the aforementioned formula (d1-1).

As the component (d1-2), one type of compound may be used, or two or more types of compounds may be used in combination.

{Component (d1-3)}•Anion moiety

In formula (d1-3), Rd³ represents a cyclic group which may have a substituent, a chain-like alkyl group which may have a substituent or a chain-like alkenyl group which may have a substituent, and is the same groups as those defined above for R¹⁰¹, and a cyclic group containing a fluorine atom, a chain-like alkyl group or a chain-like alkenyl group is preferable. Among these, a fluorinated alkyl group is preferable, and more preferably the same fluorinated alkyl groups as those described above for Rd¹.

In formula (d1-3), Rd⁴ represents a cyclic group which may have a substituent, a chain-like alkyl group which may have a substituent or a chain-like alkenyl group which may have a substituent, and is the same groups as those defined above for R¹⁰¹.

Among these, an alkyl group which may have substituent, an alkoxy group which may have substituent, an alkylene group which may have substituent or a cyclic group which may have substituent is preferable.

The alkyl group for Rd⁴ is preferably a linear or branched alkyl group of 1 to 5 carbon atoms, and specific examples include a methyl group, an ethyl group, a propyl group, an isopropyl group, an n-butyl group, an isobutyl group, a tert-butyl group, a pentyl group, an isopentyl group, and a neopentyl group. Part of the hydrogen atoms within the alkyl group for Rd⁴ may be substituted with a hydroxy group, a cyano group or the like.

The alkoxy group for Rd⁴ is preferably an alkoxy group of 1 to 5 carbon atoms, and specific examples thereof include a methoxy group, an ethoxy group, an n-propoxy group, an iso-propoxy group, an n-butoxy group and a tert-butoxy group. Among these, a methoxy group and an ethoxy group are desirable.

As the alkenyl group for Rd⁴, the same groups as those described above for R¹⁰¹ can be mentioned, and a vinyl group, a propenyl group (an allyl group), a 1-methylpropenyl group and a 2-methylpropenyl group are preferable. These groups may have an alkyl group of 1 to 5 carbon atoms or a halogenated alkyl group of 1 to 5 carbon atoms as a substituent.

As the cyclic group for Rd⁴, the same groups as those described above for R¹⁰¹ can be mentioned. Among these, as the cyclic group, an alicyclic group (e.g., a group in which one or more hydrogen atoms have been removed from a cycloalkane such as cyclopentane, cyclohexane, adamantane, norbornane, isobornane, tricyclodecane or tetracyclododecane) or an aromatic group (e.g., a phenyl group or a naphthyl group) is preferable. When Rd⁴ is an alicyclic group, the resist composition can be satisfactorily dissolved in an organic solvent, thereby improving the lithography properties. Alternatively, when Rd⁴ is an aromatic group, the resist composition exhibits an excellent photoabsorption efficiency in a lithography process using EUV or the like as the exposure source, thereby resulting in the improvement of the sensitivity and the lithography properties.

In formula (d1-3), Yd¹ represents a single bond or a divalent linking group.

The divalent linking group for Yd¹ is not particularly limited, and examples thereof include a divalent hydrocarbon group (aliphatic hydrocarbon group, or aromatic hydrocarbon group) which may have a substituent and a divalent linking group containing a hetero atom. As such groups, the same divalent linking groups as those described above for Ya²¹ in the formula (a2-1) can be mentioned.

As Yd¹, a carbonyl group, an ester bond, an amide bond, an alkylene group or a combination of these groups is preferable. As the alkylene group, a linear or branched alkylene group is more preferable, and a methylene group or an ethylene group is still more preferable.

Specific examples of preferable anion moieties for the component (d1-3) are shown below.

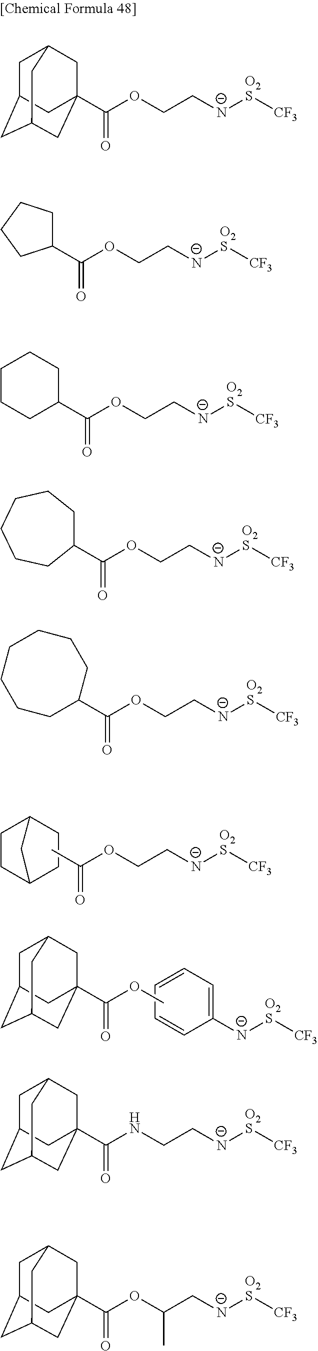

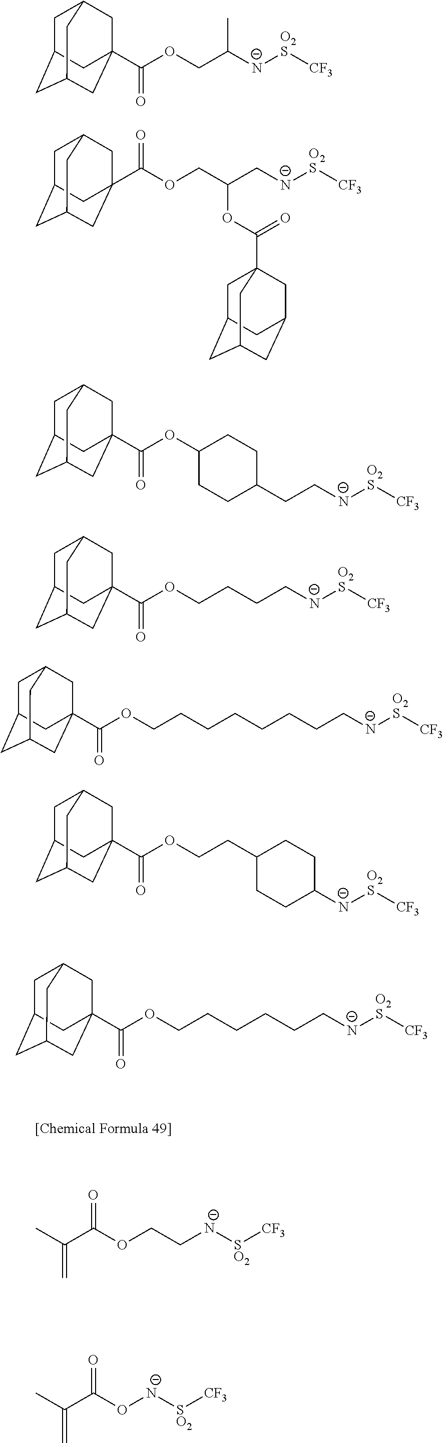

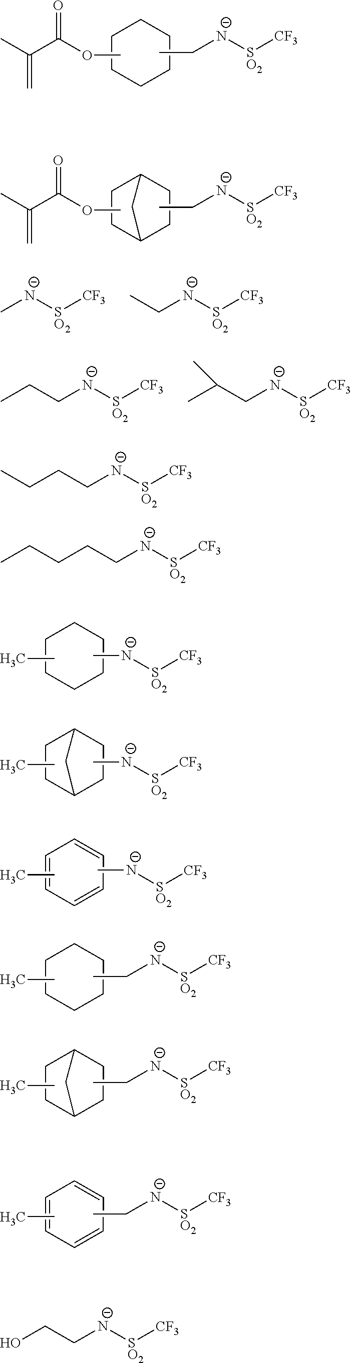

Cation Moiety

In formula (d1-3), M^{m+} is an organic cation having a valency of m, and is the same as defined for M^{m+} in the aforementioned formula (d1-1).

As the component (d1-3), one type of compound may be used, or two or more types of compounds may be used in combination.

As the component (D1), one type of the aforementioned components (d1-1) to (d1-3) can be used, or at least two types of the aforementioned components (d1-1) to (d1-3) can be used in combination.

The amount of the component (D1) relative to 100 parts by weight of the component (A′) is preferably within a range from 0.5 to 10 parts by weight, more preferably from 0.5 to 8 parts by weight, and still more preferably from 1 to 8 parts by weight.

When the amount of the component (D1) is at least as large as the lower limit of the above-mentioned range, excellent lithography properties and excellent resist pattern shape can be obtained. On the other hand, when the amount of the component (D1) is no more than the upper limit of the above-mentioned range, sensitivity can be maintained at a satisfactory level, and through-put becomes excellent.

The production methods of the components (d1-1) and (d1-2) are not particularly limited, and the components (d1-1) and (d1-2) can be produced by conventional methods.

The amount of the component (D1) relative to 100 parts by weight of the component (A′) is preferably within a range from 0.5 to 10.0 parts by weight, more preferably from 0.5 to 8.0 parts by weight, and still more preferably from 1.0 to 8.0 parts by weight. When the amount is at least as large as the lower limit of the above-mentioned range, excellent lithography properties and excellent resist pattern shape can be obtained. On the other hand, when the amount is no more than the upper limit of the above-mentioned range, sensitivity can be maintained at a satisfactory level, and throughput becomes excellent.

(Component (D2))

The component (D) may contain a nitrogen-containing organic compound (D2) (hereafter, referred to as component (D2)) which does not fall under the definition of component (D1).

The component (D2) is not particularly limited, as long as it functions as an acid diffusion control agent, and does not fall under the definition of the component (D1). As the component (D2), any of the conventionally known compounds may be selected for use. Among these, an aliphatic amine, particularly a secondary aliphatic amine or tertiary aliphatic amine is preferable.

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group of no more than 12 carbon atoms (i.e., alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, and tri-n-octanolamine. Among these, trialkylamines of 5 to 10 carbon atoms are preferable, and tri-n-pentylamine and tri-n-octylamine are particularly desirable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine, and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris {2-(2-methoxyethoxy)ethyl}amine, tris {2-(2-methoxyethoxymethoxy)ethyl}amine, tris {2-(1-methoxyethoxy)ethyl}amine, tris {2-(1-ethoxyethoxy)ethyl}amine, tris {2-(1-ethoxypropoxy)ethyl}amine, tris[2-{2-(2-hydroxyethoxy)ethoxy}ethyl]amine and triethanolamine triacetate, and triethanolamine triacetate is preferable.

Further, as the component (D2), an aromatic amine may be used.

Examples of aromatic amines include aniline, pyridine, 4-dimethylaminopyridine, pyrrole, indole, pyrazole, imidazole and derivatives thereof, as well as diphenylamine, triphenylamine, tribenzylamine, 2,6-diisopropylaniline and N-tert-butoxycarbonylpyrrolidine.

As the component (D2), one type of compound may be used alone, or two or more types may be used in combination.

The component (D2) is typically used in an amount within a range from 0.01 to 5.0 parts by weight, relative to 100 parts by weight of the component (A′). When the amount of the component (D2) is within the above-mentioned range, the shape of the resist pattern and the post exposure stability of the latent image formed by the pattern-wise exposure of the resist layer are improved.

As the component (D), one type of compound may be used, or two or more types of compounds may be used in combination.

When the resist composition 1 of the present invention contains the component (D), the amount of the component (D) relative to 100 parts by weight of the component (A′) is preferably within a range from 0.1 to 15 parts by weight, more preferably from 0.3 to 12 parts by weight, and still more preferably from 0.5 to 12 parts by weight. When the amount of the component (D) is at least as large as the lower limit of the above-mentioned range, various lithography properties (such as LWR) of the resist composition are improved. Further, a resist pattern having an excellent shape can be obtained. On the other hand, when the amount is no more than the upper limit of the above-mentioned range, sensitivity can be maintained at a satisfactory level, and throughput becomes excellent.

<Optional Components>

[Component (E)]

Furthermore, in the resist composition 1 of the present invention, for preventing any deterioration in sensitivity, and improving the resist pattern shape and the post exposure stability of the latent image formed by the pattern-wise exposure of the resist layer, at least one compound (E) (hereafter referred to as the component (E)) selected from the group consisting of an organic carboxylic acid, or a phosphorus oxo acid or derivative thereof can be added.

Examples of suitable organic carboxylic acids include acetic acid, malonic acid, citric acid, malic acid, succinic acid, benzoic acid, and salicylic acid.

Examples of phosphorus oxo acids include phosphoric acid, phosphonic acid and phosphinic acid. Among these, phosphonic acid is particularly desirable.

Examples of phosphorous oxo acid derivatives include esters in which a hydrogen atom within the above-mentioned phosphorous oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenyl phosphonate, diphenyl phosphonate and dibenzyl phosphonate.

Examples of phosphinic acid derivatives include phenylphosphinic acid and phosphinic acid esters.

As the component (E), one type may be used alone, or two or more types may be used in combination.

The component (E) is typically used in an amount within a range from 0.01 to 5.0 parts by weight, relative to 100 parts by weight of the component (A′).

[Component (F)]

In the present invention, the resist composition 1 may further include a fluorine additive (hereafter, referred to as “component (F)”) for imparting water repellency to the resist film.

As the component (F), for example, a fluorine-containing polymeric compound described in Japanese Unexamined Patent Application, First Publication No. 2010-002870, Japanese Unexamined Patent Application, First Publication No. 2010-032994, Japanese Unexamined Patent Application, First Publication No. 2010-277043, Japanese Unexamined Patent Application, First Publication No. 2011-13569, and Japanese Unexamined Patent Application, First Publication No. 2011-128226 can be used.

Specific examples of the component (F) include polymers having a structural unit (f1) represented by general formula (f1-1) shown below. As the polymer, a polymer (homopolymer) consisting of a structural unit (f1) represented by formula (f1-1) shown below; a copolymer of a structural unit (f1) represented by formula (f1-1) shown below and the aforementioned structural unit (a1); and a copolymer of a structural unit (f1) represented by the formula (f1-1) shown below, a structural unit derived from acrylic acid or methacrylic acid and the aforementioned structural unit (a1) are preferable. As the structural unit (a1) to be copolymerized with a structural unit (f1) represented by formula (f1-1) shown below, a structural unit derived from 1-ethyl-1-cyclooctyl (meth)acrylate or a structural unit represented by the aforementioned formula (a1-2-01) is preferable.

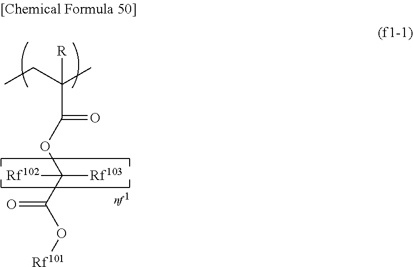

In the formula, R is the same as defined above; Rf¹⁰² and Rf¹⁰³ each independently represents a hydrogen atom, a halogen atom, an alkyl group of 1 to 5 carbon atoms, or a halogenated alkyl group of 1 to 5 carbon atoms, provided that Rf¹⁰² and Rf¹⁰³ may be the same or different; nf¹ represents an integer of 1 to 5; and Rf¹⁰¹ represents an organic group containing a fluorine atom.

In formula (f1-1), R is the same as defined above. As R, a hydrogen atom or a methyl group is preferable.

In formula (f1-1), examples of the halogen atom for Rf¹⁰² and Rf¹⁰³ include a fluorine atom, a chlorine atom, a bromine atom and an iodine atom, and a fluorine atom is particularly desirable. Examples of the alkyl group of 1 to 5 carbon atoms for Rf¹⁰² and Rf¹⁰³ include the same alkyl group of 1 to 5 carbon atoms as those described above for R, and a methyl group or an ethyl group is preferable. Specific examples of the halogenated alkyl group of 1 to 5 carbon atoms represented by Rf¹⁰² and Rf¹⁰³ include groups in which part or all of the hydrogen atoms of the aforementioned alkyl groups of 1 to 5 carbon atoms have been substituted with halogen atoms. Examples of the halogen atom include a fluorine atom, a chlorine atom, a bromine atom and an iodine atom, and a fluorine atom is particularly desirable. Among these, as Rf¹⁰² and Rf¹⁰³, a hydrogen atom, a fluorine atom or an alkyl group of 1 to 5 carbon atoms is preferable, and a hydrogen atom, a fluorine atom, a methyl group or an ethyl group is more preferable.

In formula (f1-1), nf¹ represents an integer of 1 to 5, preferably an integer of 1 to 3, and more preferably 1 or 2.

In formula (f1-1), Rf¹⁰¹ represents an organic group containing a fluorine atom, and is preferably a hydrocarbon group containing a fluorine atom.

The hydrocarbon group containing a fluorine atom may be linear, branched or cyclic, and preferably has 1 to 20 carbon atoms, more preferably 1 to 15 carbon atoms, and most preferably 1 to 10 carbon atoms.

It is preferable that the hydrocarbon group having a fluorine atom has 25% or more of the hydrogen atoms within the hydrocarbon group fluorinated, more preferably 50% or more, and most preferably 60% or more, as the hydrophobicity of the resist film during immersion exposure is enhanced.

Among these, as Rf¹⁰¹, a fluorinated hydrocarbon group of 1 to 5 carbon atoms is preferable, and a methyl group, —CH₂—CF₃, —CH₂—CF₂—CF₃, —CH(CF₃)₂, —CH₂—CH₂—CF₃ and —CH₂—CH₂—CF₂—CF₂—CF₂—CF₃ are most preferable.

The weight average molecular weight (Mw) (the polystyrene equivalent value determined by gel permeation chromatography) of the component (F) is preferably 1,000 to 50,000, more preferably 5,000 to 40,000, and most preferably 10,000 to 30,000. When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the component (F) is preferably 1.0 to 5.0, more preferably 1.0 to 3.0, and most preferably 1.2 to 2.5.

As the component (F), one type may be used alone, or two or more types may be used in combination.

The component (F) is typically used in an amount within a range from 0.5 to 10 parts by weight, relative to 100 parts by weight of the component (A′).

If desired, other miscible additives can also be added to the resist composition 1 of the present invention. Examples of such miscible additives include additive resins for improving the performance of the resist film, dissolution inhibitors, plasticizers, stabilizers, colorants, halation prevention agents, and dyes.

[Component (S)]

The resist composition 1 of the present invention can be prepared by dissolving the materials for the resist composition in an organic solvent (hereafter, frequently referred to as “component (S)”).

The component (S) may be any organic solvent which can dissolve the respective components to give a uniform solution, and one or more kinds of any organic solvent can be appropriately selected from those which have been conventionally known as solvents for a chemically amplified resist.

Examples thereof include lactones such as γ-butyrolactone; ketones such as acetone, methyl ethyl ketone (MEK), cyclohexanone, methyl-n-pentyl ketone (2-heptanone), and methyl isopentyl ketone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene; and dimethylsulfoxide (DMSO).

These solvents can be used individually, or in combination as a mixed solvent.

Among these, PGMEA, PGME, γ-butyrolactone and EL are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2.

Specifically, when EL or cyclohexanone is mixed as the polar solvent, the PGMEA:EL weight ratio or PGMEA:cyclohexanone weight ratio is preferably from 1:9 to 9:1, and more preferably from 2:8 to 8:2. Alternatively, when PGME is mixed as the polar solvent, the PGMEA:PGME is preferably from 1:9 to 9:1, more preferably from 2:8 to 8:2, and still more preferably 3:7 to 7:3.

Further, as the component (S), a mixed solvent of at least one of PGMEA and EL with γ-butyrolactone is also preferable. The mixing ratio (former:latter) of such a mixed solvent is preferably from 70:30 to 95:5.

The amount of the component (S) is not particularly limited, and is appropriately adjusted to a concentration which enables coating of a resist solution to a substrate. In general, the organic solvent is used in an amount such that the solid content of the resist composition becomes within the range from 1 to 20% by weight, and preferably from 2 to 15% by weight.

<<Polymeric Compound>>

A second aspect of the present invention is a polymeric compound having a structural unit (a0) derived from a compound represented by general formula (a0-1) shown below.

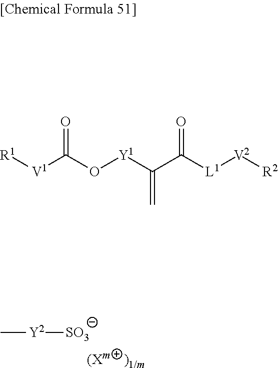

In the formula, R¹ and R² each independently represents a group represented by general formula (a0-2) or a function group, provided that at least one of R¹ and R² represents a group represented by general formula (a0-2);

V¹ represents a single bond, an oxygen atom, or an alkylene group of 1 to 10 carbon atoms which may have a substituent; V² represents a single bond or an alkylene group of 1 to 10 carbon atoms which may have a substituent;

Y¹ represents a single bond or a divalent linking group; Y² represents a fluorinated alkylene group of 1 to 4 carbon atoms which may have a substituent; L¹ represents an oxygen atom or a group represented by —NR′¹—, R′¹ represents a hydrogen atom or an alkylene group of 1 to 5 carbon atoms; X^{m+} represents a metal cation or an organic cation having a valency of m; and m represents an integer of 1 or more.

In the formula (a0-1), R¹, R², V¹, V², Y¹, Y², and L¹ are the same as defined above.

In the formula (a0-2), X^{m+} represents a metal cation or an organic cation having a valency of m, wherein m represents an integer of 1 or more.

X⁺ represents a metal cation or an organic cation, and examples thereof include an alkali metal cation as a metal cation and an organic cation. Examples of alkali metal ions include a sodium ion, a lithium ion and a potassium ion, and a sodium ion or a lithium ion is preferable. As the organic cation, a cation containing a nitrogen atom such as an ammonium ion and a pyridinium ion, and the same organic cations as those described above for M^{m+} in the formulae (b-1) to (b-3) can be mentioned.

It is preferable that the polymeric compound of the present invention further includes a structural unit (a1) containing an acid decomposable group that exhibits increased polarity by the action of acid. The structural unit (a1) which is preferably contained in the polymeric compound of the present invention is the same as the structural unit (a1) which is preferably contained in the polymeric compound (A1′).

The polymeric compound of the present invention may also include the structural units (a2) to (a4). The structural units (a2) to (a4) which are preferably contained in the polymeric compound of the present invention is the same as the structural units (a2) to (a4) which are preferably contained in the polymeric compound (A1′). The molecular weight and the dispersity of the polymeric compound of the present invention are the same as those explained in relation to the component (A1′).

<Compound>

A third aspect of the present invention is a compound represented by general formula (a0-1) shown below.

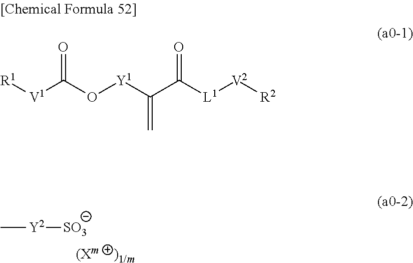

In the formula, R¹ and R² each independently represents a group represented by general formula (a0-2) or a function group, provided that at least one of R¹ and R² represents a group represented by general formula (a0-2);

V¹ represents a single bond, an oxygen atom, or an alkylene group of 1 to 10 carbon atoms which may have a substituent; V² represents a single bond or an alkylene group of 1 to 10 carbon atoms which may have a substituent;

Y¹ represents a single bond or a divalent linking group; Y² represents a fluorinated alkylene group of 1 to 4 carbon atoms which may have a substituent; L¹ represents an oxygen atom or a group represented by —NR′¹—, R′¹ represents a hydrogen atom or an alkylene group of 1 to 5 carbon atoms; X^{m+} represents a metal cation or an organic cation having a valency of m; and m represents an integer of 1 or more.

In the formulae (a0-1) and (a0-2), R¹, R², V¹, V², Y¹, Y², and L¹ and X^{m+} are the same as defined above.

<<Resist Composition 2>>

Specifically, a fourth aspect of the present invention is a resist composition including a base component (A) which exhibits changed solubility in a developing solution under action of acid, and an acid generator component (B′) which generates acid upon exposure, the acid generator component (B′) including an acid generator (B1′) represented by general formula (a0-1) shown below (hereafter, sometimes referred to as “resist composition 2”).

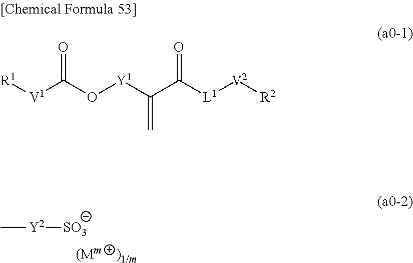

In the formula, R¹ and R² each independently represents a group represented by general formula (a0-2) or a function group, provided that at least one of R¹ and R² represents a group represented by general formula (a0-2);

V¹ represents a single bond, an oxygen atom, or an alkylene group of 1 to 10 carbon atoms which may have a substituent; V² represents a single bond or an alkylene group of 1 to 10 carbon atoms which may have a substituent;

Y¹ represents a single bond or a divalent linking group; Y² represents a fluorinated alkylene group of 1 to 4 carbon atoms which may have a substituent; L¹ represents an oxygen atom or a group represented by —NR′¹—, R′¹ represents a hydrogen atom or an alkylene group of 1 to 5 carbon atoms; M^{m+} represents an organic cation having a valency of m; and m represents an integer of 1 or more.

<Component (A)>

As the component (A), an organic compound typically used as a base component for a chemically amplified resist composition can be used alone, or two or more of such organic compounds can be mixed together.

In the resist composition 2 of the present invention, the component (A) is a base component which exhibits changed solubility in a developing solution under action of acid.

[Component (A)]

As the component (A), a resin component (base resin) typically used as a base component for a chemically amplified resist composition can be used alone, or two or more of such resin components can be mixed together.

In the present invention, the component (A) preferably has a structural unit derived from an acrylate ester which may have the hydrogen atom bonded to the carbon atom on the α-position substituted with a substituent or an atom other than the hydrogen atom.

In the resist composition 2 of the present invention, it is particularly desirable that the component (A) has a structural unit (a1) derived from an acrylate ester which may have the hydrogen atom bonded to the carbon atom on the α-position substituted with a substituent or an atom other than the hydrogen atom, and contains an acid decomposable group which exhibits increased polarity by the action of acid.

In the component (A), the amount of the structural unit (a1) based on the combined total of all structural units constituting the component (A) is preferably 15 to 80 mol %, more preferably 20 to 75 mol %, and still more preferably 25 to 70 mol %. When the amount of the structural unit (a1) is at least as large as the lower limit of the above-mentioned range, various lithography properties such as sensitivity, resolution, roughness and the like are improved. On the other hand, when the amount of the structural unit (a1) is no more than the upper limit of the above-mentioned range, a good balance can be achieved with the other structural units.

The component (A1) preferably includes, in addition to the structural unit (a1), at least one structural unit (a2) selected from the group consisting of a structural unit derived from an acrylate ester containing an —SO₂— containing cyclic group and which may have the hydrogen atom bonded to the carbon atom on the α-position substituted with a substituent or an atom other than the hydrogen atom and a structural unit derived from an acrylate ester containing a lactone-containing cyclic group and which may have the hydrogen atom bonded to the carbon atom on the α-position substituted with a substituent or an atom other than the hydrogen atom.

Furthermore, it is preferable that the component (A) include a structural unit (a3) derived from an acrylate ester containing a polar group-containing aliphatic hydrocarbon group and may have the hydrogen atom bonded to the carbon atom on the α-position substituted with a substituent or an atom other than the hydrogen atom, as well as the structural unit (a1), or the structural unit (a1) and the structural unit (a2).

The component (A) may also include a structural unit (a4) which is other than the above-mentioned structural units (a1) to (a3).

The structural units (a1) to (a4) are respectively the same as defined for the structural units (a1) to (a4) in the resist composition 1 of the third aspect of the present invention. The component (A1) is the same as the component (A1′), except that the structural unit (a0) is not included as an essential structural unit in the component (A1).

<Component (B′)>[Component (B1′)]

The resist composition 2 of the present invention includes an acid generator component (B′) (hereafter, sometimes referred to as “component (B′)”) which generates acid upon exposure, the acid generator component (B′) including an acid generator (B1′) containing a compound represented by general formula (a0-1).

The explanation of the compound represented by general formula (a0-1) is the same as those above.

As the component (B1′), one type of acid generator may be used alone, or two or more types may be used in combination.

In the resist composition 2 of the present invention, the amount of the component (B1′) within the component (B′) is preferably 40% by weight or more, still more preferably 60% by weight or more, and may be even 100% by weight.

In the case of the component (B1′) is used with a component (B2′) in combination, the amount of the component (B1′) within the component (B′) is preferably in the range of 50 to 95% by weight, and 60 to 85% by weight is more preferable. As the component (B2′), the onium salt acid generators represented by the formulae (b-1) to (b-3) are preferable.

[Component (B2′)]

In the resist composition 2 of the present invention, if desired, the component (B′) may further include an acid generator component which cannot be classified as the component (B1′) (hereafter, referred to as “component (B2′)”), in addition to the component (B1′).

The component (B2′) is not particularly limited, and for example, an acid generator which does not fall under the definition of the component (B1′) and is exemplified as the component (B) as an optional component in relation to the resist composition 1 of the third aspect of the present invention can be mentioned.

As the component (B2′), one type of acid generator may be used, or two or more types may be used in combination.

In the resist composition 2 of the present invention, the amount of the component (B′) relative to 100 parts by weight of the component (A) is preferably 1 to 70 parts by weight, more preferably 3 to 60 parts by weight, and most preferably 5 to 50 parts by weight. When the amount of the component (B′) is within the above-mentioned range, formation of a resist pattern can be satisfactorily performed. Further, by virtue of the above-mentioned range, a uniform solution can be obtained and the storage stability becomes satisfactory.

The resist composition 2 of the present invention may include the component (D), component (E), and component (F) as an optional component, like as the resist composition 1 of the first aspect of the present invention, and may be dissolved in the component (S). The component (D), component (E), component (F), and component (S) are the same as those in the resist composition 1 of the first aspect.

<<Method of Forming a Resist Pattern>>

The method of forming a resist pattern of the fifth aspect of the present invention includes: forming a resist film on a substrate using a resist composition 1 or resist composition 2 of the present invention; conducting exposure of the resist film; and developing the resist film to form a resist pattern.

The method for forming a resist pattern according to the present invention can be performed, for example, as follows.

Firstly, a resist composition of the present invention is applied to a substrate using a spinner or the like, and a bake treatment (post applied bake (PAB)) is conducted at a temperature of 80 to 150° C. for 40 to 120 seconds, preferably 60 to 90 seconds, to form a resist film.

Following selective exposure of the thus formed resist film, either by exposure through a mask having a predetermined pattern formed thereon (mask pattern) using an exposure apparatus such as an ArF exposure apparatus, an electron beam lithography apparatus or an EUV exposure apparatus, or by patterning via direct irradiation with an electron beam without using a mask pattern, baking treatment (post exposure baking (PEB)) is conducted under temperature conditions of 80 to 150° C. for 40 to 120 seconds, and preferably 60 to 90 seconds.

Next, the resist film is subjected to a developing treatment.

The developing treatment is conducted using an alkali developing solution in the case of an alkali developing process, and a developing solution containing an organic solvent (organic developing solution) in the case of a solvent developing process.

After the developing treatment, it is preferable to conduct a rinse treatment. The rinse treatment is preferably conducted using pure water in the case of an alkali developing process, and a rinse solution containing an organic solvent in the case of a solvent developing process.

In the case of a solvent developing process, after the developing treatment or the rinsing, the developing solution or the rinse liquid remaining on the pattern can be removed by a treatment using a supercritical fluid.

After the developing treatment or the rinse treatment, drying is conducted. If desired, bake treatment (post bake) can be conducted following the developing. In this manner, a resist pattern can be obtained.

The substrate is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic anti-reflection film (inorganic BARC) can be used. As the organic film, an organic antireflection film (organic BARC) and an organic film such as a lower-layer organic film used in a multilayer resist method can be used.

Here, a “multilayer resist method” is method in which at least one layer of an organic film (lower-layer organic film) and at least one layer of a resist film (upper resist film) are provided on a substrate, and a resist pattern formed on the upper resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is broadly classified into a method in which a double-layer structure consisting of an upper-layer resist film and a lower-layer organic film is formed (double-layer resist method), and a method in which a multilayer structure having at least three layers consisting of an upper-layer resist film, a lower-layer organic film and at least one intermediate layer (thin metal film or the like) provided between the upper-layer resist film and the lower-layer organic film is formed (triple-layer resist method).

The wavelength to be used for exposure is not particularly limited and the exposure can be conducted using radiations such as ArF excimer laser, KrF excimer laser, F₂ excimer laser, extreme ultraviolet rays (EUV), vacuum ultraviolet rays (VUV), electron beam (EB), X-rays, and soft X-rays. The resist composition of the present invention is effective to KrF excimer laser, ArF excimer laser, EB and EUV.

The exposure of the resist film can be either a general exposure (dry exposure) conducted in air or an inert gas such as nitrogen, or immersion exposure (immersion lithography).

In immersion lithography, the region between the resist film and the lens at the lowermost point of the exposure apparatus is pre-filled with a solvent (immersion medium) that has a larger refractive index than the refractive index of air, and the exposure (immersion exposure) is conducted in this state.

The immersion medium preferably exhibits a refractive index larger than the refractive index of air but smaller than the refractive index of the resist film to be exposed. The refractive index of the immersion medium is not particularly limited as long as it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which preferably have a boiling point within a range from 70 to 180° C. and more preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

As the immersion medium, water is preferable in terms of cost, safety, environment and versatility.

As an example of the alkali developing solution used in an alkali developing process, a 0.1 to 10% by weight aqueous solution of tetramethylammonium hydroxide (TMAH) can be given.

As the organic solvent contained in the organic developing solution used in a solvent developing process, any of the conventional organic solvents can be used which are capable of dissolving the component (A′) (prior to exposure) or component (A) (prior to exposure). Specific examples of the organic solvent include polar solvents such as ketone solvents, ester solvents, alcohol solvents, amide solvents and ether solvents, and hydrocarbon solvents.

If desired, the organic developing solution may have a conventional additive blended. Examples of the additive include surfactants. The surfactant is not particularly limited, and for example, an ionic or non-ionic fluorine and/or silicon surfactant can be used.

When a surfactant is added, the amount thereof based on the total amount of the organic developing solution is generally 0.001 to 5% by weight, preferably 0.005 to 2% by weight, and more preferably 0.01 to 0.5% by weight.

The developing treatment can be performed by a conventional developing method. Examples thereof include a method in which the substrate is immersed in the developing solution for a predetermined time (a dip method), a method in which the developing solution is cast up on the surface of the substrate by surface tension and maintained for a predetermined period (a puddle method), a method in which the developing solution is sprayed onto the surface of the substrate (spray method), and a method in which the developing solution is continuously ejected from a developing solution ejecting nozzle while scanning at a constant rate to apply the developing solution to the substrate while rotating the substrate at a constant rate (dynamic dispense method).

The rinse treatment using a rinse liquid (washing treatment) can be conducted by a conventional rinse method. Examples of the rinse method include a method in which the rinse liquid is continuously applied to the substrate while rotating it at a constant rate (rotational coating method), a method in which the substrate is immersed in the rinse liquid for a predetermined time (dip method), and a method in which the rinse liquid is sprayed onto the surface of the substrate (spray method).

The resist composition of the present invention includes a polymeric compound containing a structural unit having a function group, and the structural unit is useful for construction of polymeric compound, and therefore, it is presumed that the resist composition of the present invention exhibits excellent lithography properties.

### EXAMPLES

As follows is a description of examples of the present invention, although the scope of the present invention is by no way limited by these examples.

### Synthesis Example of Compound

10.0 g of compound (i) shown below and 1.96 g of formaldehyde were added to a double layer solution containing 59.0 g of tetrahydrofuran (hereafter, referred to as “THF”) and 59.0 g of water. 32.9 g of 1,4-diazabicyclo[2.2.2]octane (hereafter, referred to as DABCO) was added the obtained solution. The solution was heated to 90° C. and reaction was conducted for 12 hours, and was then cooled to room temperature. Then, the tetrahydrofuran phase was separated and collected, 28.7 g of compound (ii) shown below was added to the tetrahydrofuran phase, and then 1.5 g of diisopropylcarbodiimide (hereafter, referred to as DIC) was added, followed by effecting a reaction. Thereafter, 59.0 g of diluted hydrochloric acid was added thereto to stop the reaction. Subsequently, the reaction solution was washed with pure water three times, and 117.9 g of hexane was added thereto, thereby obtaining 9.4 g of compound (1) shown below.

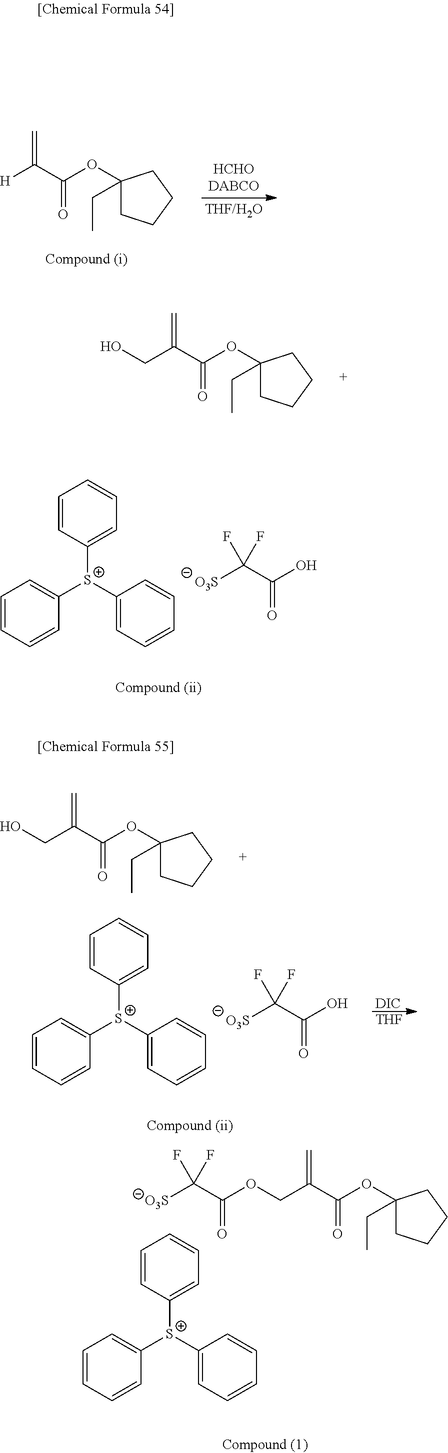

The obtained compound (1) was analyzed by NMR, and the structure thereof was identified by the following results.

¹H-NMR (400 MHz, DMSO-d6): δ(ppm)=7.25-7.91 (15H, CH), 6.10 (1H, C═CH), 5.96 (1H, C═CH), 5.58 (2H, CH), 2.35-2.41 (4H, CH), 2.03-2.11 (4H, CH), 1.68-1.75 (2H, CH), 1.30-1.48 (2H, CH), 0.91 (3H, CH)

The same procedure as in [Synthesis Example of Compound] was performed, thereby obtaining compounds (2) to (9) shown below. The results of the NMR analysis and structure of the compounds (2) to (9) are shown below.

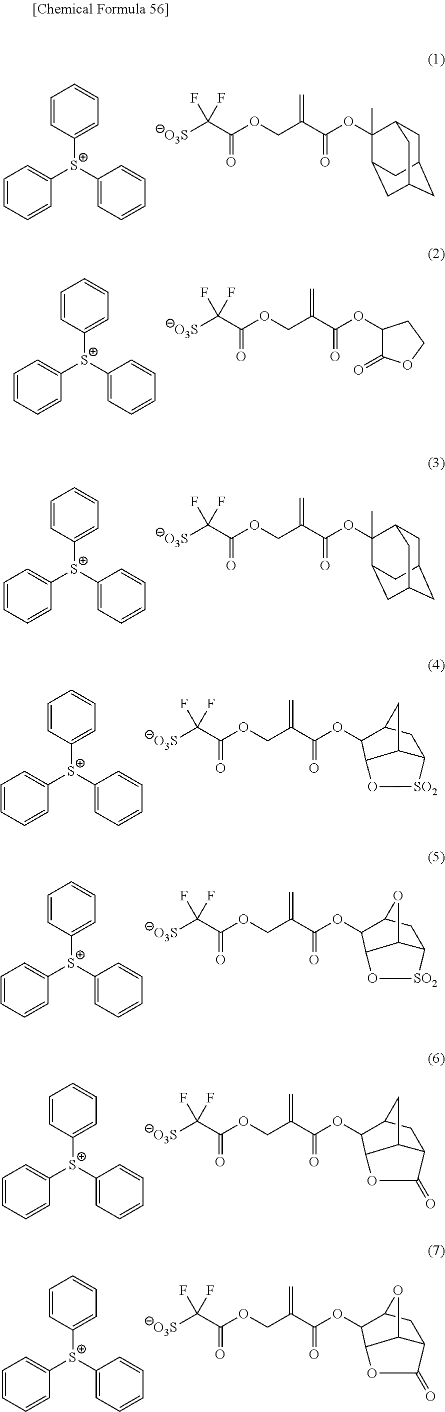

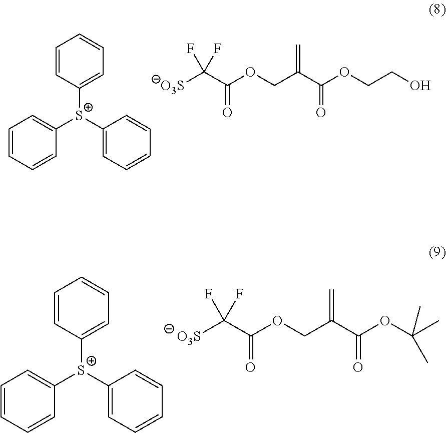

[Results of NMR Analysis]

Compound (2): ¹H-NMR (400 MHz, DMSO-d6): δ(ppm)=7.25-7.91 (15H, CH), 6.22 (1H, C═CH), 6.12 (1H, C═CH), 6.08 (1H, CH), 5.58 (2H, CH), 3.91-4.06 (2H, CH), 2.67-2.78 (2H, CH)

Compound (3): ¹H-NMR (400 MHz, DMSO-d6): δ(ppm)=7.25-7.91 (15H, CH), 6.20 (1H, C═CH), 6.06 (1H, C═CH), 5.60 (2H, CH), 2.06 (1H, CH), 1.81-2.08 (14H, CH), 1.36 (3H, CH)

Compound (4): ¹H-NMR (400 MHz, DMSO-d6): δ(ppm)=7.25-7.91 (15H, CH), 6.06 (1H, CH), 5.98 (1H, C═CH), 5.84 (1H, C═CH), 5.55 (2H, CH), 4.71-4.76 (1H, CH), 4.57-4.61 (1H, CH), 3.26-3.31 (1H, CH), 2.67-2.71 (1H, CH), 2.14-2.25 (2H, CH), 1.71 (2H, CH (1.35-1.47 (4H, CH)

Compound (5): ¹H-NMR (400 MHz, DMSO-d6): δ(ppm)=7.25-7.91 (15H, CH), 6.00 (1H, C═CH), 5.81 (1H, C═CH), 5.70 (1H, CH), 5.60 (2H, CH), 5.02-5.07 (2H, CH), 4.78 (1H, CH), 4.39-4.43 (1H, CH), 1.96-2.03 (2H, CH)

Compound (6): ¹H-NMR (400 MHz, DMSO-d6): δ(ppm)=7.25-7.91 (15H, CH), 6.09 (1H, C═CH), 5.98 (1H, C═CH), 5.63 (1H, CH), 5.55 (2H, CH), 4.92 (1H, CH), 3.19 (1H, CH), 2.75 (1H, CH), 2.48-2.52 (1H, CH), 2.08-2.18 (2H, CH), 1.60 (2H, CH), 1.29-1.39 (4H, CH)

Compound (7): ¹H-NMR (400 MHz, DMSO-d6): δ(ppm)=7.25-7.91 (15H, CH), 6.21 (2H, C═CH), 5.60 (2H, CH), 5.36 (1H, CH), 4.89 (1H, CH), 4.47-4.52 (1H, CH), 3.48 (1H, CH), 1.60-1.77 (2H, CH)

Compound (8): ¹H-NMR (400 MHz, DMSO-d6): δ(ppm)=7.25-7.91 (15H, CH), 6.15 (1H, C═CH), 6.06 (1H, C═CH), 5.60 (2H, CH), 4.55 (2H, CH), 3.76 (2H, CH)

Compound (9): ¹H-NMR (400 MHz, DMSO-d6): δ(ppm)=7.25-7.91 (15H, CH), 6.05 (2H, C═CH), 5.57 (2H, CH), 1.53 (9H, CH)

### Synthesis Example of Polymeric Compound

18.27 g of methyl ethyl ketone (hereafter, referred to as MEK) was added to a flask equipped with a thermometer, a reflux tube, a stirrer and a N₂ inlet tube in a nitrogen atmosphere, and the internal temperature was raised to 80° C. while stirring.

Separately from the above, 9.00 g (14.55 mmol) of the compound (1), 14.79 g (46.76 mmol) of compound (10) shown below, and 10.66 g (42.60 mmol) of compound (11) shown below were dissolved in 51.68 g of methyl ethyl ketone. Then, 3.59 g of V-601 as a polymerization initiator was added and dissolved in the obtained solution.

The mixed solution was added to the flask in a dropwise manner at a constant rate over 4 hours, and then heated while stirring for 1 hour, and the reacting solution was cooled to 15° C.

The obtained reaction polymer solution was returned to room temperature, and was added to an excess amount of a methanol/water mixed solution in a dropwise manner so as to deposit a polymer. Thereafter, the precipitated white powder was separated by filtration, followed by washing with a methanol/water mixed solution and drying under reduced pressure, thereby obtaining 27.56 g of a polymeric compound 1 as an objective compound.

With respect to the polymeric compound 1, the weight average molecular weight (Mw) and the dispersity (Mw/Mn) were determined by the polystyrene equivalent value as measured by gel permeation chromatography (GPC). As a result, it was found that the weight average molecular weight was 14,500, and the dispersity was 1.5.

Further, as a result of an analysis by ¹³C-NMR, it was found that the copolymer compositional ratio (ratio (molar ratio) of the respective structural units within the structural formula) was (1)/(10)/(11)=13.8/44.4/41.8.

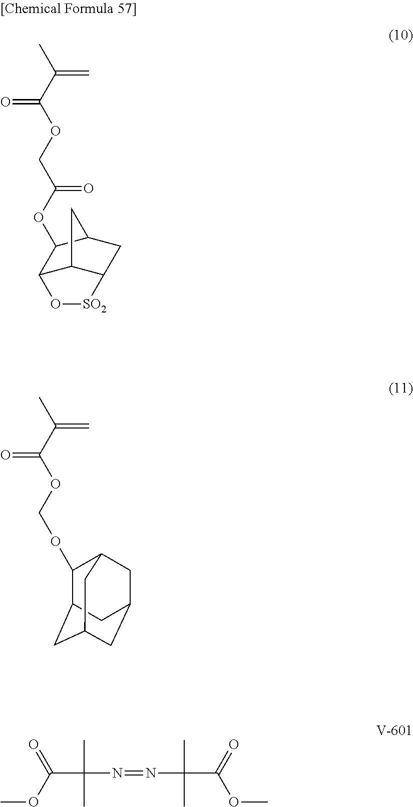

Polymeric compounds 1 to 11 were synthesized in the same manner as in [Synthesis Example of Polymeric Compound] using the monomers which derived the structural units constituting each polymeric compound with a molar ratio indicated in Tables 1 and 2.

TABLE 1

| | | Polymeric compound | | | | |
|---|---|---|---|---|---|---|
| | | 1 | 2 | 3 | 4 | 5 |
| Compound | (1) | 13.8 | | | | |
| | (2) | | 14 | | | |
| | (3) | | | 14 | | |
| | (4) | | | | 14 | |
| | (5) | | | | | 14 |
| | (6) | | | | | |
| | (7) | | | | | |
| | (8) | | | | | |
| | (9) | | | | | |
| | (10) | 44.4 | 45 | 45 | 45 | 45 |
| | (11) | 41.8 | 41 | 41 | 41 | 41 |
| | (12) | | | | | |

| | | | | | |
|---|---|---|---|---|---|
| Mw | 14500 | 14000 | 15000 | 11000 | 13500 |
| Mw/Mn | 1.5 | 1.6 | 1.6 | 2.1 | 1.9 |

TABLE 2

| | | Polymeric compound | | | | | |
|---|---|---|---|---|---|---|---|
| | | 6 | 7 | 8 | 9 | 10 | 11 |
| Com- | (1) | | | | | | |
| pound | (2) | | | | | | |
| | (3) | | | | | | |
| | (4) | | | | | | |
| | (5) | | | | | | |
| | (6) | 14 | | | | | |
| | (7) | | 14 | | | | |
| | (8) | | | 14 | | | |
| | (9) | | | | 14 | | |
| | (10) | 45 | 45 | 45 | 45 | 45 | 45 |
| | (11) | 41 | 41 | 41 | 41 | 41 | 41 |
| | (12) | | | | | 14 | |

| | | | | | | |
|---|---|---|---|---|---|---|
| Mw | 13900 | 12200 | 12900 | 14800 | 13100 | 15500 |
| Mw/Mn | 2.0 | 2.3 | 2.2 | 1.8 | 2.0 | 1.5 |

The components were mixed with the obtained polymeric compound in the mixing ratio indicated in following Tables 3 and 4 to obtain resist compositions (Examples 1 to 20, Comparative Examples 1 and 2).

TABLE 3

| | Compo- | Compo- | Compo- | Compo- | Compo- |
|---|---|---|---|---|---|
| | nent | nent | nent | nent | nent |
| | (A) | (D1) | (D2) | (E) | (S) |
| Example 1 | (A)-1 | — | (D2)-1 | (E)-1 | (S)-1 |
| | [100] | | [0.8] | [0.3] | [4000] |
| Example 2 | (A)-2 | — | (D2)-1 | (E)-1 | (S)-1 |
| | [100] | | [0.8] | [0.3] | [4000] |
| Example 3 | (A)-3 | — | (D2)-1 | (E)-1 | (S)-1 |
| | [100] | | [0.8] | [0.3] | [4000] |
| Example 4 | (A)-4 | — | (D2)-1 | (E)-1 | (S)-1 |
| | [100] | | [0.8] | [0.3] | [4000] |
| Example 5 | (A)-5 | — | (D2)-1 | (E)-1 | (S)-1 |
| | [100] | | [0.8] | [0.3] | [4000] |
| Example 6 | (A)-6 | — | (D2)-1 | (E)-1 | (S)-1 |
| | [100] | | [0.8] | [0.3] | [4000] |
| Example 7 | (A)-7 | — | (D2)-1 | (E)-1 | (S)-1 |
| | [100] | | [0.8] | [0.3] | [4000] |
| Example 8 | (A)-8 | — | (D2)-1 | (E)-1 | (S)-1 |
| | [100] | | [0.8] | [0.3] | [4000] |
| Example 9 | (A)-9 | — | (D2)-1 | (E)-1 | (S)-1 |
| | [100] | | [0.8] | [0.3] | [4000] |
| Example 10 | (A)-1 | (D1)-1 | (D2)-1 | (E)-1 | (S)-1 |
| | [100] | [3.0] | [0.8] | [0.3] | [4000] |
| Comparative | (A)-10 | — | (D2)-1 | (E)-1 | (S)-1 |
| Example 1 | [100] | | [0.8] | [0.3] | [4000] |

TABLE 4

| | Compo- | Compo- | Compo- | Compo- | Compo- | Compo- |
|---|---|---|---|---|---|---|
| | nent | nent | nent | nent | nent | nent |
| | (A) | (B) | (D1) | (D2) | (E) | (S) |
| Example 11 | (A)-11 | (B)-1 | — | (D2)-1 | (E)-1 | (S)-1 |
| | [100] | [14] | | [0.8] | [0.3] | [4000] |
| Example 12 | (A)-11 | (B)-2 | — | (D2)-1 | (E)-1 | (S)-1 |
| | [100] | [14] | | [0.8] | [0.3] | [4000] |
| Example 13 | (A)-11 | (B)-3 | — | (D2)-1 | (E)-1 | (S)-1 |
| | [100] | [14] | | [0.8] | [0.3] | [4000] |
| Example 14 | (A)-11 | (B)-4 | — | (D2)-1 | (E)-1 | (S)-1 |
| | [100] | [14] | | [0.8] | [0.3] | [4000] |
| Example 15 | (A)-11 | (B)-5 | — | (D2)-1 | (E)-1 | (S)-1 |
| | [100] | [14] | | [0.8] | [0.3] | [4000] |
| Example 16 | (A)-11 | (B)-6 | — | (D2)-1 | (E)-1 | (S)-1 |
| | [100] | [14] | | [0.8] | [0.3] | [4000] |
| Example 17 | (A)-11 | (B)-7 | — | (D2)-1 | (E)-1 | (S)-1 |
| | [100] | [14] | | [0.8] | [0.3] | [4000] |
| Example 18 | (A)-11 | (B)-8 | — | (D2)-1 | (E)-1 | (S)-1 |
| | [100] | [14] | | [0.8] | [0.3] | [4000] |
| Example 19 | (A)-11 | (B)-9 | — | (D2)-1 | (E)-1 | (S)-1 |
| | [100] | [14] | | [0.8] | [0.3] | [4000] |
| Example 20 | (A)-11 | (B)-1 | (D1)-1 | (D2)-1 | (E)-1 | (S)-1 |
| | [100] | [14] | [3.0] | [0.8] | [0.3] | [4000] |
| Comparative | (A)-11 | (B)-10 | — | (D2)-1 | (E)-1 | (S)-1 |
| Example 2 | [100] | [14] | | [0.8] | [0.3] | [4000] |

In Tables 3 and 4, the reference characters indicate the following. Further, the values in brackets [ ] indicate the amount (in terms of parts by weight) of the component added.

(A)-1 to (A)-11: the aforementioned polymeric compounds 1 to 11

(B)-1 to (B)-9: the aforementioned compounds (1) to (9)

(B)-10: compound (12) shown below

(D1)-1: compound (D1)-1 shown below

(D2)-1: tri-n-octylamine

(E)-1: salicylic acid

(S)-1: a mixed solvent of PGMEA/PGME/cyclohexanone=45/30/25 (weight ratio)

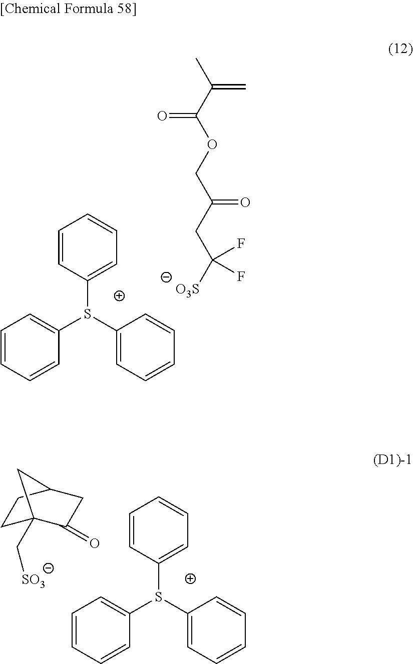

### Formation of Resist Pattern

### Examples 1 to 20, Comparative Examples 1 and 2

Using a spinner, each resist composition was uniformly applied to an 8-inch silicon wafer that had been treated with hexamethyldisilazane (HMDS) at 90° C. for 60 seconds, and subjected to a prebake treatment (PAB) at 130° C. for 60 seconds, thereby forming a resist film (film thickness: 60 nm).

Subsequently, the resist film was subjected to drawing (exposure) using an electron beam lithography apparatus JEOL-JBX-9300FS (manufactured by JEOL Ltd.) at an acceleration voltage of 100 kV, to form a pattern with a target size having a hole diameter of 50 nm and a pitch of 100 nm.

Thereafter, a bake (PEB) treatment was conducted at 100° C. for 60 seconds, followed by development for 60 seconds at 23° C. in a 2.38% by weight aqueous solution of tetramethylammonium hydroxide (TMAH) (trade name: NMD-3; manufactured by Tokyo Ohka Kogyo Co., Ltd.). Thereafter, water rinsing was conducted for 60 seconds using pure water, followed by drying by shaking. Further, a post bake was conducted at 100° C. for 60 seconds.

As a result, in each of the examples, a contact hole pattern (CH pattern) having a hole diameter of 50 nm and a pitch of 100 nm was formed.

[Evaluation of Optimum Exposure Dose (Eop)]

The optimum exposure dose Eop (μC/cm²) with which the CH pattern having the target size was formed by the aforementioned method of forming a resist pattern was determined. The results are shown in Tables 5 and 6.

[Evaluation of in-Plane Uniformity (CDU) of Pattern Size]

With respect to each CH pattern having the above target size obtained by the aforementioned method of forming a resist pattern, 100 holes in the CH pattern was observed from the upper side thereof using a measuring scanning electron microscope (SEM) (product name: S-9380, manufactured by Hitachi High-Technologies Corporation; acceleration voltage: 300V), and the hole diameter (nm) of each hole was measured. From the results, the value of 3 times the standard deviation a (i.e., 3σ) was determined. The results are indicated under “CDU” in Tables 5 and 6.

The smaller the thus determined 3σ value is, the higher the level of the dimension uniformity (CD uniformity) of the plurality of holes formed in the resist film.

[Evaluation of Exposure Latitude (EL Margin)]

In the aforementioned method of forming a resist pattern, the exposure dose with which a CH pattern having a dimension of the target dimension ±5% (i.e., 47.5 nm to 52.5 nm) was formed, was determined, and the EL margin (unit: %) was determined by the following formula. The results are indicated under “EL (%)” in Tables 5 and 6.

EL margin (%)=(|E1−E2|/Eop)×100

In the formula, E1 represents the exposure dose (μC/cm²) for forming a CH pattern with a hole diameter of 47.5 nm, E2 represents the exposure dose (μC/cm²) for forming a CH pattern having a hole diameter of 52.5 nm, and Eop represents the optimum exposure dose with which the CH pattern having a hole diameter of 50 nm was formed.

[Evaluation of Writing Error Enhancement Factor (WEEF)]

In the same manner as in the aforementioned method of forming a resist pattern, with the same exposure dose, CH patterns with a pitch of 100 nm and a target size of 45 to 54 nm (10 target sizes at intervals of 1 nm) were formed.

The WEEF was determined as the gradient of a graph obtained by plotting the target size (nm) on the horizontal axis, and the hole diameter (nm) of the formed CH patterns on the vertical axis. The results are shown in Tables 5 and 6.

A WEEF value (gradient of the plotted line) closer to 1 indicates that the writing error enhancement factor was improved.

TABLE 5

| | Eop | CDU | | |
|---|---|---|---|---|
| | [μC/cm²] | [nm] | EL [%] | WEEF |
| Example 1 | 115.5 | 1.6 | 23.2 | 1.1 |
| Example 2 | 119.1 | 1.9 | 24.0 | 1.1 |
| Example 3 | 129.0 | 1.6 | 25.2 | 1.0 |
| Example 4 | 125.5 | 1.7 | 22.2 | 1.1 |
| Example 5 | 123.8 | 1.7 | 24.9 | 1.0 |
| Example 6 | 126.6 | 1.7 | 28.7 | 1.0 |
| Example 7 | 120.1 | 2.0 | 22.1 | 1.1 |
| Example 8 | 126.7 | 1.9 | 26.7 | 1.1 |
| Example 9 | 131.3 | 2.0 | 27.8 | 1.1 |
| Example 10 | 121.2 | 1.5 | 24.5 | 1.1 |
| Comparative | 133.4 | 2.1 | 21.0 | 1.2 |
| Example 1 | | | | |

TABLE 6

| | Eop | CDU | | |
|---|---|---|---|---|
| | [μC/cm²] | [nm] | EL [%] | WEEF |
| Example 11 | 114.2 | 1.7 | 25.1 | 1.1 |
| Example 12 | 117.8 | 1.9 | 25.9 | 1.1 |
| Example 13 | 127.7 | 1.8 | 27.1 | 1.1 |
| Example 14 | 124.2 | 1.7 | 24.1 | 1.0 |
| Example 15 | 122.5 | 1.7 | 26.8 | 1.0 |
| Example 16 | 125.3 | 1.6 | 30.6 | 1.0 |
| Example 17 | 118.8 | 1.9 | 24.0 | 1.0 |
| Example 18 | 125.4 | 1.9 | 28.6 | 1.1 |
| Example 19 | 119.9 | 2.0 | 26.4 | 1.1 |
| Example 20 | 119.9 | 1.6 | 25.9 | 1.1 |
| Comparative | 131.9 | 2.4 | 22.7 | 1.3 |
| Example 2 | | | | |

From the results shown in Tables 5 and 6, it was confirmed that the resist compositions of the Examples according to the present invention were capable of forming a resist pattern having excellent lithography properties.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A resist composition which generates acid upon exposure and exhibits changed solubility in a developing solution by the action of acid, comprising:
a base component (A′) which exhibits changed solubility in a developing solution under action of acid,
the base component (A′) comprising a polymeric compound (A1′) comprising a structural unit (a0) derived from a compound represented by general formula (a0-1) shown below: 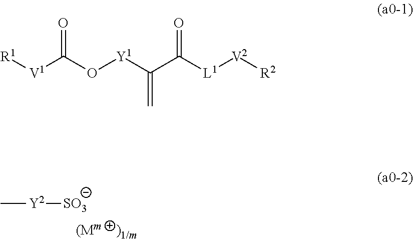
wherein R¹ and R² each independently represents a group represented by general formula (a0-2) or a functional group, provided that at least one of R¹ and R² represents a group represented by general formula (a0-2); V¹ represents a single bond, an oxygen atom, or an alkylene group of 1 to 10 carbon atoms which may have a substituent; V² represents a single bond or an alkylene group of 1 to 10 carbon atoms which may have a substituent; Y¹ represents a single bond or a divalent linking group; Y² represents a fluorinated alkylene group of 1 to 4 carbon atoms which may have a substituent; L¹ represents an oxygen atom or a group represented by —NR′¹—, wherein R′¹ represents a hydrogen atom or an alkylene group of 1 to 5 carbon atoms; M^{m+} represents an organic cation having a valency of m; and m represents an integer of 1 or more.

2. The resist composition according to claim 1, wherein the polymeric compound (A1′) further comprises a structural unit (a1) containing an acid decomposable group that exhibits increased polarity by the action of acid.

3. The resist composition according to claim 1, wherein R¹ is a group represented by general formula (a0-2), and R² is a function group.

4. The resist composition according to claim 1, wherein the functional group is selected from a group which exhibits increased polarity by the action of acid, a substrate adhesion group, a polar group-containing aliphatic hydrocarbon group, or a non-acid dissociable cyclic group.

5. The resist composition according to claim 1, wherein L¹ represents an oxygen atom.

6. A polymeric compound comprising a structural unit (a0) derived from a compound represented by general formula (a0-1) shown below: 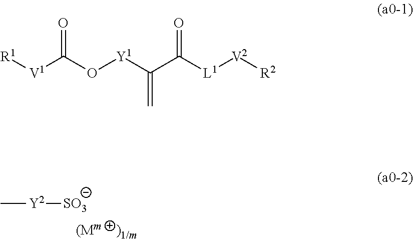
wherein R¹ and R² each independently represents a group represented by general formula (a0-2) or a functional group, provided that at least one of R¹ and R² represents a group represented by general formula (a0-2); V¹ represents a single bond, an oxygen atom, or an alkylene group of 1 to 10 carbon atoms which may have a substituent; V² represents a single bond or an alkylene group of 1 to 10 carbon atoms which may have a substituent; Y¹ represents a single bond or a divalent linking group; Y² represents a fluorinated alkylene group of 1 to 4 carbon atoms which may have a substituent; L¹ represents an oxygen atom or a group represented by —NR′¹—, wherein R′¹ represents a hydrogen atom or an alkylene group of 1 to 5 carbon atoms; X^{m+} represents a metal cation or an organic cation having a valency of m; and m represents an integer of 1 or more.

7. The polymeric compound according to claim 6, further comprising a structural unit (a1) containing an acid decomposable group that exhibits increased polarity by the action of acid.

8. The polymeric compound according to claim 6, wherein R¹ is a group represented by general formula (a0-2), and R² is a function group.

9. The polymeric compound according to claim 6, wherein the functional group is selected from a group which exhibits increased polarity by the action of acid, a substrate adhesion group, a polar group-containing aliphatic hydrocarbon group, or a non-acid dissociable cyclic group.

10. The polymeric compound according to claim 6, wherein L¹ represents an oxygen atom.

11. A compound represented by general formula (a0-1) shown below: 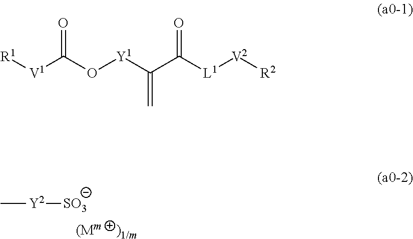
wherein R¹ and R² each independently represents a group represented by general formula (a0-2) or a functional group, provided that at least one of R¹ and R² represents a group represented by general formula (a0-2); V¹ represents a single bond, an oxygen atom, or an alkylene group of 1 to 10 carbon atoms which may have a substituent; V² represents a single bond or an alkylene group of 1 to 10 carbon atoms which may have a substituent; Y¹ represents a single bond or a divalent linking group; Y² represents a fluorinated alkylene group of 1 to 4 carbon atoms which may have a substituent; L¹ represents an oxygen atom or a group represented by —NR′¹—, wherein R′¹ represents a hydrogen atom or an alkylene group of 1 to 5 carbon atoms; X^{m+} represents a metal cation or an organic cation having a valency of m; and m represents an integer of 1 or more.

12. The compound according to claim 11, wherein R¹ is a group represented by general formula (a0-2), and R² is a function group.

13. The compound according to claim 11, wherein the functional group is selected from a group which exhibits increased polarity by the action of acid, a substrate adhesion group, a polar group-containing aliphatic hydrocarbon group, or a non-acid dissociable cyclic group.

14. The compound according to claim 11, wherein L¹ represents an oxygen atom.

15. A resist composition comprising a base component (A) which exhibits changed solubility in a developing solution under action of acid and an acid generator component (B′) which generates acid upon exposure, wherein
the acid generator component (B′) comprises an acid generator (B1′) containing a compound represented by general formula (a0-1) shown below: 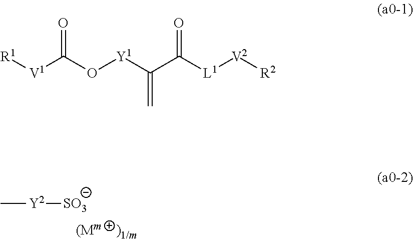
wherein R¹ and R² each independently represents a group represented by general formula (a0-2) or a functional group, provided that at least one of R¹ and R² represents a group represented by general formula (a0-2); V¹ represents a single bond, an oxygen atom, or an alkylene group of 1 to 10 carbon atoms which may have a substituent; V² represents a single bond or an alkylene group of 1 to 10 carbon atoms which may have a substituent; Y¹ represents a single bond or a divalent linking group; Y² represents a fluorinated alkylene group of 1 to 4 carbon atoms which may have a substituent; L¹ represents an oxygen atom or a group represented by —NR′¹—, wherein R′¹ represents a hydrogen atom or an alkylene group of 1 to 5 carbon atoms; M^{m+} represents an organic cation having a valency of m; and m represents an integer of 1 or more.

16. The resist composition according to claim 15, wherein the polymeric compound (A1′) further comprises a structural unit (a1) containing an acid decomposable group that exhibits increased polarity by the action of acid.

17. The resist composition according to claim 15, wherein R¹ is a group represented by general formula (a0-2), and R² is a function group.

18. The resist composition according to claim 15, wherein the functional group is selected from a group which exhibits increased polarity by the action of acid, a substrate adhesion group, a polar group-containing aliphatic hydrocarbon group, or a non-acid dissociable cyclic group.

19. The resist composition according to claim 15, wherein L¹ represents an oxygen atom.

20. A method of forming a resist pattern, comprising: forming a resist film on a substrate using a resist composition of claim 1; conducting exposure of the resist film; and developing the resist film to form a resist pattern.
